(19) United States
(12) Patent Application Publication
(10) Pub. No.: US 2024/0385505 A1
(43) Pub. Date: Nov. 21, 2024

(54) DRY PHOTORESIST OR HARDMASK FOR EUV LITHOGRAPHY

(71) Applicant: International Business Machines Corporation, Armonk, NY (US)

(72) Inventors: Gerhard Ingmar Meijer, Zuerich (CH); Valery Weber, Gattikon (CH); Lucas Morin, Kilchberg (CH); AKIHIRO KISHIMOTO, Setagaya (JP); Peter Willem Jan Staar, Zurich (CH)

(21) Appl. No.: 18/319,757

(22) Filed: May 18, 2023

(51) Int. Cl. G03F 1/22; G03F 1/38; G03F 1/80; G03F 7/004; G03F 7/039; G03F 7/20

(52) U.S. Cl. CPC G03F 1/22; G03F 1/38; G03F 1/80; G03F 7/0042; G03F 7/0392; G03F 7/70033

(57) ABSTRACT

An organometallic compound, composition, and dry photoresist or hardmask for extreme ultraviolet (EUV) lithography are disclosed. The organometallic compound includes at least one bismuth element selected from Bi(III) and Bi(V). The organometallic compound also includes at least one C1 to C6 alkyl ligand and at least one terminal or bridging ligand A (O, S, or N—R, where the R group in N—R is H or a C1 to C6 alkyl) bonded to the bismuth element. Methods for preparing the dry photoresist or hardmask composition and for using the composition to form patterned material features on a substrate are disclosed as well.

### BACKGROUND

The present disclosure relates to photoresist materials for extreme ultraviolet (EUV) lithography and, more specifically, to organometallic compounds for dry photoresists or hardmasks.

Photoresists are photosensitive materials that, after photoimaging and subsequent processing, resist action of certain chemicals in desired areas. Examples of photoresists for deep ultraviolet (DUV) and EUV lithography of the 7-nm and 5-nm technology nodes include polymer-based chemically amplified photoresists and organometallic photoresists.

Organometallic photoresists include organotin compounds in which EUV exposure causes the organotin Sn—C bonds to dissociate, resulting in solubility changes or production of volatile products. Hardmask is a material used in semiconductor processing as an etch mask instead of a polymer or other organic “soft” resist material.

However, currently available chemically amplified photoresists for EUV lithography can be limited in resolution and pattern quality due to stochastic effects and the relatively long diffusion-length of the acid. Dry photoresists and hardmasks can be more sensitive than chemically amplified photoresists. Examples of dry photoresist or hardmask platforms include an organotin precursor, tetramethyltin, and a tin halide precursor, tin (IV) bromide. However, these can have challenging processing windows. For example, tetramethyltin has a low boiling-point and will evaporate quickly from a wafer surface when evacuated at room temperature. Additionally, it can be difficult to manage sublimation of tin (IV) bromide due to its near room temperature vapor pressure of 100 Pa.

Currently available chemically amplified photoresists can also have drawbacks in terms of toxicity and chemical waste due to their use of fluorinated photoacid generators. Existing dry photoresist or hardmask platforms can have similar drawbacks due to use of organotin compounds and/or due to bromine or chlorine reaction products. Further, mitigating process-integration risks associated with these platforms is challenging.

### SUMMARY

Embodiments of the present disclosure are directed to an organometallic compound for dry photoresists or hardmasks for EUV lithography. The organometallic compound includes at least one bismuth element selected from Bi(III) and Bi(V). The organometallic compound also includes at least one terminal or bridging ligand A bonded to the bismuth element. The A ligand is O, S, or N—R, and the R group in N—R is H or a C1 to C6 alkyl. The organometallic compound also includes at least one C1 to C6 alkyl ligand bonded to the bismuth element. In some embodiments, the organometallic compounds can be represented by general formulas (I), (II), (III), (IV), (V), (VI), and (VII):

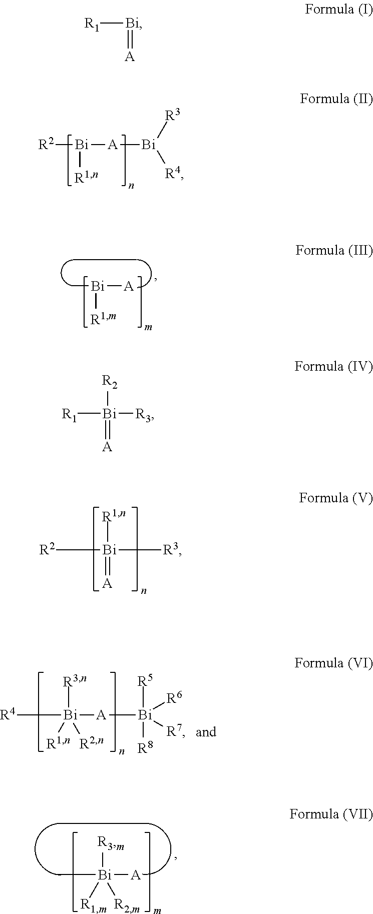

wherein, in the general formulas (I), (II), (III), (IV), (V), (VI), and (VII), A can represent 0, S, or N—R; each of R1, R2, R3, R4, R5, R6, R7, and R8 can represent an optionally substituted linear or branched C1 to C6 alkyl, an optionally substituted C3 to C6 cycloalkyl, or an optionally substituted C3 to C6 heterocycloalkyl; n can be an integer from 1 to 4; m can be an integer from 2 to 5; and R in N—R can represent H, an optionally substituted linear or branched C1 to C6 alkyl, an optionally substituted C3 to C6 cycloalkyl, or an optionally substituted C3 to C6 heterocycloalkyl. The organometallic compound may enable more sensitive and environmentally-friendly photoresists or hardmasks than existing materials.

Further embodiments are directed to a method of preparing a dry photoresist or hardmask composition for EUV lithography, which includes providing the organometallic compound. Additional embodiments are directed to a dry photoresist or hardmask composition that includes the organometallic compound, as well as a dry photoresist or hardmask for EUV lithography that includes the composition.

Additional embodiments are directed to a method of forming a patterned material feature. The method includes providing a material surface on a substrate and forming a layer of the dry photoresist or hardmask composition over material surface. The method also includes patternwise irradiating the dry photoresist or hardmask layer with an energy ray to form a pattern of radiation-exposed regions in the dry photoresist or hardmask layer. Portions of the dry photoresist or hardmask layer are then selectively removed to form exposed portions of the material surface. The patterned material features is formed by etching or ion implanting the exposed portions of the material.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a graph showing the photon absorption cross-sections at 92 eV for all naturally occurring elements.

FIG. 2 is a set of chemical structure diagrams (a) to (j) representing organometallic compounds for dry photoresists or hardmasks for EUV lithography, according to some embodiments.

FIG. 3A is a first set of chemical structure diagrams (a) to (o) representing single, linear, and cyclic organometallic compounds for dry photoresists or hardmasks for EUV lithography wherein Bi is in the oxidation state (III), according to some embodiments.

FIG. 3B is a second set of chemical structure diagrams (p) to (ad) representing single, linear, and cyclic organometallic compounds for dry photoresists or hardmasks for EUV lithography, wherein Bi is in the oxidation state (V), according to some embodiments.

FIGS. 4A-5B are sets of chemical structure diagrams illustrating single organometallic compounds for dry photoresists or hardmasks for EUV lithography represented by general formulas (I) and (IV), according to some embodiments.

FIGS. 6A-7B are sets of chemical structure diagrams illustrating linear organometallic compounds for dry photoresists or hardmasks for EUV lithography represented by general formulas (II), (V), and (VI), according to some embodiments.

FIGS. 8A-9B are sets of chemical structure diagrams illustrating cyclic organometallic compounds for dry photoresists or hardmasks for EUV lithography represented by general formulas (III) and (VII), according to some embodiments.

FIGS. 10A-11B are sets of chemical structure diagrams illustrating cyclic organometallic compounds for dry photoresists or hardmasks for EUV lithography represented by general formulas (III) and (VII), according to some embodiments.

FIG. 12 is a flowchart illustrating a process of using a dry photoresist or hardmask composition to form a patterned material feature on a substrate, according to some embodiments.

While the invention is amenable to various modifications and alternative forms, specifics thereof have been shown by way of example in the drawings, and will be described in detail. It should be understood, however, that the intention is not to limit the invention to the particular embodiments described. Instead, the intention is to cover all modifications, equivalents, and alternatives falling within the spirit and scope of the invention.

### DETAILED DESCRIPTION

The present disclosure relates to photoresist materials for extreme ultraviolet (EUV) lithography and, more specifically, to organometallic compounds for dry photoresists or hardmasks.

The description of the various embodiments of the present disclosure will be presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Unless otherwise stated, the following terms used in this application, including the specification and claims, have the definitions given below. It must be noted that, as used in the specification and the appended claims, the singular forms “a,” “an,” and “the” include plural referents unless the context clearly dictates otherwise. As used herein, the term “comprising” means that the named components are essential, but other components may be added and are still embraced by a composition. As used herein, the term “consisting of” as used according to the present disclosure means in general that the total amount of components of a composition adds up to 100% and signifies that the subject matter is closed-ended and can only include the limitations that are expressly recited. Whenever reference is made to “comprising” it is intended to cover both meanings as alternatives, that is the meaning can be either “comprising” or “consisting of,” unless the context dictates otherwise.

The term “compound(s)” or “compound(s) of the present disclosure” refers to all compounds encompassed by the structural formulas (I) to (VII) or by the structural formula (a) to (r) disclosed herein and includes each subgenus and all specific compounds within the formula whose structure is disclosed herein. The compounds may be identified by either their chemical structure and/or chemical name. When the chemical structure and chemical name are in conflict, the chemical structure determines the identity of the compound.

As used herein, the term “at least one alkyl” means that the organometallic compound according to the present disclosure can comprise either one alkyl ligand or two, three, four, five, six, or even more alkyl ligands, which can either be the same or different. The number of alkyl ligands depends on the oxidation state of the Bi element, i.e., the number of valences, in the organometallic compound and depends on whether the organometallic is a linear or a cyclic compound, as further specified below.

As used herein the term “aliphatic” encompasses the terms alkyl, alkenyl, or alkynyl.

As used herein, an “alkyl” group refers to a saturated aliphatic hydrocarbon group containing from 1 to 8 (e.g., 1, 2, 3, 4, 5, 6, 7, or 8) carbon atoms. An alkyl group can be straight, branched, cyclic, or any combination thereof. Unless specifically limited otherwise, the term “alkyl,” as well as derivative terms such as “alkoxy” and “thioalkyl,” as used herein, include within their scope, straight chain, branched chain, and cyclic moieties. If the alkyl radical is further bonded to another atom, it becomes an alkylene radical or alkylene group. In other words, the term “alkylene” also refers to a divalent linear or branched alkyl. For example, —CH₂CH₃ is an ethyl, while —CH₂CH₂— is an ethylene. The term “alkylene” alone or as part of another substituent refers to a saturated linear or branched divalent hydrocarbon radical obtained by removing two hydrogen atoms from a single carbon atom or two different carbon atoms of a starting alkane.

In preferred variants according to the present disclosure, the linear or branched alkyl group or alkylene group comprises 1 to 8 carbon atoms. In other still more preferred variants, the linear or branched alkyl group or alkylene group comprises 1 to 6 carbon atoms. More preferred according to the disclosure are saturated linear or branched C1 to C6 alkyl groups or saturated linear or branched C1 to C6 alkylene groups. Most preferred the linear or branched alkyl groups or alkylene groups with 1 to 4 carbon atoms. Preferred alkyl radicals/moieties or alkyl groups include, but are not limited to: C1 to C6 alkyl comprising methyl, ethyl, propyl, 1-methylethyl, butyl, 1-methylpropyl, 2-methylpropyl, 1,1-dimethylethyl, pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, and 1-ethyl-2-methylpropyl. The alkyl group or alkylene group as defined above may be unsubstituted or substituted with one or more substituents as set forth below. The term “alkyl” or “alkylene” further includes radicals or groups having any degree of saturation, such as groups having only single carbon-carbon bonds (“alkyl” or “alkylene”), groups having one or more double carbon-carbon bonds (“alkenyl”), radicals having one or more triple carbon-carbon bonds (“alkynyl”), and groups having a mixture of single, double and/or triple carbon-carbon bonds.

The term “alkenyl” alone or as part of another substituent according to the present disclosure refers to an unsaturated linear or branched monovalent hydrocarbon radical having at least one carbon-carbon double bond (C═C double bond). The radical may be in either the cis or trans conformation around the double bond(s). So that the term “alkenyl” also includes the corresponding cis/trans isomers. In preferred variants according to the present disclosure, the linear or branched alkenyl group comprises 2 to 8 carbon atoms. In other preferred variants, the linear or branched alkenyl group comprises 2 to 6 carbon atoms. In still further preferred variants, the linear or branched alkenyl group comprises 2 to 4 carbon atoms. Preferred according to the disclosure are mono- or di-unsaturated linear or branched C2 to C6 alkenyl groups. Typical alkenyl radicals or alkenyl groups include, but are not limited to, ethenyl; propenyls such as prop-1-en-1-yl, prop-1-en-2-yl, prop-2-en-1-yl (allyl), prop-2-en-2-yl, cycloprop-1-en-1-yl, cycloprop-2-en-1-yl; butenyls such as but-1-en-1-yl, but-1-en-2-yl, 2-methyl-prop-1-en-1-yl, but-2-en-1-yl, but-2-en-2-yl, buta-1,3-dien-1-yl, buta-1,3-dien-2-yl, and the like. The alkenyl group as defined above may be unsubstituted or substituted with one or more substituents as set forth below.

The term “alkynyl” alone or as part of another substituent according to the present disclosure refers to an unsaturated linear or branched monovalent hydrocarbon radical having at least one carbon-carbon triple bond (C≡C triple bond). In preferred variants according to the present disclosure, the linear or branched alkynyl group comprises 2 to 8 carbon atoms. In other preferred variants, the alkynyl group comprises 2 to 6 carbon atoms. In still further preferred variants, the alkynyl group comprises 2 to 4 carbon atoms. Most preferred according to the disclosure are mono- or di-unsaturated linear or branched C2 to C6 alkynyl groups. Typical alkynyl radicals/moieties or alkynyl groups include, but are not limited to, ethynyl; propynyls such as prop-1-yn-1-yl, prop-2-in-1-yl, etc.; butynyls such as but-1-in-1-yl, but-1-in-3-yl, but-3-in-1-yl, and the like. The alkynyl group as defined above may further be substituted with one or more substituents as set forth below.

The term “alkoxy” alone or as part of another substituent according to the present disclosure refers to a linear or branched radical of the formula —O—R, where R is alkyl or substituted alkyl, as defined herein. In preferred variants according to the present disclosure, the linear or branched alkoxy group comprises 1 to 8 carbon atoms. In other preferred variants, the linear or branched alkoxy group comprises 1 to 6 carbon atoms. In still further preferred variants, the linear or branched alkoxy group comprises 1 to 4 carbon atoms. Most preferred, in some embodiments, are linear or branched C1 to C6 alkoxy groups. Typical alkoxy radicals/moieties or alkoxy groups include C1 to C6 alkoxy comprising C1 to C4 alkoxy such as. methoxy, ethoxy, n-propoxy, 1-methylethoxy, butoxy, 1-methylpropoxy, 2-methylpropoxy or 1,1-dimethylethoxy; as well as pentoxy, 1-methylbutoxy, 2-methylbutoxy, 3-methylbutoxy, 1,1-dimethylpropoxy, 1,2-dimethylpropoxy, 2,2-dimethylpropoxy, 1-ethylpropoxy, hexoxy, 1-methylpentoxy, 2-methylpentoxy, 3-methylpentoxy, 4-methylpentoxy, 1,1-dimethylbutoxy, 1,2-dimethylbutoxy, 1,3-dimethylbutoxy, 2,2-dimethylbutoxy, 2,3-dimethylbutoxy, 3,3-dimethylbutoxy, 1-ethylbutoxy, 2-ethylbutoxy, 1,1,2-trimethylpropoxy, 1,2,2-trimethylpropoxy, 1-ethyl-1-methylpropoxy or 1-ethyl-2-methylpropoxy. The alkoxy group as defined above may further be substituted.

The term “alkylthio” or “thioalkoxy” alone or as part of another substituent refers to a radical of the formula —S—R, wherein R is alkyl or substituted alkyl, as defined herein.

Herein, the term “alkyl” or “alkylene” also includes heteroalkyl radicals or heteroalkyl groups. The term “heteroalkyl” by itself or as part of other substituents refers to alkyl groups in which one or more of the carbon atom(s) is/are independently replaced by the same or another heteroatom or by the same or another heteroatomic group(s). Examples of heteroatomic groups that may be included in these groups include, but are not limited to, —O—, —S—, —O—O—, —S—S—, —O—S—, —NR—, ═NN═, —N═N—, —N═NNR—, —BR—, —PR—, —P(O)₂—, —POR—, —O—P(O)₂—, —SO—, —SO₂—, —SR₂OR—, —S(O)NR—, —S(O)₂NR—, and the like, wherein R is independently hydrogen, alkyl, substituted alkyl, aryl, substituted aryl, arylalkyl, substituted arylalkyl, cycloalkyl, substituted cycloalkyl, cycloheteroalkyl, substituted cycloheteroalkyl, heteroalkyl, substituted heteroalkyl, heteroaryl, substituted heteroaryl, heteroarylalkyl or substituted heteroarylalkyl as defined herein. The heteroatoms or heteroatomic groups may be located at any internal position of the alkyl group.

As used herein, the term “cyclic” refers to an aliphatic ring compound or group comprising at least three carbon atoms and the bonds between pairs of adjacent atoms may all be of the type designated single bonds (involving two electrons), or some of them may be double or triple bonds (with four or six electrons, respectively). As used herein, a “cycloalkyl” group refers to a saturated carbocyclic ring of 3 to 8 (e.g., 3, 4, 5, 6, 7, or 8) carbon atoms. Examples of cycloalkyl groups include cyclopropyl, cyclobutyl, cyclopentyl, cyclohexyl, cycloheptyl, and cyclooctyl. The cycloalkyl group as defined above may be unsubstituted or substituted with one or more substituents as set forth below.

As used herein, the term “heterocycloalkyl” alone or as part of another substituent refers to a saturated, non-aromatic, cyclic monovalent hydrocarbon radical in which one or more carbon atom(s) is/are independently replaced by the same or a different heteroatom. Typical heteroatoms to replace the carbon atom(s) include, but are not limited to, N, B, P, O, S, Si, etc. Typical heterocycloalkyl groups include, without being limited thereto, groups derived from epoxides, azirines, thiiranes, imidazolidine, morpholine, piperazine, piperidine, pyrazolidine, pyrrolidone, quinuclidine, and the like.

The heterocycloalkyl moiety may occur as a monocyclic compound having only a single ring. Preferably, the term “heterocycloalkyl” encompasses three- to seven-membered, saturated, mono-, or polyunsaturated heterocycloalkyl radicals comprising one, two, three or four heteroatoms selected from the group consisting of O, N, and S. The heteroatom or heteroatoms may occupy any position in the heterocycloalkyl ring. In one preferred variation, the term “heterocycloalkyl” includes a three- to seven-membered monocyclic heterocycloalkyl radical. In other still more preferred variants, the heterocycloalkyl radical comprises a three-, four-, five-, six-, seven- or eight-membered monocyclic heterocycloalkyl radical.

Typical heterocycloalkyl radicals include, but are not limited to: Three to six membered saturated heterocycloalkyl containing one or two nitrogen atoms and/or one oxygen or sulfur atom or one or two oxygen and/or sulfur atoms as ring members comprising aziridinyl, oxiranyl, thiiranyl, azetidinyl, oxetanyl, thietanyl, 2-tetrahydrofuranyl, 3-tetrahydrofuranyl, 2-tetrahydrothienyl, 3-tetrahydrothienyl, 1-pyrrolidinyl, 2-pyrrolidinyl, 3-pyrrolidinyl, 3-isoxazolidinyl, 4-isoxazolidinyl, 5-isoxazolidinyl, 3-isothiazolidinyl, 4-isothiazolidinyl, 5-isothiazolidinyl, 3-pyrazolidinyl, 4-pyrazolidinyl, 5-pyrazolidinyl, 2-oxazolidinyl, 4-oxazolidinyl, 5-oxazolidinyl, 2-thiazolidinyl, 4-thiazolidinyl, 5-thiazolidinyl, 2-lmidazolidinyl, 4-lmidazolidinyl, 2-pyrrolin-2-yl, 2-pyrrolin-3-yl, 3-pyrrolin-2-yl, 3-pyrrolin-3-yl, 1-piperidinyl, 2-piperidinyl, 3-piperidinyl, 4-piperidinyl, 1,3-dioxan-5-yl, 2-tetrahydropyranyl, 4-tetrahydropyranyl, 2-tetrahydrothienyl, 3-hexahydropyridazinyl, 4-hexahydropyridazinyl, 2-hexahydropyrimidinyl, 4-hexahydropyrimidinyl, 5-hexahydropyrimidinyl, 2-piperazinyl, and the like.

The heterocycloalkyl residue or heterocycloalkyl group, as defined above, can be unsubstituted or substituted with one or more substituents as set forth below.

As used herein, the term “amine” or “amino” includes compounds where a nitrogen atom is covalently bonded to at least one carbon or heteroatom. The term “amine” or “amino” also includes —NH₂ and also includes substituted moieties. The term includes “alkyl amino” which comprises groups and compounds wherein the nitrogen is bound to at least one additional alkyl group. As used herein, the term “imino” group or residue means the bivalent group ═NR, wherein R represents either H or an alkyl group as defined herein. In some embodiments, the imino group can either be a terminal group or a bridging ligand in the general formula as defined herein, bonded to the Bi(III) or Bi(V) element by a double bond.

As used herein, an “alkoxy” group refers to an alkyl —O— group where “alkyl” has been defined previously. The term “alkylthio” includes straight-chain alkylthio, branched-chain alkylthio, cycloalkylthio, cyclic alkylthio, heteroatom-unsubstituted alkylthio, heteroatom-substituted alkylthio, heteroatom-unsubstituted Cₙ-alkylthio, and heteroatom-substituted Cₙ-alkylthio. In certain embodiments, lower alkylthios are contemplated.

The term “halogen” residue/moiety or group alone or as part of another substituent refers to F, Cl, Br, or I.

The phrase “optionally substituted” is used interchangeably with the phrase “unsubstituted or substituted.” As described herein, compounds of the present disclosure can optionally be substituted with one or more substituents, such as are illustrated generally above, or as exemplified by particular classes, subclasses, and species of the present disclosure. As described herein, any of the above moieties or those introduced below can be optionally substituted with one or more substituents described herein.

The term “substituted” in the context of the present disclosure means that one or more hydrogen atoms of the indicated radical or group is/are independently replaced by the same or a different substituent(s). Additionally, the term “substituted” specifically provides for one or more, e.g., two, three, or more, substituents commonly used in the art. However, it is generally known that the substituents should be selected so that they do not adversely affect the useful properties of the compound or its function.

Suitable substituents in the context of the present disclosure preferably include halogen groups, perfluoroalkyl groups, perfluoroalkoxy groups, alkyl groups, alkenyl groups, alkynyl groups, hydroxy groups, oxo groups, mercapto groups, alkylthio groups, alkoxy groups, aryl or heteroaryl groups, aryloxy groups or heteroaryloxy groups, arylalkyl or heteroarylalkyl groups, arylalkoxy or heteroarylalkoxy groups, amino groups, alkyl and dialkylamino groups, carbamoyl groups, alkylcarbonyl groups, carboxyl groups, alkoxycarbonyl groups, alkylaminocarbonyl groups, dialkylaminocarbonyl groups, arylcarbonyl groups, aryloxycarbonyl groups, alkylsulfonyl groups, arylsulfonyl groups, cycloalkyl groups, cyano groups, C1 to C6 alkylthio groups, arylthio groups, nitro groups, keto groups, acyl groups, boronate or boronyl groups, phosphate or phosphonyl groups, sulfamyl groups, sulfonyl groups, sulfinyl groups, and combinations thereof.

Substituents or substituent groups useful for substituting saturated carbon atoms in the indicated group or radical more preferably include, but are not limited to, halogen, hydroxyl, alkyl, alkenyl, alkynyl, alkoxyl, —NH₂, amino (primary, secondary, or tertiary), nitro, thiol, thioether, imine, cyano, amido, phosphonato, phosphine, carboxyl, thiocarbonyl, sulfonyl, sulfonamide, ketone, aldehyde, ester, acetyl, acetoxy, carbamoyl, oxygen (O); haloalkyl (e.g., trifluoromethyl); aminoacyl and aminoalkyl, carbocyclic cycloalkyl, which may be monocyclic or fused or non-fused polycyclic (e.g., cyclopropyl, cyclobutyl, cyclopentyl, or cyclohexyl), or a heterocycloalkyl, which may be monocyclic or fused or non-fused polycyclic (e.g., pyrrolidinyl, piperidinyl, piperazinyl, morpholinyl, or thiazinyl), carbocyclic or heterocyclic, monocyclic or fused or non-fused polycyclic aryl (e.g., phenyl, naphthyl, pyrrolyl, indolyl, furanyl, thiophenyl, imidazolyl, oxazolyl, isoxazolyl, thiazolyl, triazolyl, tetrazolyl, pyrazolyl, pyridinyl, quinolinyl, isoquinolinyl, acridinyl, pyrazinyl, pyridazinyl, pyrimidinyl, benzimidazolyl, benzothiophenyl, or benzofuranyl), —CO₂CH₃, —CONH₂, —OCH₂CONH₂; —SO₂NH₂, —OCHF₂, —CF₃, —OCF₃.

Modifications or derivatives of the compounds disclosed throughout this specification are contemplated as being useful with the methods and compositions of the present disclosure. Derivatives may be prepared and the properties of such derivatives may be assayed for their desired properties by any method known to those of skill in the art. In certain aspects, “derivative” refers to a chemically modified compound that still retains the desired effects of the compound prior to the chemical modification.

In various embodiments, conventional materials and processing techniques can be employed and, hence, such conventional aspects are not set forth herein in detail. For example, the selection of suitable solvents, photosensitizers, pigments, fillers, antistatic agents, flame retardants, defoaming agents, light stabilizers, and antioxidants can be conducted in a conventional manner.

Turning now to an overview of technologies that are more specifically relevant to aspects of the present disclosure, Examples of photoresists for deep ultraviolet (DUV) and EUV lithography of the 7-nm and 5-nm technology nodes include polymer-based chemically amplified photoresists and organometallic photoresists, such as organotin photoresists. These photoresist platforms can include a photoacid generator and an acid-labile polymer. The acid-labile protection group of this polymer can be removed by an acid, resulting in compounds that are alkali-soluble or volatile. Organometallic photoresist platforms are also used. For example, EUV exposure can cause the organotin Sn—C bonds to dissociate, resulting in solubility changes or production of volatile products.

In general, photoresists for deep ultraviolet (DUV) and EUV lithography of the 7-nm and 5-nm technology nodes have typically been polymer-based chemically amplified photoresists. These photoresist platforms include a photoacid generator (PAG) and an acid-labile polymer. The acid-labile protection group of this polymer can be removed by an acid, resulting in compounds that are alkali-soluble or volatile. Organometallic photoresist platforms are also used, such as organotin photoresists. For example, EUV exposure can cause the organotin Sn—C bonds to dissociate, resulting in solubility changes or production of volatile products.

A key metric of a photoresist is its sensitivity. Sensitivity is the UV dose that is required to print a feature in the photoresist. Currently available chemically amplified photoresists for EUV lithography can be insufficiently sensitive for various applications.

Another key metric of the photoresist is its resolution or pattern quality. Currently available chemically amplified photoresists for EUV lithography can be limited in resolution and pattern quality due to stochastic effects related to the relatively small number of photons that are absorbed and due to the relatively long diffusion-length of the acid.

Organometallic photoresists can be more sensitive than the chemically amplified photoresists. Examples of organometallic photoresists for EUV lithography include organotin clusters, which may be applied by chemical vapor deposition (CVD) or atomic layer deposition (ALD). In these examples, EUV exposure can cause dissociation of the Sn—C bonds and crosslinking of the inorganic SnOₓ clusters. This leads to a change of the solubility in which the non-exposed material is soluble in alkaline solvents, and the exposed material is not. While these photoresist platforms can be more sensitive in the EUV than state-of-the-art chemically amplified photoresists, further performance improvements are sought.

Dry photoresists or hardmasks for EUV lithography can also be more sensitive than chemically amplified photoresists. An example dry photoresist or hardmask platform includes an organotin precursor, tetramethyltin, or a tin halide precursor, tin (IV) bromide. Upon EUV exposure, the Sn—C or Sn—Br bonds dissociate, resulting in Sn metal and, respectively, ethane or bromine. Ethane and bromine are volatile at processing conditions in an EUV scanner. Therefore, only the Sn metal is left behind. While this photoresist platform can have a higher sensitivity in the EUV than chemically amplified photoresists, the processing window is challenging. Tetramethyltin is a low boiling-point temperature liquid and will evaporate quickly from a wafer surface when evacuated at room temperature. Tin (IV) bromide has a near room temperature vapor pressure of 100 Pa, and it is challenging to manage tin (IV) bromide sublimation.

Further, toxicity and chemical waste of photoresists are increasingly in focus. Previously, regulations have been enacted to control and phase-down fluorinated materials such as perfluorocarbons and sulfur hexafluoride. It is expected that regulation bodies will scrutinize use of fluorinated materials and that international actions on these fluorinated materials might follow. Currently available chemically amplified photoresists for DUV and for EUV lithography generally have, due to the use of fluorinated photoacid generators, drawbacks in terms of toxicity and chemical waste.

While organometallic photoresist platforms and dry photoresist or hardmask platforms are generally fluorine-free, existing platforms often have similar drawbacks due to incorporation of organotin compounds and/or due to bromine or chlorine reaction products, which are both strong oxidants. Further, while existing dry photoresists or hardmasks for EUV lithography have generally a high sensitivity, mitigating process-integration risks is challenging.

Therefore, there is a need for photoresists for EUV lithography which have high sensitivity, good resolution/pattern quality, low toxicity/chemical waste, and low process-integration risk. Disclosed herein are organometallic compounds that, in some embodiments, may address these and other challenges. The disclosed organometallic compounds can be formulated into dry photoresist or hardmasks compositions that may be useful in lithographic processes, especially when EUV radiation is used.

In some embodiments, the organometallic compounds include at least one bismuth (Bi(III) or Bi(V)) element bonded to at least one terminal or bridging ligand (A) and at least one C1 to C6 alkyl ligand. The metal element bismuth has a large absorption cross-section for EUV photons. Examples of terminal ligands can include oxo, thioxo, and imino (═N—R), and examples of bridging ligands can include an oxygen, sulfur, and amino (—N(R)—). The R group or R residue in N—R can be H or an alkyl ligand such as the alkyl ligand bonded to the Bi(III) or Bi(V) element as defined herein.

The disclosed organometallic compounds for dry photoresists or hardmasks for EUV lithography may have advantages over existing materials (see above) in terms of toxicity and chemical waste. For example, the disclosed compounds are fluorine-free, in contrast to currently available chemically amplified photoresists that use fluorinated PAGs. Additionally, the disclosed compounds do not include tin, in contrast to currently available organometallic photoresists and dry photoresists or hardmasks for EUV lithography.

The disclosed organometallic compounds for dry photoresists or hardmasks for EUV lithography may also have advantages over existing materials in terms of resolution or pattern quality: The disclosed organometallic molecules have high melting-point temperatures and, concomitantly, high activation energies for diffusion. Therefore, the disclosed molecules can have a low diffusion coefficient at processing conditions in the EUV scanner. Furthermore, the disclosed organometallic molecules have a high density and, concomitantly, low shrinkage when inorganic clusters crosslink upon EUV exposure.

The organometallic molecules for dry photoresists or hardmasks for EUV lithography taught here can have high absorption cross-sections for photons in the EUV. Therefore, the disclosed compounds can have a high sensitivity in the EUV. The disclosed organometallic molecules for dry photoresists or hardmasks for EUV lithography may also have low process-integration risks: For example, the disclosed compounds have high melting-point temperatures and are solids with a very low vapor pressure at conditions (vacuum) found in the EUV scanner.

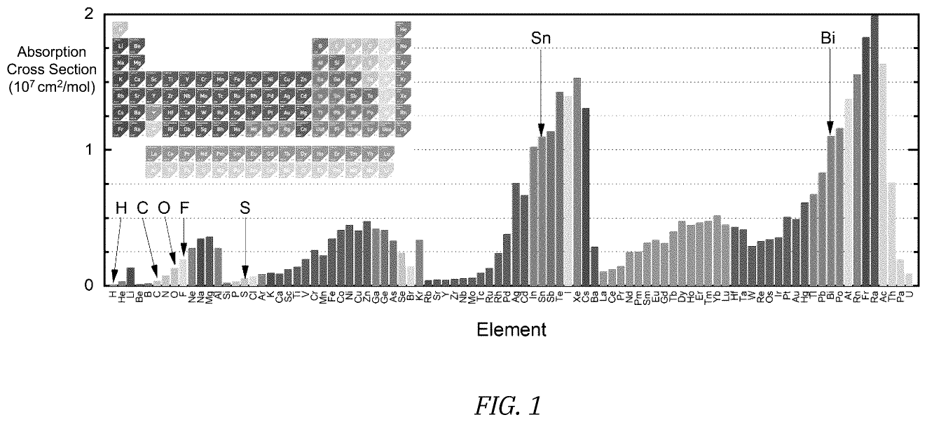

FIG. 1 is a graph showing the photon absorption cross-section μₐ at 92 eV of all naturally occurring elements. In order to devise materials that can be used to increase the sensitivity of photoresists for EUV lithography, it is crucial to understand and to appreciate the microscopic mechanisms that cause photon absorption events in the EUV, in contrast to mechanisms in the DUV.

The DUV (193 nm, 6 eV) photon absorption is determined by the molecular orbitals of the photoresist material. The absorbed photons can directly and selectively cause resonant electronic transitions in a photoacid generator, resulting in the generation of the acid. The sensitivity of chemically amplified photoresists for DUV lithography can be increased by adjusting the molecular structure of the photoacid generator. The EUV (13.5 nm, 92 eV, soft X-ray) photon absorption, on the other hand, is determined by the atomic composition of the photoresist material, rather than the molecular structure.

The absorption of photons in a layer of thickness d is given by 1−exp (−n μₐ d), where n is the number of atoms per unit volume in the layer. To increase the photoresists' 92-eV-photon absorption cross-section, elements that have a large absorption cross-section at this photon energy can be added to the photoresist composition. For example, the elements In, Sn, Sb, Te, Bi, Sb, and Po have a large absorption cross-section for EUV photons. Of these, bismuth (Bi) can have advantages in terms of toxicity, stability, and cost.

Herein, the organometallic compounds for dry photoresists or hardmasks for EUV lithography include the metal element Bi in its oxidation state (III) or the metal element Bi in its oxidation state (V). Providing the metal element Bi with the ligand A can increase the molecule's melting-point temperature and, concomitantly, increase the molecule's activation energy for diffusion and, therefore, a decrease of the molecule's diffusion coefficient at processing conditions in the EUV scanner.

The C1 to C6 alkyl ligand(s) of the organometallic compound can be chosen such that the reaction products formed upon EUV exposure, aside from the inorganic clusters (Bi═O clusters, Bi═S clusters, Bi═N clusters, Bi—O clusters, Bi—S clusters, or Bi—N clusters), are volatile at processing conditions in the EUV scanner. EUV exposure can cause the Bi—C bonds and the N—R bonds in the organometallic compounds to dissociate. Upon dissociation, the alkyl groups can become radicals, and the inorganic Bi═O clusters, Bi═S clusters, Bi═N clusters, Bi—O clusters, Bi—S clusters, or Bi═N clusters can crosslink. The thus obtained C1 to C6 alkyl radicals pairwise react with each other, forming C2 to C12 alkyl species, which are volatile and evaporate. For example, when the alkyl ligand is methyl or ethyl, the volatile product is ethane or butane, respectively. The non-volatile crosslinked inorganic clusters can remain as reaction product on the substrate after the volatile organic alkyl species evaporate.

The organometallic compounds can be represented by general formulas (I), (II), (III), (IV), (V), (VI), and (VII):

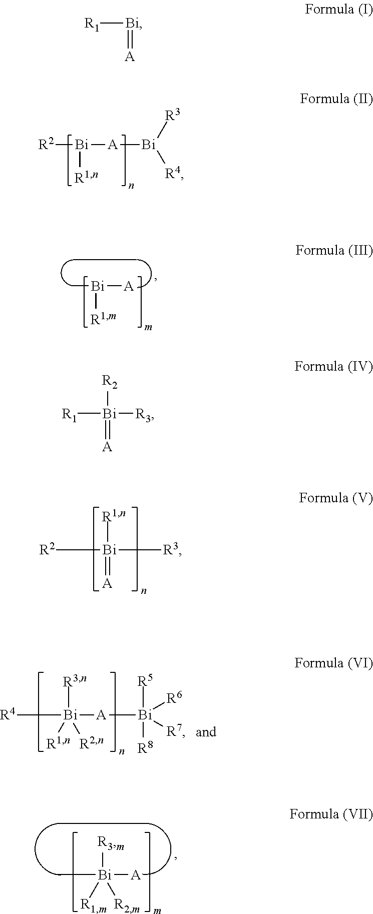

wherein, in the general formulas (I), (II), (III), (IV), (V), (VI), and (VII), A can represent 0, S, or N—R; each of R1, R2, R3, R4, R5, R6, R7, and R8 can represent an optionally substituted linear or branched C1 to C6 alkyl, an optionally substituted C3 to C6 cycloalkyl, or an optionally substituted C3 to C6 heterocycloalkyl; n can be an integer from 1 to 4; m can be an integer from 2 to 5; and R in N—R can represent either H or an optionally substituted linear or branched C1 to C6 alkyl, an optionally substituted C3 to C6 cycloalkyl, or an optionally substituted C3 to C6 heterocycloalkyl.

In a preferred variant, the organometallic compound is a single compound according to the general formula (I), wherein Bi is in the oxidation state (III), or is a single compound according to the general formula (IV), wherein Bi is in the oxidation state (V). In a more preferred variant, the organometallic compound is a linear, non-cyclic, compound according to the general formula (II), (V), or (VI), wherein n is an integer from 1 to 3. Most preferred, n is 1 or 2. Even more preferred, the organometallic compound is a cyclic compound according to the general formula (III) or (VII), wherein m is an integer from 2 to 4. Most preferred, m is 2 or 3.

In some embodiments, in the organometallic compound represented by any one of the above specified general formulas (I) to (VII), the alkyl ligand R1, R2, R3, R4, R5, R6, R7, R8, or RN is an optionally substituted linear or branched C1 to C6 alkyl, an optionally substituted C3 to C6 cycloalkyl, or an optionally substituted C3 to C6 heterocycloalkyl, in particular an optionally substituted linear C1 to C6 alkyl, an optionally substituted C3 to C6 cycloalkyl, or an optionally substituted C3 to C6 heterocycloalkyl.

In further embodiments, in the organometallic compound represented by any one of the above specified general formulas (I) to (VII), the alkyl ligand R1, R2, R3, R4, R5, R6, R7, R8, or RN is an optionally substituted linear or branched C1 to C5 alkyl, an optionally substituted C3 to C5 cycloalkyl, or an optionally substituted C3 to C5 heterocycloalkyl, in particular an optionally substituted linear C1 to C5 alkyl, an optionally substituted C3 to C5 cycloalkyl, or an optionally substituted C3 to C5 heterocycloalkyl.

In further embodiments, in the organometallic compound represented by any one of the above specified general formulas (I) to (VII), the alkyl ligand R1, R2, R3, R4, R5, R6, R7, R8, or RN is an optionally substituted linear or branched C1 to C4 alkyl, an optionally substituted C3 or C4 cycloalkyl, or an optionally substituted C3 or C4 heterocycloalkyl, in particular an optionally substituted linear C1 to C4 alkyl, an optionally substituted C3 or C4 cycloalkyl, or an optionally substituted C3 or C4 heterocycloalkyl.

In further embodiments, in the organometallic compound represented by any one of the above specified general formulas (I) to (VII), the alkyl ligand R1, R2, R3, R4, R5, R6, R7, R8, or RN is an optionally substituted linear or branched C1 to C3 alkyl, an optionally substituted C3 cycloalkyl, or an optionally substituted C3 heterocycloalkyl, in particular an optionally substituted linear C1 to C3 alkyl, an optionally substituted C3 cycloalkyl, or an optionally substituted C3 heterocycloalkyl.

In additional embodiments, in the organometallic compound represented by any one of the above specified general formulas (I) to (VII), the alkyl ligand R1, R2, R3, R4, R5, R6, R7, R8, or RN is an optionally substituted C1 or C2 alkyl.

In the organometallic compounds represented by any one of the above specified general formulas (I) to (VII), R1, R2, R3, R4, R5, R6, R7, R8, or RN may be either identical or different from each other. For ease of synthesis, the alkyl ligands R1, R2, R3, R4, R5, R6, R7, R8, or RN may be identical.

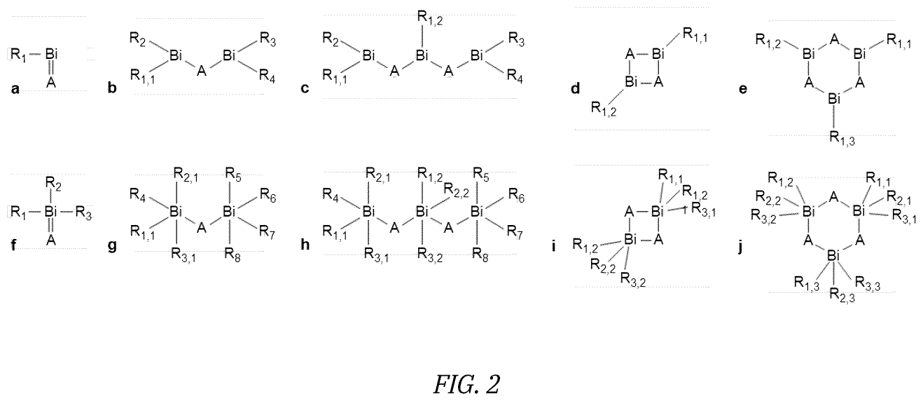

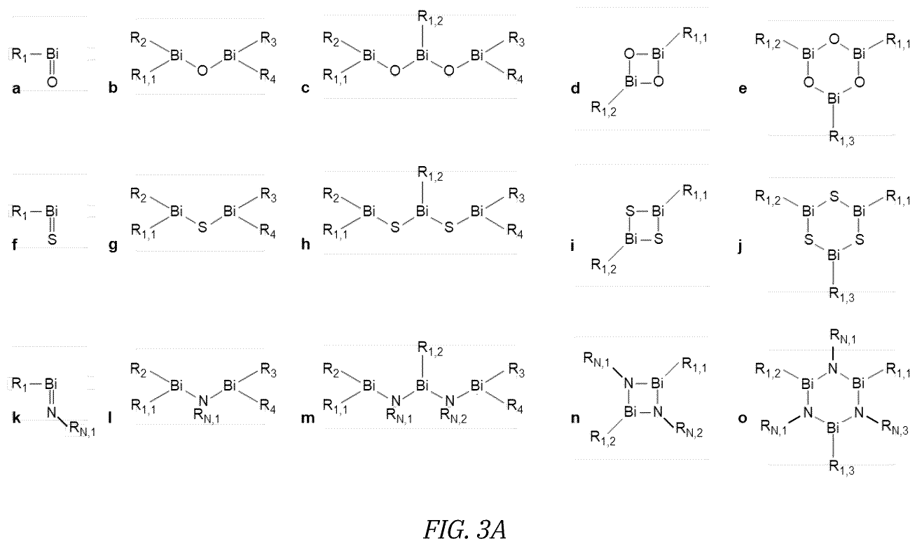

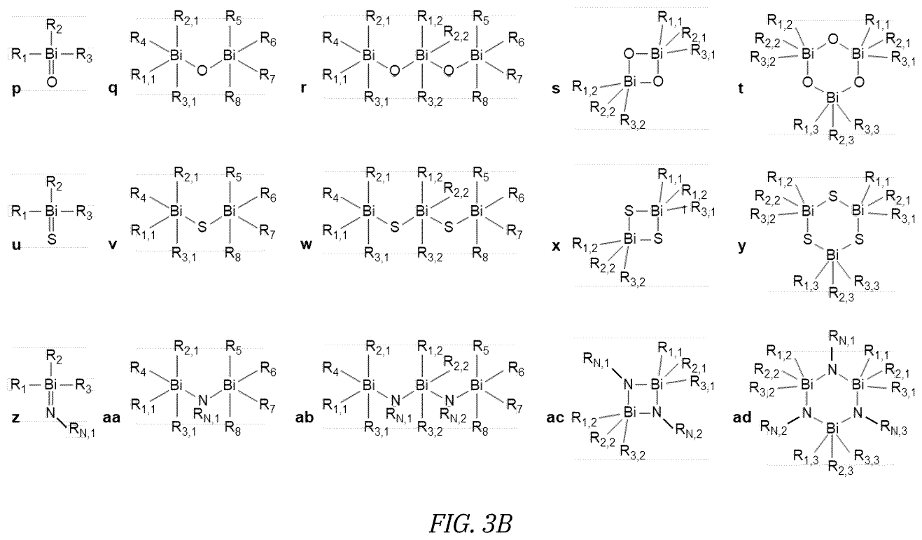

In preferred embodiments, the organometallic compound is represented by any one of the general formulas (a) to (j) illustrated in FIG. 2. In further preferred embodiments, the organometallic compound is represented by any one of the formulas (a) to (o) illustrated in FIG. 3A or any one of the formulas (p) to (ad) illustrated in FIG. 3B. The compounds illustrated in FIGS. 3A and 3B include single, linear, and cyclic organometallic compounds according to the general formulas (I), (II), (III), (IV), (VI), or (VII), wherein A=O, S, or N—R, and n is 1 or 2, or mis 2 or 3.

FIG. 2 is a set of chemical structure diagrams representing organometallic compounds (a) to (j) for dry photoresists or hardmasks for EUV lithography, according to some embodiments. In the compounds (a), (b), (c), (d), and (e), Bi is in the oxidation state (III) and in the compounds (f), (g), (h), (i), and (j), Bi is in the oxidation state (V). In compounds (a)-(j), A can represent a species selected from the group consisting of O, S, and N—R; and the alkyl ligands R1, R2, R3, R4, R5, R6, R7, R8, R1/1, R2/1, R3/1, R1/2, R2/2, R3/2, R1/3, R2/3, and R3/3 can represent, independently from each other, an optionally substituted linear or branched C1 to C6 alkyl, an optionally substituted C3 to C6 cycloalkyl, or an optionally substituted C3 to C6 heterocycloalkyl. In N—R, the R can represent either H or an optionally substituted linear or branched C1 to C6 alkyl, an optionally substituted C3 to C6 cycloalkyl, or an optionally substituted C3 to C6 heterocycloalkyl.

In a more preferred variant, in the organometallic compound represented by any one of the formulas (a) to (j) of FIG. 2, the alkyl ligand R1, R2, R3, R4, R5, R6, R7, R8, R1/1, R2/1, R3/1, R1/2, R2/2, R3/2, R1/3, R2/3, or R3/3 is an optionally substituted linear or branched C1 to C6 alkyl, an optionally substituted C3 to C6 cycloalkyl, or an optionally substituted C3 to C6 heterocycloalkyl, in particular an optionally substituted linear C1 to C6 alkyl, an optionally substituted C3 to C6 cycloalkyl, or an optionally substituted C3 to C6 heterocycloalkyl.

In a more preferred variant, in the organometallic compound represented by any one of the formulas (a) to (j) of FIG. 2, the alkyl ligand R1, R2, R3, R4, R5, R6, R7, R8, R1/1, R2/1, R3/1, R1/2, R2/2, R3/2, R1/3, R2/3, or R3/3 is an optionally substituted linear or branched C1 to C5 alkyl, an optionally substituted C3 to C5 cycloalkyl, or an optionally substituted C3 to C5 heterocycloalkyl, in particular an optionally substituted linear C1 to C5 alkyl, an optionally substituted C3 to C5 cycloalkyl, or an optionally substituted C3 to C5 heterocycloalkyl.

In a more preferred variant, in the organometallic compound represented by any one of the general formulas (a) to (j) of FIG. 2, the alkyl ligand R1, R2, R3, R4, R5, R6, R7, R8, R1/1, R2/1, R3/1, R1/2, R2/2, R3/2, R1/3, R2/3, or R3/3 is an optionally substituted linear or branched C1 to C4 alkyl, an optionally substituted C3 to C4 cycloalkyl, or an optionally substituted C3 to C4 heterocycloalkyl, in particular an optionally substituted linear C1 to C4 alkyl, an optionally substituted C3 or C4 cycloalkyl, or an optionally substituted C3 or C4 heterocycloalkyl.

In a further preferred variant, in the organometallic compound represented by any one of the general formulas (a) to (j) of FIG. 2, the alkyl ligand R1, R2, R3, R4, R5, R6, R7, R8, R1/1, R2/1, R3/1, R1/2, R2/2, R3/2, R1/3, R2/3, or R3/3 is an optionally substituted linear or branched C1 to C3 alkyl, an optionally substituted C3 cycloalkyl, or an optionally substituted C3 heterocycloalkyl, in particular an optionally substituted linear C1 to C3 alkyl, an optionally substituted C3 cycloalkyl, or an optionally substituted C3 heterocycloalkyl.

In an even more preferred variant, in the organometallic compound represented by any one of the general formulas (a) to (j) of FIG. 2, the alkyl ligand R1, R2, R3, R4, R5, R6, R7, R8, R1/1, R2/1, R3/1, R1/2, R2/2, R3/2, R1/3, R2/3, or R3/3 is an optionally substituted C1 or C2 alkyl.

FIG. 3A is a set of chemical structure diagrams (a) to (o) representing single, linear, and cyclic organometallic compounds for dry photoresists or hardmasks for EUV lithography, wherein Bi is in the oxidation state (III), according to some embodiments. In FIG. 3A:
(a) A in general Formula (I) is O;
(b) A in general Formula (II) is O and n=1;
(c) A in general Formula (II) is O and n=2;
(d) A in general Formula (III) is O and m=2;
(e) A in general Formula (III) is O and m=3;
(f) A in general Formula (I) is S;
(g) A in general Formula (II) is S and n=1;
(h) A in general Formula (II) is S and n=2;
(i) A in general Formula (III) is S and m=2;
(j) A in general Formula (III) is S and m=3;
(k) A in general Formula (I) is N—R;
(l) A in general Formula (II) is N—R and n=1;
(m) A in general Formula (II) is N—R and n=2;
(n) A in general Formula (III) is N—R and m=2; and
(o) A in general Formula (III) is N—R and m=3.

In the general formulas (a) to (o) shown in FIG. 3A, R1, R2, R3, R4, R1/1, R1/2, R1/3, RN/1, RN/2, and RN/3 can represent, independently from each other, an optionally substituted linear or branched C1 to C6 alkyl, an optionally substituted C3 to C6 cycloalkyl, or an optionally substituted C3 to C6 heterocycloalkyl.

In a more preferred variant, in the organometallic compound represented by any one of the formulas (a) to (o) of FIG. 3A, the alkyl ligand R1, R1/1, R1/2, R1/3, RN/1, RN/2, and RN/3 is an optionally substituted linear or branched C1 to C6 alkyl, an optionally substituted C3 to C6 cycloalkyl, or an optionally substituted C3 to C6 heterocycloalkyl, in particular an optionally substituted linear C1 to C6 alkyl, an optionally substituted C3 to C6 cycloalkyl, or an optionally substituted C3 to C6 heterocycloalkyl.

In a more preferred variant, in the organometallic compound represented by any one of the formulas (a) to (o) of FIG. 3A, the alkyl ligand R1, R1/1, R1/2, R1/3, RN/1, RN/2, and RN/3 is an optionally substituted linear or branched C1 to C5 alkyl, an optionally substituted C3 to C5 cycloalkyl, or an optionally substituted C3 to C5 heterocycloalkyl, in particular an optionally substituted linear C1 to C5 alkyl, an optionally substituted C3 to C5 cycloalkyl, or an optionally substituted C3 to C5 heterocycloalkyl.

In a more preferred variant, in the organometallic compound represented by any one of the formulas (a) to (o) of FIG. 3A, the alkyl ligand R1, R1/1, R1/2, R1/3, RN/1, RN/2, and RN/3 is an optionally substituted linear or branched C1 to C4 alkyl, an optionally substituted C3 to C4 cycloalkyl, or an optionally substituted C3 to C4 heterocycloalkyl, in particular an optionally substituted linear C1 to C4 alkyl, an optionally substituted C3 or C4 cycloalkyl, or an optionally substituted C3 or C4 heterocycloalkyl.

In a further preferred variant, in the organometallic compound represented by any one of the formulas (a) to (o) of FIG. 3A, the alkyl ligand R1, R1/1, R1/2, R1/3, RN/1, RN/2, and RN/3 is an optionally substituted linear or branched C1 to C3 alkyl, an optionally substituted C3 cycloalkyl, or an optionally substituted C3 heterocycloalkyl, in particular an optionally substituted linear C1 to C3 alkyl, an optionally substituted C3 cycloalkyl, or an optionally substituted C3 heterocycloalkyl.

In an even more preferred variant, in the organometallic compound represented by any one of the formulas (a) to (o) of FIG. 3A, the alkyl ligand R1, R1/1, R1/2, R1/3, RN/1, RN/2, and RN/3 is an optionally substituted C1 or C2 alkyl.

FIG. 3B is a set of chemical structure diagrams (p) to (ad) representing single, linear, and cyclic organometallic compounds for dry photoresists or hardmasks for EUV lithography, wherein Bi is in the oxidation state (V), according to some embodiments. In FIG. 3B:
(p) A in general Formula (IV) is O;
(q) A in general Formula (VI) is O and n=1;
(r) A in general Formula (VI) is O and n=2;
(s) A in general Formula (VII) is O and m=2;
(t) A in general Formula (VII) is O and m=3;
(u) A in general Formula (IV) is S;
(v) A in general Formula (VI) is S and n=1;
(w) A in general Formula (VI) is S and n=2;
(x) A in general Formula (VII) is S and m=2;
(y) A in general Formula (VII) is S and m=3;
(z) A in general Formula (IV) is N—R;
(aa) A in general Formula (VI) is N—R and n=1;
(ab) A in general Formula (VI) is N—R and n=2;
(ac) A in general Formula (VII) is N—R and m=2; and
(ad) A in general Formula (VII) is N—R and m=3.

In the general formulas (p) to (ad) shown in FIG. 3B, where the bismuth element is Bi(V), each of R1, R2, R3, R4, R5, R6, R7, R8, R1/1, R2/1, R3/1, R1/2, R2/2, R3/2, R1/3, R2/3, R3/3, RN/1, RN/2, and RN/3 can represent, independently from each other, an optionally substituted linear or branched C1 to C6 alkyl, optionally substituted C3 to C6 cycloalkyl, or an or an optionally substituted heterocycloalkyl.

In a more preferred variant, in the organometallic compound represented by any one of the formulas (p) to (ad) of FIG. 3B, the alkyl ligand R1, R2, R3, R1/1, R2/1, R3/1, R1/2, R2/2, R3/2, R1/3, R2/3, R3/3, RN/1, RN/2, and RN/3 is an optionally substituted linear or branched C1 to C6 alkyl, an optionally substituted C3 to C6 cycloalkyl, or an optionally substituted C3 to C6 heterocycloalkyl, in particular an optionally substituted linear C1 to C6 alkyl, an optionally substituted C3 to C6 cycloalkyl, or an optionally substituted C3 to C6 heterocycloalkyl.

In a more preferred variant, in the organometallic compound represented by any one of the formulas (p) to (ad) of FIG. 3B, the alkyl ligand R1, R2, R3, R1/1, R2/1, R3/1, R1/2, R2/2, R3/2, R1/3, R2/3, R3/3, RN/1, RN/2, and RN/3 is an optionally substituted linear or branched C1 to C5 alkyl, an optionally substituted C3 to C5 cycloalkyl, or an optionally substituted C3 to C5 heterocycloalkyl, in particular an optionally substituted linear C1 to C5 alkyl, an optionally substituted C3 to C5 cycloalkyl, or an optionally substituted C3 to C5 heterocycloalkyl.

In a more preferred variant, in the organometallic compound represented by any one of the formulas (p) to (ad) of FIG. 3B, the alkyl ligand R1, R2, R3, R1/1, R2/1, R3/1, R1/2, R2/2, R3/2, R1/3, R2/3, R3/3, RN/1, RN/2, and RN/3 is an optionally substituted linear or branched C1 to C4 alkyl, an optionally substituted C3 to C4 cycloalkyl, or an optionally substituted C3 to C4 heterocycloalkyl, in particular an optionally substituted linear C1 to C4 alkyl, an optionally substituted C3 or C4 cycloalkyl, or an optionally substituted C3 or C4 heterocycloalkyl.

In a further preferred variant, in the organometallic compound represented by any one of the formulas (p) to (ad) of FIG. 3B, the alkyl ligand R1, R2, R3, R1/1, R2/1, R3/1, R1/2, R2/2, R3/2, R1/3, R2/3, R3/3, RN/1, RN/2, and RN/3 is an optionally substituted linear or branched C1 to C3 alkyl, an optionally substituted C3 cycloalkyl, or an optionally substituted C3 heterocycloalkyl, in particular an optionally substituted linear C1 to C3 alkyl, an optionally substituted C3 cycloalkyl, or an optionally substituted C3 heterocycloalkyl.

In an even more preferred variant, in the organometallic compound represented by any one of the formulas (p) to (ad) of FIG. 3B, the alkyl ligand R1, R2, R3, R1/1, R2/1, R3/1, R1/2, R2/2, R3/2, R1/3, R2/3, R3/3, RN/1, RN/2, and RN/3 is an optionally substituted C1 or C2 alkyl.

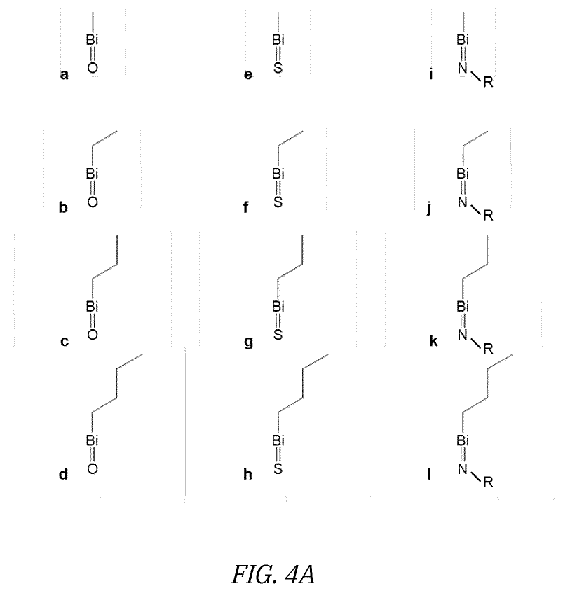

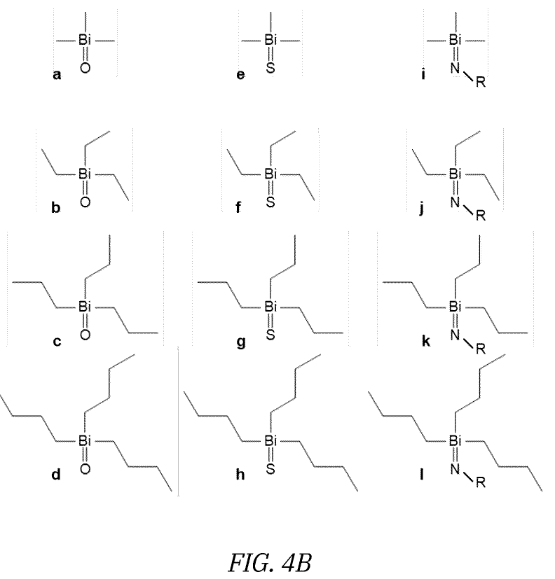

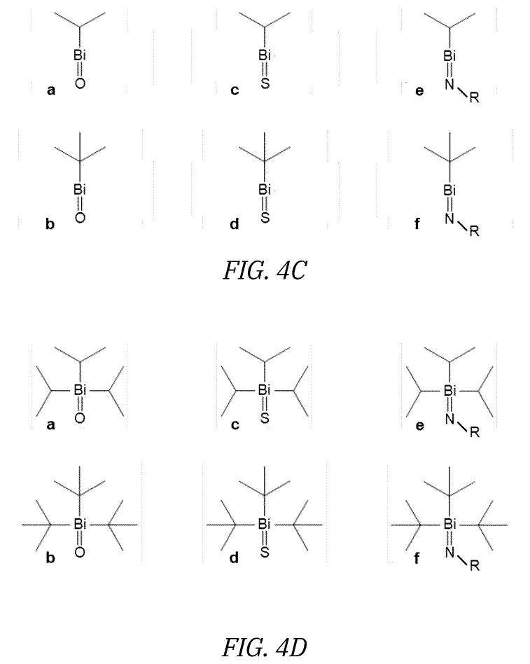

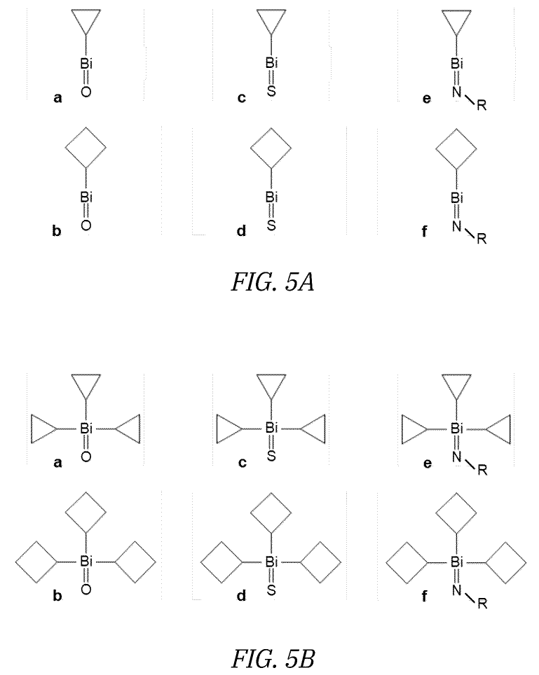

FIGS. 4A-5B are sets of chemical structure diagrams illustrating single organometallic compounds for dry photoresists or hardmasks for EUV lithography represented by general formulas (I) and (IV), according to some embodiments.

FIGS. 4A and 4B show particularly preferred single organometallic compounds represented by general formulas (I) or (IV), where Bi is in an oxidation state (III) or (V), A is O, S, or N—R, and the alkyl ligands R1, R2, and R3 are linear C1 to C4 alkyls (e.g., methyl, ethyl, propyl, or butyl).

In FIG. 4A:
(a) methylbismuthanone;
(b) ethylbismuthanone;
(c) propylbismuthanone;
(d) butylbismuthanone;
(e) methylbismuthanethione;
(f) ethylbismuthanethione;
(g) propylbismuthanethione;
(h) butylbismuthanethione;
(i) Bi-methylbismuthanimine;
(j) Bi-ethylbismuthanimine;
(k) Bi-propylbismuthanimine; and
(l) Bi-butylbismuthanimine.

In FIG. 4B:
(a) trimethyl-λ⁵-bismuthanone;
(b) triethyl-λ⁵-bismuthanone;
(c) tripropyl-λ⁵-bismuthanone;
(d) tributyl-λ⁵-bismuthanone;
(e) trimethyl-λ⁵-bismuthanethione;
(f) triethyl-λ⁵-bismuthanethione;
(g) tripropyl-λ⁵-bismuthanethione;
(h) tributyl-λ⁵-bismuthanethione;
(i) Bi,Bi,Bi-trimethyl-λ⁵-bismuthanimine;
(j) Bi,Bi,Bi-triethyl-λ⁵-bismuthanimine;
(k) Bi,Bi,Bi-tripropyl-λ⁵-bismuthanimine; and
(l) Bi,Bi,Bi-tributyl-λ⁵-bismuthanimine.

FIGS. 4C and 4D show particularly preferred single organometallic compounds represented by general formulas (I) and (IV), where Bi is in an oxidation state (III) or (V), A is O, S, or N—R, and the alkyl ligands R1, R2, and R3 are branched C3 or C4 alkyl, (e.g., isopropyl or tert-butyl).

In FIG. 4C:
(a) propan-2-ylbismuthanone;
(b) tert-butylbismuthanone;
(c) propan-2-ylbismuthanethione;
(d) tert-butylbismuthanethione;
(e) Bi-propan-2-ylbismuthanimine; and
(f) Bi-tert-butylbismuthanimine.

In FIG. 4D:
(a) tri(propan-2-yl)-λ⁵-bismuthanone;
(b) tri(tert-butyl)-λ⁵-bismuthanone;
(c) tri(propan-2-yl)-λ⁵-bismuthanethione;
(d) tri(tert-butyl)-λ⁵-bismuthanethione;
(e) Bi,Bi,Bi-tri(propan-2-yl)-λ⁵-bismuthanimine; and
(f) Bi,Bi,Bi-tri(tert-butyl)-as-bismuthanimine.

FIGS. 5A and 5B show preferred single organometallic compounds represented by general formula (I) or (IV), where Bi is in an oxidation state (III) or (V), A is O, S, or N—R, and the alkyl ligands R1, R2, and R3 are cyclic C3 or C4 alkyl (e.g., cyclopropyl or cyclobutyl).

In FIG. 5A:
(a) cyclopropylbismuthanone;
(b) cyclobutylbismuthanone;
(c) cyclopropylbismuthanethione;
(d) cyclobutylbismuthanethione;
(e) Bi-cyclopropylbismuthanimine; and
(f) Bi-cyclobutylbismuthanimine.

In FIG. 5B:
(a) tricyclopropyl-λ⁵-bismuthanone;
(b) tricyclobutyl-λ⁵-bismuthanone;
(c) tricyclopropyl-λ⁵-bismuthanethione;
(d) tricyclobutyl-λ⁵-bismuthanethione;
(e) Bi,Bi,Bi-tricyclopropyl-λ⁵-bismuthanimine; and
(f) Bi,Bi,Bi-tricyclobutyl-λ⁵-bismuthanimine.

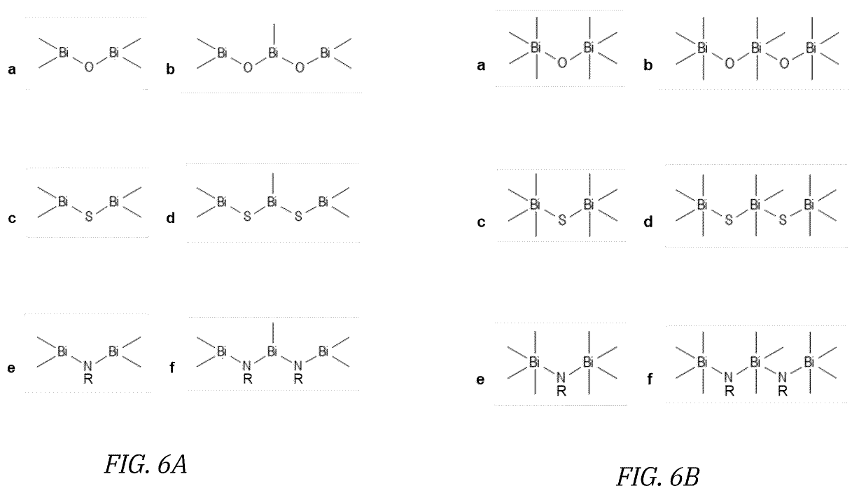

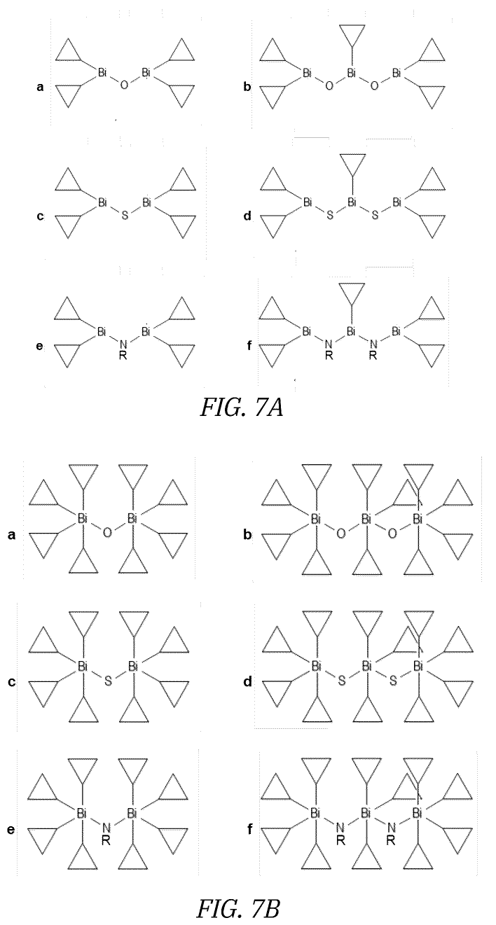

FIGS. 6A-7B are sets of chemical structure diagrams illustrating linear organometallic compounds for dry photoresists or hardmasks for EUV lithography represented by general formulas (II), (V), and (VI), according to some embodiments.

FIGS. 6A and 6B show particularly preferred linear organometallic compounds represented by general formulas (II), (V), or (VI), where Bi is in an oxidation state (III) or (V); A is O, S, or N—R; n is 1 or 2; and the alkyl ligands R1, R2, R3, R4, R5, R6, R7, and R8 are methyl groups. In further embodiments, the alkyl ligands can by ethyl, propyl, or butyl.

In FIG. 6A:
(a) dimethylbismuthanyloxy(dimethyl)bismuthane;
(b) bis(dimethylbismuthanyloxy)(methyl)bismuthane;
(c) dimethylbismuthanylsulfanyl(dimethyl)bismuthane;
(d) bis(dimethylbismuthanylsulfanyl)(methyl)bismuthane;
(e) bis(dimethylbismuthanyl)amine; and
(f) dimethylbismuthanylamino(methyl)bismuthanyl(dimethylbismuthanyl)amine.

In FIG. 6B:
(a) tetramethyl-λ⁵-bismuthanyloxy(tetramethyl)-λ⁵-bismuthane;
(b) bis(tetramethyl-λ⁵-bismuthanyloxy)(trimethyl)-λ⁵-bismuthane;
(c) tetramethyl-λ⁵-bismuthanylsulfanyl(tetramethyl)-λ⁵-bismuthane;
(d) bis(tetramethyl-λ⁵-bismuthanylsulfanyl)(trimethyl)-λ⁵-bismuthane;
(e) bis(tetramethyl-λ⁵-bismuthanyl)amine; and
(f) tetramethyl-λ⁵-bismuthanylamino(trimethyl)-λ⁵-bismuthanyl)(tetramethyl-λ⁵-bismuthanyl)amine.

FIGS. 7A and 7B show preferred linear organometallic compounds represented by general formula (II), (V), or (VI), where Bi in an oxidation state (III) or (V); A is O, S, or N—R, n is 1 or 2, and the alkyl ligands R1, R2, R3, R4, R5, R6, R7, and R8 are cyclopropyl. In further embodiments, the alkyl ligands can be cyclobutyl.

In FIG. 7A:
(a) dicyclopropylbismuthanyloxy(dicyclopropyl)bismuthane;
(b) bis(dicyclopropylbismuthanyloxy)(cyclopropyl)bismuthane;
(c) dicyclopropylbismuthanylsulfanyl(dicyclopropyl)bismuthane;
(d) bis(dicyclopropylbismuthanylsulfanyl)(cyclopropyl)bismuthane;
(e) bis(dicyclopropylbismuthanyl)amine; and
(f) dicyclopropylbismuthanylamino(cyclopropyl)bismuthanyl(di-cyclopropylbismuthanyl)amine.

In FIG. 7B:
(a) tetracyclopropyl-λ⁵-bismuthanyloxy(tetracyclopropyl)-λ⁵-bismuthane;
(b) bis(tetracyclopropyl-λ⁵-bismuthanyloxy)(tricyclopropyl)-λ⁵-bismuthane;
(c) tetracyclopropyl-λ⁵-bismuthanylsulfanyl(tetracyclopropyl)-λ⁵-bismuthane;
(d) bis(tetracyclopropyl-λ⁵-bismuthanylsulfanyl)(tricyclopropyl)-λ⁵-bismuthane; (e) bis(tetracyclopropyl-λ⁵-bismuthanyl)amine; and
(f) tetracyclopropyl-λ⁵-bismuthanylamino(tricyclopropyl-λ⁵-bismuthanyl)(tetracyclopropyl-λ⁵-bismuthanyl)amine.

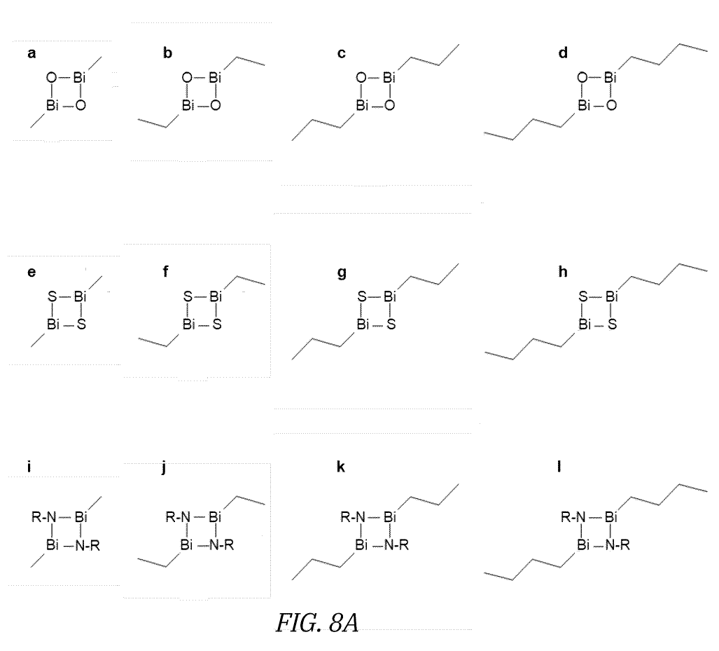

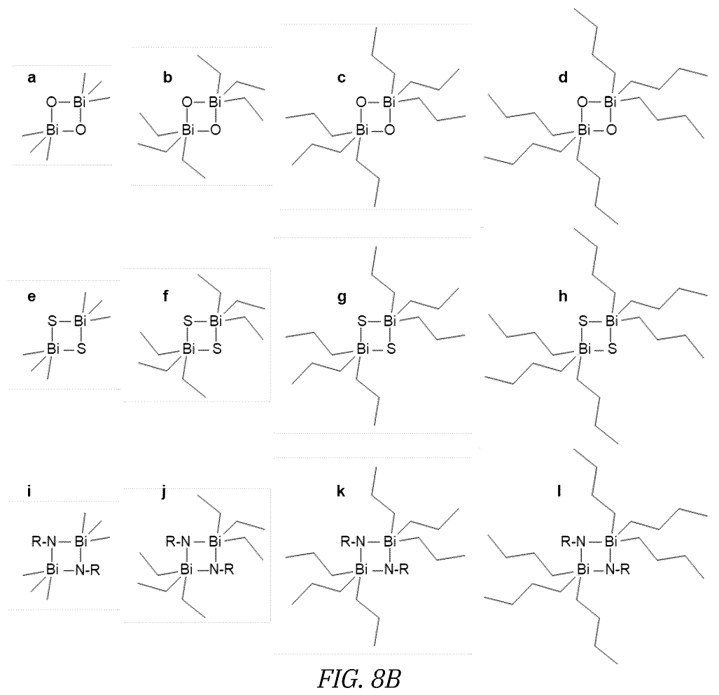

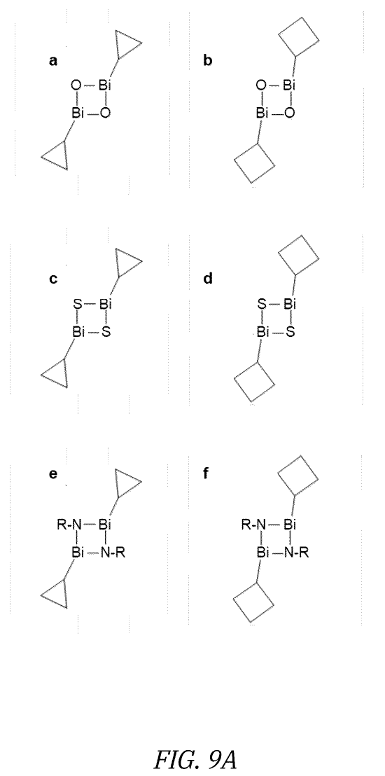

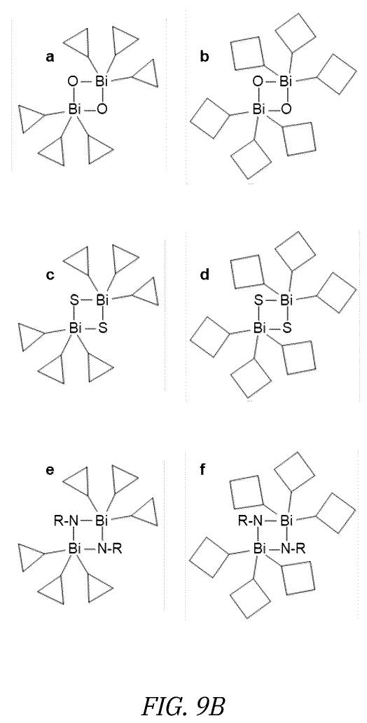

FIGS. 8A-9B are sets of chemical structure diagrams illustrating cyclic organometallic compounds for dry photoresists or hardmasks for EUV lithography represented by general formulas (III) and (VII), according to some embodiments.

FIGS. 8A and 8B show particularly preferred cyclic organometallic compounds represented by general formula (III) or (VII), where Bi is in an oxidation state (III) or (V); A is O, S, or N—R; m is 2; and the alkyl ligands R1/1, R2/1, R3/1, R1/2, R2/2, and R3/2 are methyl, ethyl, propyl, or butyl.

In FIG. 8A:
(a) 2,4-dimethyl-1,3,2,4-dioxadibismetane;
(b) 2,4-diethyl-1,3,2,4-dioxadibismetane;
(c) 2,4-dipropyl-1,3,2,4-dioxadibismetane;
(d) 2,4-dibutyl-1,3,2,4-dioxadibismetane;
(e) 2,4-dimethyl-1,3,2,4-dithiadibismetane;
(f) 2,4-diethyl-1,3,2,4-dithiadibismetane;
(g) 2,4-dipropyl-1,3,2,4-dithiadibismetane;
(h) 2,4-dibutyl-1,3,2,4-dithiadibismetane;
(i) 2,4-dimethyl-1,3,2,4-diazadibismetane;
j) 2,4-diethyl-1,3,2,4-diazadibismetane;
(k) 2,4-dipropyl-1,3,2,4-diazadibismetane; and
(l) 2,4-dibutyl-1,3,2,4-diazadibismetane.

In FIG. 8B:
(a) 2,2,2,4,4,4-hexamethyl-1,3,2,4-dioxadi-λ⁵-bismetane;
(b) 2,2,2,4,4,4-hexaethyl-1,3,2,4-dioxadi-λ⁵-bismetane;
(c) 2,2,2,4,4,4-hexapropyl-1,3,2,4-dioxadi-λ⁵-bismetane;
(d) 2,2,2,4,4,4-hexabutyl-1,3,2,4-dioxadi-as-bismetane;
(e) 2,2,2,4,4,4-hexamethyl-1,3,2,4-dithiadi-λ⁵-bismetane;
(f) 2,2,2,4,4,4-hexaethyl-1,3,2,4-dithiadi-λ⁵-bismetane;
(g) 2,2,2,4,4,4-hexapropyl-1,3,2,4-dithiadi-λ⁵-bismetane;
(h) 2,2,2,4,4,4-hexabutyl-1,3,2,4-dithiadi-λ⁵-bismetane;
(i) 2,2,2,4,4,4-hexamethyl-1,3,2,4-diazadi-λ⁵-bismetane;
(j) 2,2,2,4,4,4-hexaethyl-1,3,2,4-diazadi-λ⁵-bismetane;
(k) 2,2,2,4,4,4-hexapropyl-1,3,2,4-diazadi-λ⁵-bismetane; and
(l) 2,2,2,4,4,4-hexabutyl-1,3,2,4-diazadi-λ⁵-bismetane.

FIGS. 9A and 9B show preferred cyclic organometallic compounds represented by general formula (III) or (VII), where Bi in an oxidation state (III) or (V); A is O, S, or N—R, m is 2; and the alkyl ligands R1/1, R2/1, R3/1, R1/2, R2/2, and R3/2 are cyclopropyl or cyclobutyl.

In FIG. 9A:
(a) 2,4-dicyclopropyl-1,3,2,4-dioxadibismetane;
(b) 2,4-dicyclobutyl-1,3,2,4-dioxadibismetane;
(c) 2,4-dicyclopropyl-1,3,2,4-dithiadibismetane;
(d) 2,4-dicyclobutyl-1,3,2,4-dithiadibismetane;
(e) 2,4-dicyclopropyl-1,3,2,4-diazabismetane; and
(f) 2,4-dicyclobutyl-1,3,2,4-diazadibismetane.

In FIG. 9B:
(a) 2,2,2,4,4,4-hexacyclopropyl-1,3,2,4-dioxadi-λ⁵-bismetane;
(b) 2,2,2,4,4,4-hexacyclobutyl-1,3,2,4-dioxadi-λ⁵-bismetane;
(c) 2,2,2,4,4,4-hexacyclopropyl-1,3,2,4-dithiadi-λ⁵-bismetane;
(d) 2,2,2,4,4,4-hexacyclobutyl-1,3,2,4-dithiadi-λ⁵-bismetane;
(e) 2,2,2,4,4,4-hexacyclopropyl-1,3,2,4-diazadi-λ⁵-bismetane; and
(f) 2,2,2,4,4,4-hexacyclobutyl-1,3,2,4-diazadi-λ⁵-bismetane.

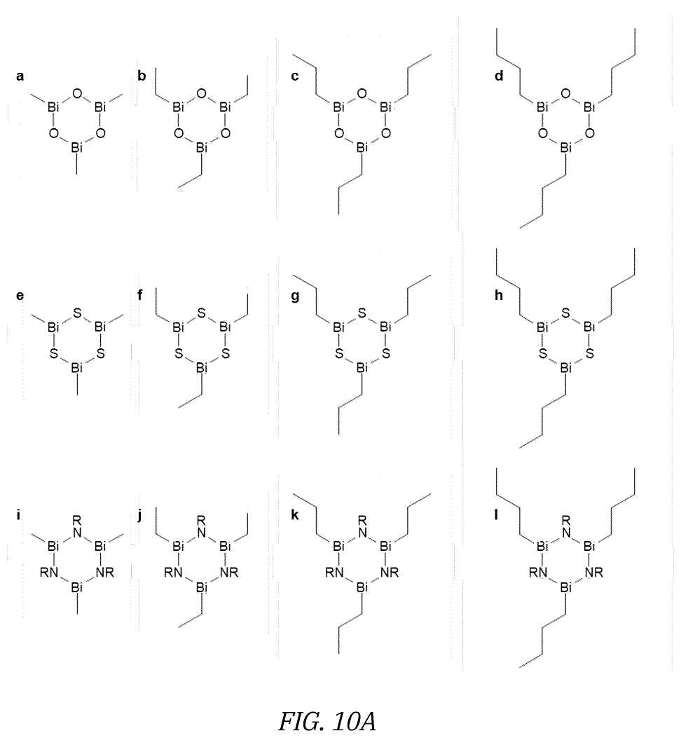

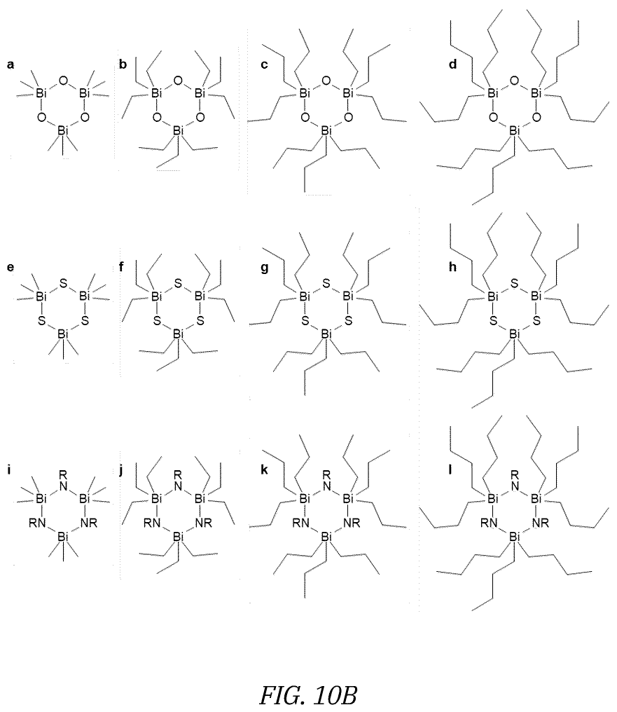

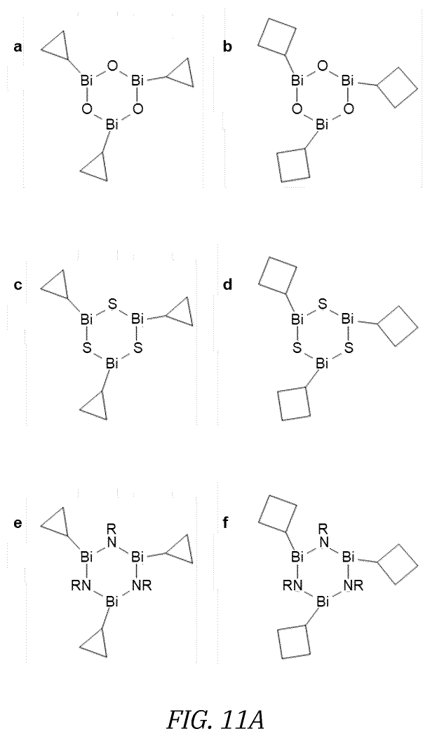

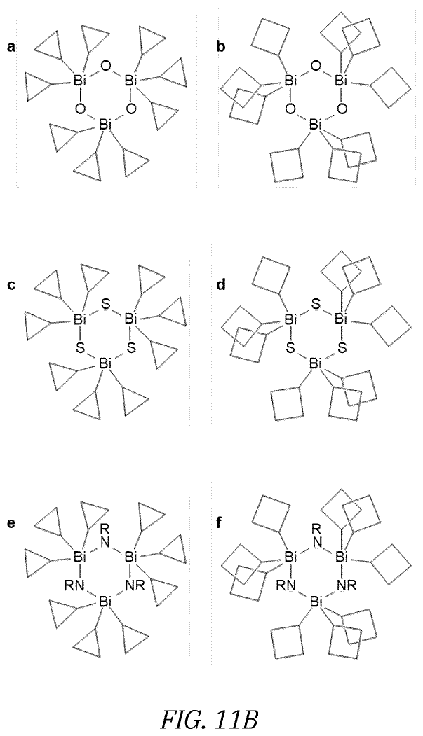

FIGS. 10A-11B are sets of chemical structure diagrams illustrating cyclic organometallic compounds for dry photoresists or hardmasks for EUV lithography represented by general formulas (III) and (VII), according to some embodiments.

FIGS. 10A and 10B show particularly preferred cyclic organometallic compounds represented by general formula (III) or (VII), where Bi in an oxidation state (III) or (V); A is O, S, N—R, m is 3; and the alkyl ligands R1/1, R2/1, R3/1, R1/2, R2/2, and R3/2 are methyl, ethyl, propyl, or butyl.

In FIG. 10A:
(a) 2,4,6-trimethyl-1,3,5,2,4,6-trioxatribismane;
(b) 2,4,6-triethyl-1,3,5,2,4,6-trioxatribismane;
(c) 2,4,6-tripropyl-1,3,5,2,4,6-trioxatribismane;
(d) 2,4,6-tributyl-1,3,5,2,4,6-trioxatribismane;
(e) 2,4,6-trimethyl-1,3,5,2,4,6-trithiatribismane;
(f) 2,4,6-triethyl-1,3,5,2,4,6-trithiatribismane;
(g) 2,4,6-tripropyl-1,3,5,2,4,6-trithiatribismane;
(h) 2,4,6-tributyl-1,3,5,2,4,6-trithiatribismane;
(i) 2,4,6-trimethyl-1,3,5,2,4,6-triazatribismane;
(j) 2,4,6-triethyl-1,3,5,2,4,6-triazatribismane;
(k) 2,4,6-tripropyl-1,3,5,2,4,6-triazatribismane; and
(l) 2,4,6-tributyl-1,3,5,2,4,6-triazatribismane.

In FIG. 10B:
(a) 2,2,2,4,4,4,6,6,6-nonamethyl-1,3,5,2,4,6-trioxatri-λ⁵-bismane;
(b) 2,2,2,4,4,4,6,6,6-nonaethyl-1,3,5,2,4,6-trioxatri-λ⁵-bismane;
(c) 2,2,2,4,4,4,6,6,6-nonapropyl-1,3,5,2,4,6-trioxatri-λ⁵-bismane;
(d) 2,2,2,4,4,4,6,6,6-nonabutyl-1,3,5,2,4,6-trioxatri-λ⁵-bismane;
(e) 2,2,2,4,4,4,6,6,6-nonamethyl-1,3,5,2,4,6-trithiatri-λ⁵-bismane;
(f) 2,2,2,4,4,4,6,6,6-nonaethyl-1,3,5,2,4,6-trithiatri-λ⁵-bismane;
(g) 2,2,2,4,4,4,6,6,6-nonapropyl-1,3,5,2,4,6-trithiatri-λ⁵-bismane;
(h) 2,2,2,4,4,4,6,6,6-nonabutyl-1,3,5,2,4,6-trithiatri-λ⁵-bismane;
(i) 2,2,2,4,4,4,6,6,6-nonamethyl-1,3,5,2,4,6-triazatri-λ⁵-bismane;
(j) 2,2,2,4,4,4,6,6,6-nonaethyl-1,3,5,2,4,6-triazatri-λ⁵-bismane;
(k) 2,2,2,4,4,4,6,6,6-nonapropyl-1,3,5,2,4,6-triazatri-λ⁵-bismane; and
(l) 2,2,2,4,4,4,6,6,6-nonabutyl-1,3,5,2,4,6-triazatri-λ⁵-bismane.

FIGS. 11A and 11B show preferred cyclic organometallic compounds represented by general formula (III) or (VII), where Bi in an oxidation state (III) or (V); A is O, S, N—R, m is 3; and the alkyl ligands R1/1, R2/1, R3/1, R1/2, R2/2, and R3/2 are cyclopropyl or cyclobutyl.

In FIG. 11A:
(a) 2,4,6-tricyclopropyl-1,3,5,2,4,6-trioxatribismane;
(b) 2,4,6-tricyclobutyl-1,3,5,2,4,6-trioxatribismane;
(c) 2,4,6-tricylcopropyl-1,3,5,2,4,6-trithiatribismane;
(d) 2,4,6-tricylcobutyl-1,3,5,2,4,6-trithiatribismane;
(e) 2,4,6-tricylcopropyl-1,3,5,2,4,6-triazatribismane; and
(f) 2,4,6-tricylcobutyl-1,3,5,2,4,6-triazatribismane.

In FIG. 11B:
(a) 2,2,2,4,4,4,6,6,6-nonacyclopropyl-1,3,5,2,4,6-trioxatri-λ⁵-bismane;
(b) 2,2,2,4,4,4,6,6,6-nonacyclobutyl-1,3,5,2,4,6-trioxatri-λ⁵-bismane;
(c) 2,2,2,4,4,4,6,6,6-nonacylcopropyl-1,3,5,2,4,6-trithiatri-λ⁵-bismane;
(d) 2,2,2,4,4,4,6,6,6-nonacylcobutyl-1,3,5,2,4,6-trithiatri-λ⁵-bismane;
(e) 2,2,2,4,4,4,6,6,6-nonacylcopropyl-1,3,5,2,4,6-triazatri-λ⁵-bismane; and
(f) 2,2,2,4,4,4,6,6,6-nonacylcobutyl-1,3,5,2,4,6-triazatri-λ⁵-bismane.

When A is N—R, in the aforementioned preferred organometallic compounds of the general formulas (I) to (VII), R or the R-group (RN/1, RN/2, or RN/3) is either H; a linear C1 to C4 alkyl, such as methyl, ethyl, propyl, or butyl; or a branched C3 or C4 alkyl, such as isopropyl or tert-butyl; or a cyclic C3 or C4 alkyl, such as cyclopropyl or cyclobutyl. Preferably, R is identical to the alkyl ligand(s) of said organometallic compounds.

In the disclosed organometallic compounds for dry photoresists or hardmasks for EUV lithography, comprising Bi; one of a terminal oxo ligand, a terminal thioxo ligand, a terminal imino ligand, an oxygen bridging ligand, a sulfur bridging ligand, or an aminoalkyl bridging ligand; and C1 to C4 alkyl ligands, the molecular composition and structure can be advantageously selected such that:
(i) At room temperature, the molecule's diffusion coefficient should be low. To that end, the molecule's composition and structure can be selected such that its melting-point temperature high. The terminal oxo ligand, terminal thioxo ligand, terminal imino ligand, oxygen bridging ligand, sulfur bridging ligand, or amino bridging ligand causes the molecule's melting-point temperature to be substantially above room temperature, even when the alkyl ligands are methyl (C1). By increasing the alkyl ligand length from C1 to C4, the melting-point temperature can be further tuned (e.g., about 180 K).
(ii) Upon EUV exposure, the Bi—C bonds and the N—C bonds dissociate, and the inorganic Bi═O clusters, Bi—O clusters, Bi═S clusters, Bi—S clusters, Bi═N clusters, or Bi—N clusters crosslink. The clusters are non-volatile.
(iii) The alkyl ligands can be chosen such that the reaction products upon EUV exposure, aside from the Bi═O clusters, Bi—O clusters, Bi═S clusters, Bi—S clusters, Bi═N clusters, or Bi—N clusters, are volatile at processing conditions in the EUV scanner. Therefore, C1 to C4 alkyl ligands are preferred.
(iv) The shrink due to species volatilization upon EUV exposure should be moderate. Therefore, C1 to C3 alkyl ligands are still more preferred as alkyl ligands.

With respect to the diffusion coefficient (i), the diffusion coefficient in solids is generally found to be well predicted by an Arrhenius-type dependance exp(E_{A}/kT), where the activation energy for diffusion E_{A} is—first-order approximation—proportional to the melting-point temperature of the solid. It was found that due to the exponential correlation of diffusion coefficient and melting-point temperature, the organometallic molecules' melting-point temperature can be of crucial importance for selecting preferred organometallic molecules.

Therefore, preferred are organometallic molecules that have a high melting-point temperature and that are therefore solids with a very-low vapor pressure at vacuum conditions found in the EUV scanner.

A reasonable estimate for the melting-point temperature T_{M} of the class of bismuthanone organometallic molecules for dry photoresists or hardmasks for EUV lithography can be obtained by considering the boiling-point temperature T_{B} of the organometallic molecule series tetraalkylstannane, trialkylstibane, and trialkylbismuthane, and by realizing that for example, the melting-point temperature T_{M} of dimethyloxotin is about 380° C.

For tetramethylstannane and tetrapropylstannane, the respective boiling-point temperatures T_{B} are about 80° C. and 220° C., for trimethylstibane and tripropylstibane the respective boiling-point temperatures T_{B} are about 80° C. and 210° C., and for trimethylbismuthane and tripropylbismuthane the respective boiling-point temperatures T_{B} are about 100° C. and 220° C. It was determined experimentally that tetraalkylstannane, trialkylstibane, and trialkylbismuthane organometallic molecules behave similarly. It was also determined experimentally that the boiling-point temperatures T_{B} increase at least about 120 K for the organometallic molecules with propyl ligands compared to the organometallic molecules with methyl ligands.

Based on these observations, the melting-point temperature T_{M} was estimated to be about 380° C. when R is a C1 alkyl (e.g., trimethyl-λ⁵-bismuthanone; 2,2,2,4,4,4-hexamethyl-1,3,2,4-dioxadi-λ⁵-bismetane; and 2,2,2,4,4,4,6,6,6-nonamethyl-1,3,5,2,4,6-trioxatri-λ⁵-bismane), about 440° C. when R is a C2 alkyl (e.g., triethyl-λ⁵-bismuthanone; 2,2,2,4,4,4-hexaethyl-1,3,2,4-dioxadi-λ⁵-bismetane; and 2,2,2,4,4,4,6,6,6-nonaethyl-1,3,5,2,4,6-trioxatri-λ⁵-bismane), about 500° C. when R is a C3 alkyl (e.g., tripropyl-λ⁵-bismuthanone; tri(propan-2-yl)-λ⁵-bismuthanone; tricyclopropyl-λ⁵-bismuthanone; 2,2,2,4,4,4-hexapropyl-1,3,2,4-dioxadi-λ⁵-bismetane; 2,2,2,4,4,4-hexacyclopropyl-1,3,2,4-dioxadi-λ⁵-bismetane; 2,2,2,4,4,4,6,6,6-nonapropyl-1,3,5,2,4,6-trioxatri-λ5-bismane; and 2,2,2,4,4,4,6,6,6-nonacyclopropyl-1,3,5,2,4,6-trioxatri-λ⁵-bismane), and about 560° C. when R is a C4 alkyl (e.g., tributyl-λ⁵-bismuthanone; tri(tert-butyl)-λ⁵-bismuthanone; tricyclobutyl-λ⁵-bismuthanone; 2,2,2,4,4,4-hexabutyl-1,3,2,4-dioxadi-λ⁵-bismetane; 2,2,2,4,4,4-hexacyclobutyl-1,3,2,4-dioxadi-λ⁵-bismetane; 2,2,2,4,4,4,6,6,6-nonabutyl-1,3,5,2,4,6-trioxatri-λ⁵-bismane; and 2,2,2,4,4,4,6,6,6-nonacylcobutyl-1,3,5,2,4,6-trioxatri-λ⁵-bismane).

Sulfide compounds generally have a similar (but slightly lower) melting-point temperature T_{M} than the corresponding oxides. For example, Bi₂S₃ and Bi₂O₃ have melting-point temperatures T_{M} of about 775° C. and about 817° C., respectively. Therefore, it was reasonable to assume that corresponding bismuthanone, and λ⁵-bismuthanone, bismuthanethione, λ⁵-bismuthanethione, bismuthanimine, λ⁵-bismuthanimine, 1,3,2,4-dioxadibismetane, 1,3,2,4-dioxadi-λ⁵-bismetane, 1,3,5,2,4,6-trioxatribismane, 1,3,5,2,4,6-trioxatri-λ⁵-bismane, 1,3,2,4-dithiadibismetane, 1,3,2,4-dithiadi-λ⁵-bismetane, 1,3,5,2,4,6-trithiatribismane, 1,3,5,2,4,6-trithiatri-λ⁵-bismane, 1,3,2,4-diazadibismetane, 1,3,2,4-diazadi-λ⁵-bismetane, 1,3,5,2,4,6-triazatribismane, and 1,3,5,2,4,6-triazatri-λ⁵-bismaneorganometallic molecules for dry photoresists or hardmasks for EUV lithography have similar melting-point temperatures T_{M}.

In a preferred embodiment, the organometallic compounds for dry photoresists or hardmasks for EUV lithography have a melting point of at least 100° C. In a more preferred embodiment, the melting point of the organometallic compounds lies within a range of 300° C. to 600° C. Such organometallic compounds are solids with a very-low vapor pressure at vacuum conditions found in the EUV scanner. Therefore, from a diffusion-coefficient perspective, an alkyl ligand or R-group in the organometallic compounds as defined above in detail may preferably be a linear or branched C1 to C4 alkyl or cyclic C1 to C4 alkyl, more preferably a linear or branched C2 to C4 alkyl or cyclic C3 or C4 alkyl.

With respect to bond dissociation (ii), (Bi—C), ab initio gas phase simulations of the bond energies (the homolytic dissociation energies) of organobismuth(V) molecules were carried out at the Perdew-Burke-Esnzerof and double-zeta valence polarizations (PBE/DZVP) level of theory. These simulations can provide a detailed understanding of the expected relative sensitivities of the organometallic molecules for dry photoresists or hardmasks for EUV lithography. In the chemical formulas below, Me refers to a methyl group, Et refers to an ethyl group, Pr refers to a propyl group, Bu refers to a butyl group, iPr refers to an iso-propyl group, tBu refers to a tert-butyl group, cPr refers to a cyclopropyl group, and cBu refers to a cyclobutyl group.

The simulations of the bond energies of trimethyl-λ⁵-bismuthanone, triethyl-λ⁵-bismuthanone, tripropyl-λ⁵-bismuthanone, and tributyl-λ⁵-bismuthanone (FIG. 4B) yielded:

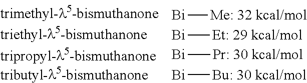

The simulations of the bond energies of tri(propan-2-yl)-λ⁵-bismuthanone and tri(tert-butyl)-λ⁵-bismuthanone (FIG. 4D) yielded:

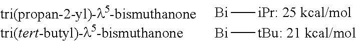

Due to their higher bond energies, the compounds shown in FIG. 4B may be preferable to those shown in FIG. 4D.

The simulations of the bond energies of cyclopropyldimethyl-λ⁵-bismuthanone, tricyclopropyl-λ⁵-bismuthanone, cyclobutyldimethyl-λ⁵-bismuthanone, and tricyclobutyl-λ⁵-bismuthanone (FIG. 5B) yielded:

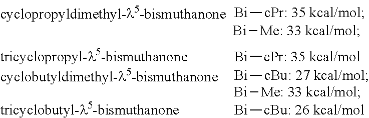

Based on the above bond energies determined for the series of λ⁵-bismuthanethione molecules shown in FIGS. 4B, 4D, and 5B, it was found that the bond energy of the “bismuthanthione”-type molecule is, within experimental uncertainty, identical to the corresponding “bismuthanone”-type molecule.

The organometallic compounds for dry photoresists or hardmasks for EUV lithography having 4-member cycles (FIGS. 8B and 9B) or 6-member cycles (FIGS. 10B and 11B), have similar Bi-alkyl bond energies to the corresponding “bismuthanone”-type molecules shown in FIGS. 4B and 5B, respectively.

Organometallic compounds having bond energies below 30 kcal/mol (e.g., the compounds shown in FIG. 4D) can be less stable. Therefore, the organometallic compounds with bond energies larger than about 30 kcal/mol may be preferred in some embodiments.

In some embodiments, from a bond-dissociation perspective, the alkyl ligand(s) or R group(s) in the organometallic compounds as defined above in detail may preferably be a linear C1 to C4 alkyl, an isobutyl (branched C4 alkyl), or a cyclic C3 alkyl. For example, methyl (C1 alkyl) or cyclopropyl (cyclic C3 alkyl) may be preferred. In further embodiments, isopropyl (branched C3 alkyl), tert-butyl (C4 branched alkyl), sec-butyl (branched C4 alkyl) and cyclobutyl (cyclic C4 alkyl) are less preferred.

With respect to reaction products (iii), upon EUV exposure, the Bi—C bonds and N—C bonds in the organometallic molecules dissociate, the inorganic Bi═O clusters, Bi═S clusters, Bi—O cluster, Bi—S clusters, Bi═N clusters, and Bi—N clusters crosslink (the clusters are non-volatile), and the organic radicals pairwise react with each other. For example, with trimethyloxobismuthane, the decomposition chemistry can proceed by: n C₃H₉OBi→(BiO)ₙ+3n/2 C₂H₆. With trimethyloxobismuthane, methyl radicals pairwise react to form ethane. In another example, with tricyclobutyloxobismuthane, the decomposition chemistry can proceed by: n C₁₂H₂₁OBi→(BiO)ₙ+3n/2 C₈H₁₄. With tricyclobutyloxobismuthane, cyclobutyl radicals pairwise react with each other to form cyclobutylcyclobutane. Examples of organic products formed by pairwise radical reactions in some embodiments are as follows:

When R is methyl (C1 alkyl), the pairwise radical reaction product is ethane (C2), which has an ambient-pressure boiling-point temperature T_{B} of −89° C. and a room temperature vapor pressure of about 4200 kPa. When R is ethyl (C2 alkyl), the pairwise radical reaction product is butane (C4), which has an ambient-pressure boiling-point temperature T_{B} of −1° C. and a room temperature vapor pressure of about 220 kPa.

When R is propyl (C3 alkyl), the pairwise radical reaction product is hexane (C6), which has an ambient-pressure boiling-point temperature T_{B} of 69° C. and a room temperature vapor pressure of about 20 kPa. When R is isopropyl (C3 alkyl), the pairwise radical reaction product is 2,4-dimethylpentane (C6), which has an ambient-pressure boiling-point temperature T_{B} of 80° C. and a room temperature vapor pressure of about 10 kPa. When R is cyclopropyl (C3 alkyl), the pairwise radical reaction product is cyclopropylcyclopropane (C6), which has an ambient-pressure boiling-point temperature T_{B} of about 70° C. and a room temperature vapor pressure of about 20 kPa.

When R is butyl (C4 alkyl), the pairwise radical reaction product is octane (C8), which has an ambient-pressure boiling-point temperature T_{B} of 126° C. and a room temperature vapor pressure of about 2 kPa. When R is isobutyl (C4 alkyl), the pairwise radical reaction product is 2,2,4,4-tetramethylpentane (C8), which has an ambient-pressure boiling-point temperature T_{B} of 122° C. and a room temperature vapor pressure of about 2 kPa. When R is cyclobutyl (C4 alkyl), the pairwise radical reaction product is cyclobutylcyclobutane (C8) which has an ambient-pressure boiling-point temperature T_{B} of about 130° C. and a room temperature vapor pressure of about 2 kPa.

EUV production scanners, e.g., ASML TWINSCAN NXE:3400C (manufactured by ASML Holding N.V.), typically have a background pressure of about 1 Pa. Therefore, linear or branched C2 to C8 alkyl molecules and cyclic C6 to C8 alkyl molecules are volatile at processing conditions in the EUV scanner. Thus, from a reaction-products perspective, the alkyl ligand or R group in the organometallic compounds as defined above in detail are preferably a linear or branched C1 to C4 alkyl or a cyclic C3 or C4 alkyl. More preferably, the at least one alkyl ligand or R group is a linear or a branched C1 to C3 alkyl or a cyclic C3 alkyl.

With respect to shrink upon EUV exposure (iv), numerical simulations of the molecular volume of organobismuth (V) molecules were performed to gain understanding of the shrink due to species volatilization upon EUV exposure of the disclosed organometallic molecules for dry photoresists or hardmasks for EUV lithography.

The ratios of Bi═O cluster volume to organobismuth (V) molecule volume of trimethyl-λ⁵-bismuthanone, triethyl-λ⁵-bismuthanone, tripropyl-λ⁵-bismuthanone, and tributyl-λ⁵-bismuthanone (FIG. 4B), and of tricyclopropyl-λ⁵-bismuthanone and tricyclobutyl-λ⁵-bismuthanone (FIG. 5B), are:

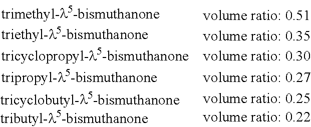

The ratios of Bi═S cluster volume to organobismuth(V) molecule volume of trimethyl-λ⁵-bismuthanethione, triethyl-λ⁵-bismuthanethione, tripropyl-λ⁵-bismuthanethione, and tributyl-λ⁵-bismuthanethione (FIG. 4B), and of tricyclopropyl-λ⁵-bismuthanethione and tricyclobutyl-_5-bismuthanethione (FIG. 5B), are:

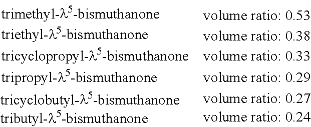

The ratios of Bi═O cluster volume to organobismuth(V) molecule volume of hexaalkyl-1,3,2,4-dioxadi-λ⁵-bismetane (m=2) and nonaalkyl-1,3,5,2,4,6-trioxatri-λ⁵-bismane (m=3) are, within experimental uncertainty, identical to the corresponding trialkyl-λ⁵-bismuthanone molecules. The ratios of Bi═S cluster volume to organobismuth(V) molecule volume of hexaalkyl-1,3,2,4-dithiadi-λ⁵-bismetane (m=2) and nonaalkyl-1,3,5,2,4,6-trithiatri-λ⁵-bismane (m=3) are, within experimental uncertainty, identical to the corresponding trialkyl-λ⁵-bismuthanethione molecules. Based on these ratios, from a shrink perspective, the at least one alkyl ligand or R group in the organometallic compound as defined above in detail may preferably be a linear or a branched C1 to C3 alkyl or a cyclic C3 alkyl. More preferably, the R group(s) is/are a C1 or C2 alkyl in some embodiments.

Due to the above-described properties/effects, the organometallic compound for dry photoresists or hardmasks for EUV lithography may preferably be selected from methylbismuthanone, ethylbismuthanone, propylbismuthanone, butylbismuthanone, methylbismuthanethione, ethylbismuthanethione, propylbismuthanethione, butylbismuthanethione, Bi-methylbismuthanimine, Bi-ethylbismuthanimine, Bi-propylbismuthanimine, Bi-butylbismuthanimine, trimethyl-λ⁵-bismuthanone, triethyl-λ⁵-bismuthanone, tripropyl-λ⁵-bismuthanone, tributyl-λ⁵-bismuthanone, trimethyl-λ⁵-bismuthanethione, triethyl-λ⁵-bismuthanethione, tripropyl-λ⁵-bismuthanethione, tributyl-λ⁵-bismuthanethione, Bi,Bi,Bi-trimethyl-λ⁵-bismuthanimine, Bi,Bi,Bi-triethyl-λ⁵-bismuthanimine, Bi,Bi,Bi-tripropyl-λ⁵-bismuthanimine, Bi,Bi,Bi-tributyl-λ⁵-bismuthanimine, propan-2-ylbismuthanone, tert-butylbismuthanone, propan-2-ylbismuthanethione, tert-butylbismuthanethione, Bi-propan-2-ylbismuthanimine, Bi-tert-butylbismuthanimine, tri(propan-2-yl)-λ⁵-bismuthanone, tri(tert-butyl)-λ⁵-bismuthanone, tri(propan-2-yl)-λ⁵-bismuthanethione, tri(tert-butyl)-λ⁵-bismuthanethione, Bi,Bi,Bi-tri(propan-2-yl)-λ⁵-bismuthanimine, Bi,Bi,Bi-tri(tert-butyl)-λ⁵-bismuthanimine, cyclopropylbismuthanone, cyclobutylbismuthanone, cyclopropylbismuthanethione, cyclobutylbismuthanethione, Bi-cyclopropylbismuthanimine, Bi-cyclobutylbismuthanimine, tricyclopropyl-λ⁵-bismuthanone, tricyclobutyl-λ⁵-bismuthanone, tricyclopropyl-λ⁵-bismuthanethione, tricyclobutyl-λ⁵-bismuthanethione, Bi,Bi,Bi-tricyclopropyl-λ⁵-bismuthanimine, Bi,Bi,Bi-tricyclobutyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane, diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, dipropylbismuthanyloxy(dipropyl)bismuthane, bis(dipropylbismuthanyloxy)(propyl)bismuthane, dipropylbismuthanylsulfanyl(dipropyl)bismuthane, bis(dipropylbismuthanylsulfanyl)(propyl)bismuthane, bis(dipropylbismuthanyl)amine, dipropylbismuthanylamino(propyl)bismuthanyl(dipropylbismuthanyl)amine, dibutylbismuthanyloxy(dibutyl)bismuthane, bis(dibutylbismuthanyloxy)(butyl)bismuthane, dibutylbismuthanylsulfanyl(dibutyl)bismuthane, bis(dibutylbismuthanylsulfanyl)(butyl)bismuthane, bis(dibutylbismuthanyl)amine, dibutylbismuthanylamino(butyl)bismuthanyl(dibutylbismuthanyl, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-as-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, tetrapropyl-λ⁵-bismuthanyloxy(tetrapropyl)-λ⁵-bismuthane, bis(tetrapropyl-λ⁵-bismuthanyloxy)(tripropyl)-λ⁵-bismuthane, tetrapropyl-λ⁵-bismuthanylsulfanyl(tetrapropyl)-λ⁵-bismuthane, bis(tetrapropyl-λ⁵-bismuthanylsulfanyl)(tripropyl)-λ⁵-bismuthane, bis(tetrapropyl-λ⁵-bismuthanyl)amine, tetrapropyl-λ⁵-bismuthanylamino(tripropyl)-λ⁵-bismuthanyl)(tetrapropyl-λ⁵-bismuthanyl)amine, tetrabutyl-λ⁵-bismuthanyloxy(tetrabutyl)-λ⁵-bismuthane, bis(tetrabutyl-λ⁵-bismuthanyloxy)(tributyl)-λ⁵-bismuthane, tetrabutyl-λ⁵-bismuthanylsulfanyl(tetrabutyl)-λ⁵-bismuthane, bis(tetrabutyl-λ⁵-bismuthanylsulfanyl)(tributyl)-λ⁵-bismuthane, bis(tetrabutyl-λ⁵-bismuthanyl)amine, tetrabutyl-λ⁵-bismuthanylamino(tributyl)-λ⁵-bismuthanyl)(tetrabutyl-λ⁵-bismuthanyl)amine, dicyclopropylbismuthanyloxy(dicyclopropyl)bismuthane, bis(dicyclopropylbismuthanyloxy)(cyclopropyl)bismuthane, dicyclopropylbismuthanylsulfanyl(dicyclopropyl)bismuthane, bis(dicyclopropylbismuthanylsulfanyl)(cyclopropyl)bismuthane, bis(dicyclopropylbismuthanyl)amine, dicyclopropylbismuthanylamino(cyclopropyl)bismuthanyl(dicyclopropylbismuthanyl)amine, dicyclobutylbismuthanyloxy(dicyclobutyl)bismuthane, bis(dicyclobutylbismuthanyloxy)(cyclobutyl)bismuthane, dicyclobutylbismuthanylsulfanyl(dicyclobutyl)bismuthane, bis(dicyclobutylbismuthanylsulfanyl)(cyclobutyl)bismuthane, bis(dicyclobutylbismuthanyl)amine, dicyclobutylbismuthanylamino(cyclobutyl)bismuthanyl(dicyclobutylbismuthanyl)-amine, tetracyclopropyl-λ⁵-bismuthanyloxy(tetracyclopropyl)-λ⁵-bismuthane, bis(tetracyclopropyl-λ⁵-bismuthanyloxy)(tricyclopropyl)-λ⁵-bismuthane, tetracyclopropyl-λ⁵-bismuthanylsulfanyl(tetracyclopropyl)-λ⁵-bismuthane, bis(tetracyclopropyl-λ⁵-bismuthanylsulfanyl)(tricyclopropyl)-λ⁵-bismuthane, bis(tetracyclopropyl-λ⁵-bismuthanyl)amine, tetracyclopropyl-λ⁵-bismuthanylamino(tricyclopropyl)-λ⁵-bismuthanyl)(tetracyclopropyl-λ⁵-bismuthanyl)amine, tetracyclobutyl-λ⁵-bismuthanyloxy(tetracyclobutyl)-λ⁵-bismuthane, bis(tetracyclobutyl-λ⁵-bismuthanyloxy)(tricyclobutyl)-λ⁵-bismuthane, tetracyclobutyl-λ⁵-bismuthanylsulfanyl(tetracyclobutyl)-λ⁵-bismuthane, bis(tetracyclobutyl-λ⁵-bismuthanylsulfanyl)(tricyclobutyl)-λ⁵-bismuthane, bis(tetracyclobutyl-λ⁵-bismuthanyl)amine, tetracyclobutyl-λ⁵-bismuthanylamino(tricyclobutyl)-λ⁵-bismuthanyl)(tetracyclobutyl-λ⁵-bismuthanyl)amine, 2,4-dimethyl-1,3,2,4-dioxadibismetane, 2,4-diethyl-1,3,2,4-dioxadibismetane, 2,4-dipropyl-1,3,2,4-dioxadibismetane, 2,4-dibutyl-1,3,2,4-dioxadibismetane, 2,4-dimethyl-1,3,2,4-dithiadibismetane, 2,4-diethyl-1,3,2,4-dithiadibismetane, 2,4-dipropyl-1,3,2,4-dithiadibismetane, 2,4-dibutyl-1,3,2,4-dithiadibismetane, 2,4-dimethyl-1,3,2,4-diazadibismetane, 2,4-diethyl-1,3,2,4-diazadibismetane, 2,4-dipropyl-1,3,2,4-diazadibismetane, 2,4-dibutyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexapropyl-1,3,2,4-dioxadi-λ⁵-bismetane, 2,2,2,4,4,4-hexabutyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexapropyl-1,3,2,4-dithiadi-λ⁵-bismetane, 2,2,2,4,4,4-hexabutyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,2,2,4,4,4-hexapropyl-1,3,2,4-diazadi-λ⁵-bismetane, 2,2,2,4,4,4-hexabutyl-1,3,2,4-diazadi-λ⁵-bismetane, 2,4-dicyclopropyl-1,3,2,4-dioxadibismetane, 2,4-dicyclobutyl-1,3,2,4-dioxadibismetane, 2,4-dicyclopropyl-1,3,2,4-dithiadibismetane, 2,4-dicyclobutyl-1,3,2,4-dithiadibismetane, 2,4-dicyclopropyl-1,3,2,4-diazabismetane, 2,4-dicyclobutyl-1,3,2,4-diazadibismetane, 2,2,2,4,4,4-hexacyclopropyl-1,3,2,4-dioxadi-λ⁵-bismetane, 2,2,2,4,4,4-hexacyclobutyl-1,3,2,4-dioxadi-λ⁵-bismetane, 2,2,2,4,4,4-hexacyclopropyl-1,3,2,4-dithiadi-λ⁵-bismetane, 2,2,2,4,4,4-hexacyclobutyl-1,3,2,4-dithiadi-λ⁵-bismetane, 2,2,2,4,4,4-hexacyclopropyl-1,3,2,4-diazadi-λ⁵-bismetane, 2,2,2,4,4,4-hexacyclobutyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-tripropyl-1,3,5,2,4,6-trioxatribismane, 2,4,6-tributyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-tripropyl-1,3,5,2,4,6-trithiatribismane, 2,4,6-tributyl-1,3,5,2,4,6-trithiatribismane, 2,4,6-trimethyl-1,3,5,2,4,6-triazatribismane, 2,4,6-triethyl-1,3,5,2,4,6-triazatribismane, 2,4,6-tripropyl-1,3,5,2,4,6-triazatribismane, 2,4,6-tributyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonapropyl-1,3,5,2,4,6-trioxatri-λ⁵-bismane, 2,2,2,4,4,4,6,6,6-nonabutyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonapropyl-1,3,5,2,4,6-trithiatri-λ⁵-bismane, 2,2,2,4,4,4,6,6,6-nonabutyl-1,3,5,2,4,6-trithiatri-λ⁵-bismane, 2,2,2,4,4,4,6,6,6-nonamethyl-1,3,5,2,4,6-triazatri-λ⁵-bismane, 2,2,2,4,4,4,6,6,6-nonaethyl-1,3,5,2,4,6-triazatri-λ⁵-bismane, 2,2,2,4,4,4,6,6,6-nonapropyl-1,3,5,2,4,6-triazatri-λ⁵-bismane, 2,2,2,4,4,4,6,6,6-nonabutyl-1,3,5,2,4,6-triazatri-λ⁵-bismane, 2,4,6-tricyclopropyl-1,3,5,2,4,6-trioxatribismane, 2,4,6-tricyclobutyl-1,3,5,2,4,6-trioxatribismane, 2,4,6-tricylcopropyl-1,3,5,2,4,6-trithiatribismane, 2,4,6-tricylcobutyl-1,3,5,2,4,6-trithiatribismane, 2,4,6-tricylcopropyl-1,3,5,2,4,6-triazatribismane, 2,4,6-tricylcobutyl-1,3,5,2,4,6-triazatribismane, 2,2,2,4,4,4,6,6,6-nonacyclopropyl-1,3,5,2,4,6-trioxatri-λ⁵-bismane, 2,2,2,4,4,4,6,6,6-nonacyclobutyl-1,3,5,2,4,6-trioxatri-λ⁵-bismane, 2,2,2,4,4,4,6,6,6-nonacylcopropyl-1,3,5,2,4,6-trithiatri-λ⁵-bismane, 2,2,2,4,4,4,6,6,6-nonacylcobutyl-1,3,5,2,4,6-trithiatri-λ⁵-bismane, 2,2,2,4,4,4,6,6,6-nonacylcopropyl-1,3,5,2,4,6-triazatri-λ⁵-bismane, and 2,2,2,4,4,4,6,6,6-nonacylcobutyl-1,3,5,2,4,6-triazatri-λ⁵-bismane.

In a still more preferred variant, the organometallic compound for dry photoresist or hardmasks for EUV lithography can be selected from the following: methylbismuthanone, ethylbismuthanone, propylbismuthanone, methylbismuthanethione, ethylbismuthanethione, propylbismuthanethione, Bi-methylbismuthanimine, Bi-ethylbismuthanimine, Bi-propylbismuthanimine, trimethyl-λ⁵-bismuthanone, triethyl-λ⁵-bismuthanone, tripropyl-λ⁵-bismuthanone, trimethyl-λ⁵-bismuthanethione, triethyl-λ⁵-bismuthanethione, tripropyl-λ⁵-bismuthanethione, Bi,Bi,Bi-trimethyl-λ⁵-bismuthanimine, Bi,Bi,Bi-triethyl-λ⁵-bismuthanimine, Bi,Bi,Bi-tripropyl-λ⁵-bismuthanimine, cyclopropylbismuthanone, cyclopropylbismuthanethione, Bi-cyclopropylbismuthanimine, tricyclopropyl-λ⁵-bismuthanone, tricyclopropyl-λ⁵-bismuthanethione, Bi,Bi,Bi-tricyclopropyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane, diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, dipropylbismuthanyloxy(dipropyl)bismuthane, bis(dipropylbismuthanyloxy)(propyl)bismuthane, dipropylbismuthanylsulfanyl(dipropyl)bismuthane, bis(dipropylbismuthanylsulfanyl)(propyl)bismuthane, bis(dipropylbismuthanyl)amine, dipropylbismuthanylamino(propyl)bismuthanyl(dipropylbismuthanyl)amine, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-λ⁵-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, tetrapropyl-λ⁵-bismuthanyloxy(tetrapropyl)-λ⁵-bismuthane, bis(tetrapropyl-λ⁵-bismuthanyloxy)(tripropyl)-λ⁵-bismuthane, tetrapropyl-λ⁵-bismuthanylsulfanyl(tetrapropyl)-λ⁵-bismuthane, bis(tetrapropyl-λ⁵-bismuthanylsulfanyl)(tripropyl)-λ⁵-bismuthane, bis(tetrapropyl-λ⁵-bismuthanyl)amine, tetrapropyl-λ⁵-bismuthanylamino(tripropyl)-λ⁵-bismuthanyl)(tetrapropyl-λ⁵-bismuthanyl)amine, dicyclopropylbismuthanyloxy(dicyclopropyl)bismuthane, bis(dicyclopropylbismuthanyloxy)(cyclopropyl)bismuthane, dicyclopropylbismuthanylsulfanyl(dicyclopropyl)bismuthane, bis(dicyclopropylbismuthanylsulfanyl)(cyclopropyl)bismuthane, bis(dicyclopropylbismuthanyl)amine, dicyclopropylbismuthanylamino(cyclopropyl)bismuthanyl(dicyclopropylbismuthanyl)amine, tetracyclopropyl-λ⁵-bismuthanyloxy(tetracyclopropyl)-λ⁵-bismuthane, bis(tetracyclopropyl-λ⁵-bismuthanyloxy)(tricyclopropyl)-λ⁵-bismuthane, tetracyclopropyl-λ⁵-bismuthanylsulfanyl(tetracyclopropyl)-λ⁵-bismuthane, bis(tetracyclopropyl-λ⁵-bismuthanylsulfanyl)(tricyclopropyl)-λ⁵-bismuthane, bis(tetracyclopropyl-λ⁵-bismuthanyl)amine, tetracyclopropyl-λ⁵-bismuthanylamino(tricyclopropyl)-λ⁵-bismuthanyl)(tetracyclopropyl-λ⁵-bismuthanyl)amine, 2,4-dimethyl-1,3,2,4-dioxadibismetane, 2,4-diethyl-1,3,2,4-dioxadibismetane, 2,4-dipropyl-1,3,2,4-dioxadibismetane, 2,4-dimethyl-1,3,2,4-dithiadibismetane, 2,4-diethyl-1,3,2,4-dithiadibismetane, 2,4-dipropyl-1,3,2,4-dithiadibismetane, 2,4-dimethyl-1,3,2,4-diazadibismetane, 2,4-diethyl-1,3,2,4-diazadibismetane, 2,4-dipropyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexapropyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexapropyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,2,2,4,4,4-hexapropyl-1,3,2,4-diazadi-λ⁵-bismetane, 2,4-dicyclopropyl-1,3,2,4-dioxadibismetane, 2,4-dicyclopropyl-1,3,2,4-dithiadibismetane, 2,4-dicyclopropyl-1,3,2,4-diazabismetane, 2,2,2,4,4,4-hexacyclopropyl-1,3,2,4-dioxadi-λ⁵-bismetane, 2,2,2,4,4,4-hexacyclopropyl-1,3,2,4-dithiadi-λ⁵-bismetane, 2,2,2,4,4,4-hexacyclopropyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-tripropyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-tripropyl-1,3,5,2,4,6-trithiatribismane, 2,4,6-trimethyl-1,3,5,2,4,6-triazatribismane, 2,4,6-triethyl-1,3,5,2,4,6-triazatribismane, 2,4,6-tripropyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonapropyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonapropyl-1,3,5,2,4,6-trithiatri-λ⁵-bismane, 2,2,2,4,4,4,6,6,6-nonamethyl-1,3,5,2,4,6-triazatri-λ⁵-bismane, 2,2,2,4,4,4,6,6,6-nonaethyl-1,3,5,2,4,6-triazatri-λ⁵-bismane, 2,2,2,4,4,4,6,6,6-nonapropyl-1,3,5,2,4,6-triazatri-λ⁵-bismane, 2,4,6-tricyclopropyl-1,3,5,2,4,6-trioxatribismane, 2,4,6-tricylcopropyl-1,3,5,2,4,6-trithiatribismane, 2,4,6-tricylcopropyl-1,3,5,2,4,6-triazatribismane, 2,2,2,4,4,4,6,6,6-nonacyclopropyl-1,3,5,2,4,6-trioxatri-λ⁵-bismane, 2,2,2,4,4,4,6,6,6-nonacylcopropyl-1,3,5,2,4,6-trithiatri-λ⁵-bismane, and 2,2,2,4,4,4,6,6,6-nonacylcopropyl-1,3,5,2,4,6-triazatri-λ⁵-bismane.

In a most preferred variant, the organometallic compound for dry photoresist or hardmasks for EUV lithography can be selected from the following: methylbismuthanone, ethylbismuthanone, methylbismuthanethione, ethylbismuthanethione, Bi-methylbismuthanimine, Bi-ethylbismuthanimine, trimethyl-λ⁵-bismuthanone, triethyl-λ⁵-bismuthanone, trimethyl-λ⁵-bismuthanethione, triethyl-λ⁵-bismuthanethione, Bi,Bi,Bi-trimethyl-λ⁵-bismuthanimine, Bi,Bi,Bi-triethyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane, diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-λ⁵-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, 2,4-dimethyl-1,3,2,4-dioxadibismetane, 2,4-diethyl-1,3,2,4-dioxadibismetane, 2,4-dimethyl-1,3,2,4-dithiadibismetane, 2,4-diethyl-1,3,2,4-dithiadibismetane, 2,4-dimethyl-1,3,2,4-diazadibismetane, 2,4-diethyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-trimethyl-1,3,5,2,4,6-triazatribismane, 2,4,6-triethyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonamethyl-1,3,5,2,4,6-triazatri-λ⁵-bismane, and 2,2,2,4,4,4,6,6,6-nonaethyl-1,3,5,2,4,6-triazatri-λ⁵-bismane.

The synthesis of the organometallic compounds for dry photoresists or hardmasks for EUV lithography is described by way of example for the trimethylbismuthine oxide compound. A benzene solution of trimethylbismuth dichloride (1.072 g, 3.3 mmol) was mixed with an aqueous solution of freshly prepared silver oxide (0.773 g, 3.3 mmol), and the resulting mixture was stirred for 5 h at room temperature in the dark. The benzene layer was separated by decantation, laid on molecular sieves for 12 h, and then filtered and concentrated by evaporation. Trimethylbismuthine oxide (40%) was precipitated from the concentrated benzene solution by adding petroleum ether slowly.

The organometallic compound for dry photoresists or hardmasks for EUV lithography can be combined with a solvent. Examples of such solvents can include ethers (e.g., tetrahydrofuran), glycol ethers (e.g., 2-methoxyethyl ether (diglyme), ethylene glycol monomethyl ether, propylene glycol monomethyl ether, propylene glycol monomethylether acetate (PGMEA), etc.), aromatic hydrocarbons (e.g., toluene, xylene, benzene, etc.), ketones (e.g., methylisobutylketone, 2-heptanone, cycloheptanone, cyclohexanone, etc.), esters (e.g., ethyl lactate, ethoxy ethyl propionate, etc.), and the like. A solvent system including a mixture of two or more of the aforementioned solvents is also contemplated herein.

Embodiments of the present disclosure can include dry photoresists or hardmask compositions for EUV lithography that include at least one of the organometallic compounds illustrated herein, as well as the dry photoresists or hardmasks that include the compositions. In some embodiments, the disclosed organometallic compounds are capable of undergoing chemical transformations upon exposure of the dry photoresist or hardmask composition, in particular EUV irradiation, whereby a differential in the solubility of the dry photoresist or hardmask in the exposed and unexposed regions is created.

In some embodiments, the content of the organometallic compound in the photoresists or hardmasks compositions is preferably about 5 to 95% by weight, more preferably 10 to 90% by weight, and most preferably 20 to 80% by weight, based on the total weight of the photoresist or hardmask EUV lithography. The photoresist or hardmask composition can contain a solvent or solvent mixture that is capable of dissolving the organometallic compound. Examples of such solvents include, but are not limited to, ethers, glycol ethers, aromatic hydrocarbons, ketones, esters, and the like (see above). In addition, the photoresist or hardmask composition for EUV lithography may also include other components such as a photosensitizer, a pigment, a filler, an antistatic agent, a flame retardant, a defoaming agent, a light stabilizer, an antioxidant, or other additives. If desired, combinations or mixtures of these other components may be used.

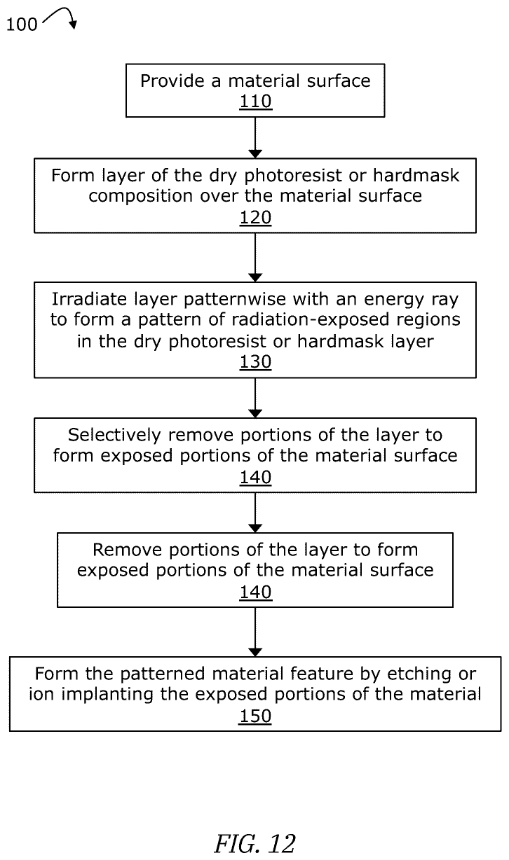

FIG. 12 is a flowchart illustrating a process 100 of using a dry photoresist or hardmask composition to form a patterned material feature on a substrate, according to some embodiments. Process 100 can include lithographic processes to create patterned material layer structures such as metal wiring lines, holes for contacts or vias, insulation sections (e.g., damascene trenches or shallow trench isolation), trenches for capacitor structures, ion implanted semiconductor structures for transistors, etc., as may be used in integrated circuit devices.

A material surface can be provided on a substrate. This is illustrated at operation 110. The substrate can be any suitable substrate conventionally used in processes involving photoresists. For example, the substrate can be silicon, silicon oxide, aluminum, aluminum oxide, gallium arsenide, ceramic, quartz, copper, or any combination thereof, including multilayers. The material surface may include a metal conductor layer, a ceramic insulator layer, a semiconductor layer or other material depending on the stage of the manufacture process and the desired material set for the end product.

A layer of the disclosed dry photoresist or hardmask composition can be formed over the material surface. This is illustrated at operation 120. The layer can be irradiated patternwise with an energy ray, thereby creating a pattern of radiation-exposed regions in the dry photoresist or hardmask layer. This is illustrated at operation 130. In some embodiments, the energy ray with which the patternwise irradiation of the photoresist composition is conducted an EUV ray. When exposed to EUV radiation, the organometallic compounds can crosslink, generating an insoluble network that remains as patterned material layer structures on the substrate. Portions of the layer can then be selectively removed to form exposed portions of the material surface. This is illustrated at operation 140. In some embodiments, after exposure, the photoresist structure with the desired pattern can be obtained or developed by dry photoresist processing steps. Examples of dry photoresist processing steps that may be used can include thermal process steps, plasma ashing, plasma etching, etc.

In other embodiments, after exposure, the photoresist structure with the desired pattern can be obtained or developed by contacting the photoresist layer with an aqueous alkaline solution, which selectively dissolves the areas of the photoresist that were exposed to radiation in the case of a positive photoresist (or the unexposed areas in the case of a negative photoresist).

Some aqueous alkaline solutions or developers comprise aqueous solutions of tetramethyl ammonium hydroxide. The resulting lithographic structure on the substrate may then be dried to remove any remaining developer. If a topcoat has been used, it can be dissolved by the developer in this step.

Process 100 can also include etching or ion implanting the exposed portions of the material, thereby forming the patterned material feature. This is illustrated at operation 150. The pattern from the photoresist structure may be transferred to the exposed portions of underlying material of the substrate by etching with a suitable etchant using techniques known in the art. In some embodiments, the transfer is done by reactive ion etching or by wet etching. Once the desired pattern transfer has taken place, any remaining photoresist may be removed using conventional stripping techniques. Alternatively, the pattern may be transferred by ion implantation to form a pattern of ion implanted material.

Although the invention has been described in reference to specific embodiments, it should be understood that the invention is not limited to these examples only and that many variations of these embodiments may be readily envisioned by the skilled person after having read the present disclosure. The invention may thus further be described without limitation, and by way of example only, by the following embodiments. The following embodiments may contain preferred embodiments. Accordingly, the term “clause” as used therein may refer to such a “preferred embodiment”.

Clause 1: An organometallic compound for dry photoresists or hardmasks for EUV lithography comprising: at least one Bi(III) or Bi(V) element; at least one terminal or bridging ligand A bonded to the Bi(III) or Bi(V) element, wherein the A ligand is O, S, or N—R, and wherein the R group in N—R is selected from the group consisting of H and C1 to C6 alkyls; and at least one C1 to C6 alkyl ligand bonded to the Bi(III) or Bi(V) element.

Clause 2: The organometallic compound according to clause 1, having a general formula (I), (II), (III), (IV), (V), (VI), or (VII), as illustrated above, wherein A represents an element selected from the group consisting of O, S and N—R; R1, R2, R3, R4, R5, R6, R7, or R8 represent, independently from each other, an unsubstituted or substituted linear or branched C1 to C6 alkyl, an unsubstituted or substituted C3 to C6 cycloalkyl, or an unsubstituted or substituted C3 to C6 heterocycloalkyl; n is an integer from 1 to 4; m is an integer from 2 to 5; and R in N—R represents either H or an unsubstituted or substituted linear or branched C1 to C6 alkyl, an unsubstituted or substituted C3 to C6 cycloalkyl, or an unsubstituted or substituted C3 to C6 heterocycloalkyl.

Clause 3: The organometallic compound according to clause 2, wherein n is an integer from 1 to 3 and m is an integer from 2 to 4.

Clause 4: The organometallic compound according to any one of clauses 1 to 3, wherein the organometallic compound is represented by any one of the formulas (a) to (o) illustrated in FIG. 3A, in which R1, R2, R3, R4, R1/1, R1/2, R1/3, RN/1, RN/2, and RN/3 represent, independently from each other, an unsubstituted or substituted linear or branched C1 to C6 alkyl, an unsubstituted or substituted C3 to C6 cycloalkyl, or an unsubstituted or substituted C3 to C6 heterocycloalkyl; or wherein the organometallic compound is represented by any one of the formulas (p) to (ad) illustrated in FIG. 3B, in which R1, R2, R3, R4, R5, R6, R7, R8, R1/1, R2/1, R3/1, R1/2, R2/2, R3/2, R1/3, R2/3, R3/3, RN/1, RN/2, and RN/3 represent, independently from each other, an unsubstituted or substituted linear or branched C1 to C6 alkyl, an unsubstituted or substituted C3 to C6 cycloalkyl, or an or an unsubstituted or substituted C3 to C6 heterocycloalkyl.

Clause 5: The organometallic compound according to any one of clauses 2 to 4, wherein R1, R2, R3, R4, R5, R6, R7, and R8 in general formulas (I) to (VII) or R1, R2, R3, R4, R5, R6, R7, R8, R1/1, R2/1, R3/1, R1/2, R2/2, R3/2, R1/3, R2/3, R3/3, RN/1, RN/2, and RN/3 in general formulas (a) to (ad), is an unsubstituted or substituted linear or branched C1 to C5 alkyl, an unsubstituted or substituted C3 to C5 cycloalkyl, or an unsubstituted or substituted C3 to C5 heterocycloalkyl, in particular an unsubstituted or substituted linear C1 to C5 alkyl.

Clause 6: The organometallic compound according to any one of clauses 2 to 5, wherein R1, R2, R3, R4, R5, R6, R7, and R8 in general formulas (I) to (VII) or R1, R2, R3, R4, R5, R6, R7, R8, R1/1, R2/1, R3/1, R1/2, R2/2, R3/2, R1/3, R2/3, R3/3, RN/1, RN/2, and RN/3 in general formulae (a) to (ad) is an unsubstituted or substituted linear or branched C1 to C4 alkyl, an unsubstituted or substituted C3 or C4 cycloalkyl, or an unsubstituted or substituted C3 or C4 heterocycloalkyl, in particular an unsubstituted or substituted linear C1 to C4 alkyl.

Clause 7: The organometallic compound according to any one of clauses 2 to 6, wherein R1, R2, R3, R4, R5, R6, R7, and R8 in general formulas (I) to (VII) or R1, R2, R3, R4, R5, R6, R7, R8, R1/1, R2/1, R3/1, R1/2, R2/2, R3/2, R1/3, R2/3, R3/3, RN/1, RN/2, and RN/3 in general formulas (a) to (ad) is an unsubstituted or substituted linear or branched C1 to C3 alkyl, an unsubstituted or substituted C3 cycloalkyl, or an unsubstituted or substituted C3 heterocycloalkyl, in particular an unsubstituted or substituted linear C1 to C3 alkyl.

Clause 8: The organometallic compound according to any one of clauses 2 to 7, wherein R1, R2, R3, R4, R5, R6, R7, and R8 in general formulas (I) to (VII) or R1, R2, R3, R4, R5, R6, R7, R8, R1/1, R2/1, R3/1, R1/2, R2/2, R3/2, R1/3, R2/3, R3/3, RN/1, RN/2, and RN/3 in general formulas (a) to (ad) is an unsubstituted or substituted C1 or C2 alkyl.

Clause 9: The organometallic compound according to any one of clauses 2 to 8, wherein R1, R2, R3, R4, R5, R6, R7, and R8 in general formulas (I) to (VII) or R1, R2, R3, R4, R5, R6, R7, R8, R1/1, R2/1, R3/1, R1/2, R2/2, R3/2, R1/3, R2/3, R3/3, RN/1, RN/2, and RN/3 in general formulas (a) to (ad) are either identical or different from each other.

Clause 10: The organometallic compound according to any one of clauses 1 to 9, wherein the organometallic compound has a melting point of at least 100° C., in particular a melting point in a range of 300° C. to 600° C.

Clause 11: The organometallic compound according to any one of clauses 1 to 10, wherein the organometallic compound has a dissociation energy of at least 30 kcal/mol.

Clause 12: The organometallic compound according to any one of clauses 1 to 11, wherein the organometallic compound is selected from the group consisting of methylbismuthanone, ethylbismuthanone, propylbismuthanone, butylbismuthanone, methylbismuthanethione, ethylbismuthanethione, propylbismuthanethione, butylbismuthanethione, Bi-methylbismuthanimine, Bi-ethylbismuthanimine, Bi-propylbismuthanimine, Bi-butylbismuthanimine, trimethyl-λ⁵-bismuthanone, triethyl-λ⁵-bismuthanone, tripropyl-λ⁵-bismuthanone, tributyl-λ⁵-bismuthanone, trimethyl-λ⁵-bismuthanethione, triethyl-λ⁵-bismuthanethione, tripropyl-λ⁵-bismuthanethione, tributyl-λ⁵-bismuthanethione, Bi,Bi,Bi-trimethyl-λ⁵-bismuthanimine, Bi,Bi,Bi-triethyl-λ⁵-bismuthanimine, Bi,Bi,Bi-tripropyl-λ⁵-bismuthanimine, Bi,Bi,Bi-tributyl-λ⁵-bismuthanimine, propan-2-ylbismuthanone, tert-butylbismuthanone, propan-2-ylbismuthanethione, tert-butylbismuthanethione, Bi-propan-2-ylbismuthanimine, Bi-tert-butylbismuthanimine, tri(propan-2-yl)-λ⁵-bismuthanone, tri(tert-butyl)-λ⁵-bismuthanone, tri(propan-2-yl)-λ⁵-bismuthanethione, tri(tert-butyl)-λ⁵-bismuthanethione, Bi,Bi,Bi-tri(propan-2-yl)-λ⁵-bismuthanimine, Bi,Bi,Bi-tri(tert-butyl)-λ⁵-bismuthanimine, cyclopropylbismuthanone, cyclobutylbismuthanone, cyclopropylbismuthanethione, cyclobutylbismuthanethione, Bi-cyclopropylbismuthanimine, Bi-cyclobutylbismuthanimine, tricyclopropyl-λ⁵-bismuthanone, tricyclobutyl-λ⁵-bismuthanone, tricyclopropyl-λ⁵-bismuthanethione, tricyclobutyl-λ⁵-bismuthanethione, Bi,Bi,Bi-tricyclopropyl-λ⁵-bismuthanimine, Bi,Bi,Bi-tricyclobutyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane, diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, dipropylbismuthanyloxy(dipropyl)bismuthane, bis(dipropylbismuthanyloxy)(propyl)bismuthane, dipropylbismuthanylsulfanyl(dipropyl)bismuthane, bis(dipropylbismuthanylsulfanyl)(propyl)bismuthane, bis(dipropylbismuthanyl)amine, dipropylbismuthanylamino(propyl)bismuthanyl(dipropylbismuthanyl)amine, dibutylbismuthanyloxy(dibutyl)bismuthane, bis(dibutylbismuthanyloxy)(butyl)bismuthane, dibutylbismuthanylsulfanyl(dibutyl)bismuthane, bis(dibutylbismuthanylsulfanyl)(butyl)bismuthane, bis(dibutylbismuthanyl)amine, dibutylbismuthanylamino(butyl)bismuthanyl(dibutylbismuthanyl, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-λ⁵-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, tetrapropyl-λ⁵-bismuthanyloxy(tetrapropyl)-λ⁵-bismuthane, bis(tetrapropyl-λ⁵-bismuthanyloxy)(tripropyl)-λ⁵-bismuthane, tetrapropyl-λ⁵-bismuthanylsulfanyl(tetrapropyl)-λ⁵-bismuthane, bis(tetrapropyl-λ⁵-bismuthanylsulfanyl)(tripropyl)-λ⁵-bismuthane, bis(tetrapropyl-λ⁵-bismuthanyl)amine, tetrapropyl-λ⁵-bismuthanylamino(tripropyl)-λ⁵-bismuthanyl)(tetrapropyl-λ⁵-bismuthanyl)amine, tetrabutyl-λ⁵-bismuthanyloxy(tetrabutyl)-λ⁵-bismuthane, bis(tetrabutyl-λ⁵-bismuthanyloxy)(tributyl)-λ⁵-bismuthane, tetrabutyl-λ⁵-bismuthanylsulfanyl(tetrabutyl)-λ⁵-bismuthane, bis(tetrabutyl-λ⁵-bismuthanylsulfanyl)(tributyl)-λ⁵-bismuthane, bis(tetrabutyl-λ⁵-bismuthanyl)amine, tetrabutyl-λ⁵-bismuthanylamino(tributyl)-λ⁵-bismuthanyl)(tetrabutyl-λ⁵-bismuthanyl)amine, dicyclopropylbismuthanyloxy(dicyclopropyl)bismuthane, bis(dicyclopropylbismuthanyloxy)(cyclopropyl)bismuthane, dicyclopropylbismuthanylsulfanyl(dicyclopropyl)bismuthane, bis(dicyclopropylbismuthanylsulfanyl)(cyclopropyl)bismuthane, bis(dicyclopropylbismuthanyl)amine, dicyclopropylbismuthanylamino(cyclopropyl)bismuthanyl(dicyclopropylbismuthanyl)amine, dicyclobutylbismuthanyloxy(dicyclobutyl)bismuthane, bis(dicyclobutylbismuthanyloxy)(cyclobutyl)bismuthane, dicyclobutylbismuthanylsulfanyl(dicyclobutyl)bismuthane, bis(dicyclobutylbismuthanylsulfanyl)(cyclobutyl)bismuthane, bis(dicyclobutylbismuthanyl)amine, dicyclobutylbismuthanylamino(cyclobutyl)bismuthanyl(dicyclobutylbismuthanyl)-amine, tetracyclopropyl-λ⁵-bismuthanyloxy(tetracyclopropyl)-λ⁵-bismuthane, bis(tetracyclopropyl-λ⁵-bismuthanyloxy)(tricyclopropyl)-λ⁵-bismuthane, tetracyclopropyl-λ⁵-bismuthanylsulfanyl(tetracyclopropyl)-λ⁵-bismuthane, bis(tetracyclopropyl-λ⁵-bismuthanylsulfanyl)(tricyclopropyl)-λ⁵-bismuthane, bis(tetracyclopropyl-λ⁵-bismuthanyl)amine, tetracyclopropyl-λ⁵-bismuthanylamino(tricyclopropyl)-λ⁵-bismuthanyl)(tetracyclopropyl-λ⁵-bismuthanyl)amine, tetracyclobutyl-λ⁵-bismuthanyloxy(tetracyclobutyl)-λ⁵-bismuthane, bis(tetracyclobutyl-λ⁵-bismuthanyloxy)(tricyclobutyl)-λ⁵-bismuthane, tetracyclobutyl-λ⁵-bismuthanylsulfanyl(tetracyclobutyl)-λ⁵-bismuthane, bis(tetracyclobutyl-λ⁵-bismuthanylsulfanyl)(tricyclobutyl)-λ⁵-bismuthane, bis(tetracyclobutyl-λ⁵-bismuthanyl)amine, tetracyclobutyl-λ⁵-bismuthanylamino(tricyclobutyl)-λ⁵-bismuthanyl)(tetracyclobutyl-λ⁵-bismuthanyl)amine, 2,4-dimethyl-1,3,2,4-dioxadibismetane, 2,4-diethyl-1,3,2,4-dioxadibismetane, 2,4-dipropyl-1,3,2,4-dioxadibismetane, 2,4-dibutyl-1,3,2,4-dioxadibismetane, 2,4-dimethyl-1,3,2,4-dithiadibismetane, 2,4-diethyl-1,3,2,4-dithiadibismetane, 2,4-dipropyl-1,3,2,4-dithiadibismetane, 2,4-dibutyl-1,3,2,4-dithiadibismetane, 2,4-dimethyl-1,3,2,4-diazadibismetane, 2,4-diethyl-1,3,2,4-diazadibismetane, 2,4-dipropyl-1,3,2,4-diazadibismetane, 2,4-dibutyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexapropyl-1,3,2,4-dioxadi-λ⁵-bismetane, 2,2,2,4,4,4-hexabutyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexapropyl-1,3,2,4-dithiadi-λ⁵-bismetane, 2,2,2,4,4,4-hexabutyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,2,2,4,4,4-hexapropyl-1,3,2,4-diazadi-λ⁵-bismetane, 2,2,2,4,4,4-hexabutyl-1,3,2,4-diazadi-λ⁵-bismetane, 2,4-dicyclopropyl-1,3,2,4-dioxadibismetane, 2,4-dicyclobutyl-1,3,2,4-dioxadibismetane, 2,4-dicyclopropyl-1,3,2,4-dithiadibismetane, 2,4-dicyclobutyl-1,3,2,4-dithiadibismetane, 2,4-dicyclopropyl-1,3,2,4-diazabismetane, 2,4-dicyclobutyl-1,3,2,4-diazadibismetane, 2,2,2,4,4,4-hexacyclopropyl-1,3,2,4-dioxadi-λ⁵-bismetane, 2,2,2,4,4,4-hexacyclobutyl-1,3,2,4-dioxadi-λ⁵-bismetane, 2,2,2,4,4,4-hexacyclopropyl-1,3,2,4-dithiadi-λ⁵-bismetane, 2,2,2,4,4,4-hexacyclobutyl-1,3,2,4-dithiadi-λ⁵-bismetane, 2,2,2,4,4,4-hexacyclopropyl-1,3,2,4-diazadi-λ⁵-bismetane, 2,2,2,4,4,4-hexacyclobutyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-tripropyl-1,3,5,2,4,6-trioxatribismane, 2,4,6-tributyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-tripropyl-1,3,5,2,4,6-trithiatribismane, 2,4,6-tributyl-1,3,5,2,4,6-trithiatribismane, 2,4,6-trimethyl-1,3,5,2,4,6-triazatribismane, 2,4,6-triethyl-1,3,5,2,4,6-triazatribismane, 2,4,6-tripropyl-1,3,5,2,4,6-triazatribismane, 2,4,6-tributyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonapropyl-1,3,5,2,4,6-trioxatri-λ⁵-bismane, 2,2,2,4,4,4,6,6,6-nonabutyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonapropyl-1,3,5,2,4,6-trithiatri-λ⁵-bismane, 2,2,2,4,4,4,6,6,6-nonabutyl-1,3,5,2,4,6-trithiatri-λ⁵-bismane, 2,2,2,4,4,4,6,6,6-nonamethyl-1,3,5,2,4,6-triazatri-λ⁵-bismane, 2,2,2,4,4,4,6,6,6-nonaethyl-1,3,5,2,4,6-triazatri-λ⁵-bismane, 2,2,2,4,4,4,6,6,6-nonapropyl-1,3,5,2,4,6-triazatri-λ⁵-bismane, 2,2,2,4,4,4,6,6,6-nonabutyl-1,3,5,2,4,6-triazatri-λ⁵-bismane, 2,4,6-tricyclopropyl-1,3,5,2,4,6-trioxatribismane, 2,4,6-tricyclobutyl-1,3,5,2,4,6-trioxatribismane, 2,4,6-tricylcopropyl-1,3,5,2,4,6-trithiatribismane, 2,4,6-tricylcobutyl-1,3,5,2,4,6-trithiatribismane, 2,4,6-tricylcopropyl-1,3,5,2,4,6-triazatribismane, 2,4,6-tricylcobutyl-1,3,5,2,4,6-triazatribismane, 2,2,2,4,4,4,6,6,6-nonacyclopropyl-1,3,5,2,4,6-trioxatri-λ⁵-bismane, 2,2,2,4,4,4,6,6,6-nonacyclobutyl-1,3,5,2,4,6-trioxatri-λ⁵-bismane, 2,2,2,4,4,4,6,6,6-nonacylcopropyl-1,3,5,2,4,6-trithiatri-λ⁵-bismane, 2,2,2,4,4,4,6,6,6-nonacylcobutyl-1,3,5,2,4,6-trithiatri-λ⁵-bismane, 2,2,2,4,4,4,6,6,6-nonacylcopropyl-1,3,5,2,4,6-triazatri-5-bismane, and 2,2,2,4,4,4,6,6,6-nonacylcobutyl-1,3,5,2,4,6-triazatri-λ⁵-bismane.

Clause 13: The organometallic compound according to clause 12, wherein the organometallic compound is selected from the group consisting of methylbismuthanone, ethylbismuthanone, propylbismuthanone, methylbismuthanethione, ethylbismuthanethione, propylbismuthanethione, Bi-methylbismuthanimine, Bi-ethylbismuthanimine, Bi-propylbismuthanimine, trimethyl-λ⁵-bismuthanone, triethyl-λ⁵-bismuthanone, tripropyl-λ⁵-bismuthanone, trimethyl-λ⁵-bismuthanethione, triethyl-λ⁵-bismuthanethione, tripropyl-λ⁵-bismuthanethione, Bi,Bi,Bi-trimethyl-λ⁵-bismuthanimine, Bi,Bi,Bi-triethyl-λ⁵-bismuthanimine, Bi,Bi,Bi-tripropyl-λ⁵-bismuthanimine, cyclopropylbismuthanone, cyclopropylbismuthanethione, Bi-cyclopropylbismuthanimine, tricyclopropyl-λ⁵-bismuthanone, tricyclopropyl-λ⁵-bismuthanethione, Bi,Bi,Bi-tricyclopropyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane,diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, dipropylbismuthanyloxy(dipropyl)bismuthane, bis(dipropylbismuthanyloxy)(propyl)bismuthane, dipropylbismuthanylsulfanyl(dipropyl)bismuthane, bis(dipropylbismuthanylsulfanyl)(propyl)bismuthane, bis(dipropylbismuthanyl)amine, dipropylbismuthanylamino(propyl)bismuthanyl(dipropylbismuthanyl)amine, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-λ⁵-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, tetrapropyl-λ⁵-bismuthanyloxy(tetrapropyl)-λ⁵-bismuthane, bis(tetrapropyl-λ⁵-bismuthanyloxy)(tripropyl)-λ⁵-bismuthane, tetrapropyl-λ⁵-bismuthanylsulfanyl(tetrapropyl)-λ⁵-bismuthane, bis(tetrapropyl-λ⁵-bismuthanylsulfanyl)(tripropyl)-λ⁵-bismuthane, bis(tetrapropyl-λ⁵-bismuthanyl)amine, tetrapropyl-λ⁵-bismuthanylamino(tripropyl)-λ⁵-bismuthanyl)(tetrapropyl-λ⁵-bismuthanyl)amine, dicyclopropylbismuthanyloxy(dicyclopropyl)bismuthane, bis(dicyclopropylbismuthanyloxy)(cyclopropyl)bismuthane, dicyclopropylbismuthanylsulfanyl(dicyclopropyl)bismuthane, bis(dicyclopropylbismuthanylsulfanyl)(cyclopropyl)bismuthane, bis(dicyclopropylbismuthanyl)amine, dicyclopropylbismuthanylamino(cyclopropyl)bismuthanyl(dicyclopropylbismuthanyl)amine, tetracyclopropyl-λ⁵-bismuthanyloxy(tetracyclopropyl)-λ⁵-bismuthane, bis(tetracyclopropyl-λ⁵-bismuthanyloxy)(tricyclopropyl)-λ⁵-bismuthane, tetracyclopropyl-λ⁵-bismuthanylsulfanyl(tetracyclopropyl)-λ⁵-bismuthane, bis(tetracyclopropyl-λ⁵-bismuthanylsulfanyl)(tricyclopropyl)-λ⁵-bismuthane, bis(tetracyclopropyl-λ⁵-bismuthanyl)amine, tetracyclopropyl-λ⁵-bismuthanylamino(tricyclopropyl)-λ⁵-bismuthanyl)(tetracyclopropyl-λ⁵-bismuthanyl)amine, 2,4-dimethyl-1,3,2,4-dioxadibismetane, 2,4-diethyl-1,3,2,4-dioxadibismetane, 2,4-dipropyl-1,3,2,4-dioxadibismetane, 2,4-dimethyl-1,3,2,4-dithiadibismetane, 2,4-diethyl-1,3,2,4-dithiadibismetane, 2,4-dipropyl-1,3,2,4-dithiadibismetane, 2,4-dimethyl-1,3,2,4-diazadibismetane, 2,4-diethyl-1,3,2,4-diazadibismetane, 2,4-dipropyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexapropyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexapropyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,2,2,4,4,4-hexapropyl-1,3,2,4-diazadi-λ⁵-bismetane, 2,4-dicyclopropyl-1,3,2,4-dioxadibismetane, 2,4-dicyclopropyl-1,3,2,4-dithiadibismetane, 2,4-dicyclopropyl-1,3,2,4-diazabismetane, 2,2,2,4,4,4-hexacyclopropyl-1,3,2,4-dioxadi-λ⁵-bismetane, 2,2,2,4,4,4-hexacyclopropyl-1,3,2,4-dithiadi-λ⁵-bismetane, 2,2,2,4,4,4-hexacyclopropyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-tripropyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-tripropyl-1,3,5,2,4,6-trithiatribismane, 2,4,6-trimethyl-1,3,5,2,4,6-triazatribismane, 2,4,6-triethyl-1,3,5,2,4,6-triazatribismane, 2,4,6-tripropyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonapropyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonapropyl-1,3,5,2,4,6-trithiatri-λ⁵-bismane, 2,2,2,4,4,4,6,6,6-nonamethyl-1,3,5,2,4,6-triazatri-λ⁵-bismane, 2,2,2,4,4,4,6,6,6-nonaethyl-1,3,5,2,4,6-triazatri-λ⁵-bismane, 2,2,2,4,4,4,6,6,6-nonapropyl-1,3,5,2,4,6-triazatri-λ⁵-bismane, 2,4,6-tricyclopropyl-1,3,5,2,4,6-trioxatribismane, 2,4,6-tricylcopropyl-1,3,5,2,4,6-trithiatribismane, 2,4,6-tricylcopropyl-1,3,5,2,4,6-triazatribismane, 2,2,2,4,4,4,6,6,6-nonacyclopropyl-1,3,5,2,4,6-trioxatri-λ⁵-bismane, 2,2,2,4,4,4,6,6,6-nonacylcopropyl-1,3,5,2,4,6-trithiatri-λ⁵-bismane, and 2,2,2,4,4,4,6,6,6-nonacylcopropyl-1,3,5,2,4,6-triazatri-λ⁵-bismane; and preferably selected from the group consisting of methylbismuthanone, ethylbismuthanone, methylbismuthanethione, ethylbismuthanethione, Bi-methylbismuthanimine, Bi-ethylbismuthanimine, trimethyl-λ⁵-bismuthanone, triethyl-λ⁵-bismuthanone, trimethyl-λ⁵-bismuthanethione, triethyl-λ⁵-bismuthanethione, Bi,Bi,Bi-trimethyl-λ⁵-bismuthanimine, Bi,Bi,Bi-triethyl-λ⁵-bismuthanimine, dimethylbismuthanyloxy(dimethyl)bismuthane, bis(dimethylbismuthanyloxy)(methyl)bismuthane, dimethylbismuthanylsulfanyl(dimethyl)bismuthane, bis(dimethylbismuthanylsulfanyl)(methyl)bismuthane, bis(dimethylbismuthanyl)amine, dimethylbismuthanylamino(methyl)bismuthanyl(dimethylbismuthanyl)amine, diethylbismuthanyloxy(diethyl)bismuthane, bis(diethylbismuthanyloxy)(ethyl)bismuthane, diethylbismuthanylsulfanyl(diethyl)bismuthane, bis(diethylbismuthanylsulfanyl)(ethyl)bismuthane, bis(diethylbismuthanyl)amine, diethylbismuthanylamino(ethyl)bismuthanyl(diethylbismuthanyl)amine, tetramethyl-λ⁵-bismuthanyloxy(tetramethyl)-λ⁵-bismuthane, bis(tetramethyl-λ⁵-bismuthanyloxy)(trimethyl)-λ⁵-bismuthane, tetramethyl-λ⁵-bismuthanylsulfanyl(tetramethyl)-λ⁵-bismuthane, bis(tetramethyl-λ⁵-bismuthanylsulfanyl)(trimethyl)-λ⁵-bismuthane, bis(tetramethyl-λ⁵-bismuthanyl)amine, tetramethyl-λ⁵-bismuthanylamino(trimethyl)-λ⁵-bismuthanyl)(tetramethyl-λ⁵-bismuthanyl)amine, tetraethyl-λ⁵-bismuthanyloxy(tetraethyl)-λ⁵-bismuthane, bis(tetraethyl-λ⁵-bismuthanyloxy)(triethyl)-λ⁵-bismuthane, tetraethyl-λ⁵-bismuthanylsulfanyl(tetraethyl)-λ⁵-bismuthane, bis(tetraethyl-λ⁵-bismuthanylsulfanyl)(triethyl)-λ⁵-bismuthane, bis(tetraethyl-λ⁵-bismuthanyl)amine, tetraethyl-λ⁵-bismuthanylamino(triethyl)-λ⁵-bismuthanyl)(tetraethyl-λ⁵-bismuthanyl)amine, 2,4-dimethyl-1,3,2,4-dioxadibismetane, 2,4-diethyl-1,3,2,4-dioxadibismetane, 2,4-dimethyl-1,3,2,4-dithiadibismetane, 2,4-diethyl-1,3,2,4-dithiadibismetane, 2,4-dimethyl-1,3,2,4-diazadibismetane, 2,4-diethyl-1,3,2,4-diazadibismetane, 2,2,2,4,4,4-hexamethyl-1,3,2,4-dioxadi-λ⁵-bismetane, 2,2,2,4,4,4-hexaethyl-1,3,2,4-dioxadi-λ⁵-bismetane, 2,2,2,4,4,4-hexamethyl-1,3,2,4-dithiadi-λ⁵-bismetane, 2,2,2,4,4,4-hexaethyl-1,3,2,4-dithiadi-λ⁵-bismetane, 2,2,2,4,4,4-hexamethyl-1,3,2,4-diazadi-λ⁵-bismetane, 2,2,2,4,4,4-hexaethyl-1,3,2,4-diazadi-λ⁵-bismetane, 2,4,6-trimethyl-1,3,5,2,4,6-trioxatribismane, 2,4,6-triethyl-1,3,5,2,4,6-trioxatribismane, 2,4,6-trimethyl-1,3,5,2,4,6-trithiatribismane, 2,4,6-triethyl-1,3,5,2,4,6-trithiatribismane, 2,4,6-trimethyl-1,3,5,2,4,6-triazatribismane, 2,4,6-triethyl-1,3,5,2,4,6-triazatribismane, 2,2,2,4,4,4,6,6,6-nonamethyl-1,3,5,2,4,6-trioxatri-λ⁵-bismane, 2,2,2,4,4,4,6,6,6-nonaethyl-1,3,5,2,4,6-trioxatri-λ⁵-bismane, 2,2,2,4,4,4,6,6,6-nonamethyl-1,3,5,2,4,6-trithiatri-λ⁵-bismane, 2,2,2,4,4,4,6,6,6-nonaethyl-1,3,5,2,4,6-trithiatri-λ⁵-bismane, 2,2,2,4,4,4,6,6,6-nonamethyl-1,3,5,2,4,6-triazatri-λ⁵-bismane, and 2,2,2,4,4,4,6,6,6-nonaethyl-1,3,5,2,4,6-triazatri-λ⁵-bismane.

Clause 14: Use of the organometallic compound according to any one of clauses 1 to 13 for preparing a dry photoresist or hardmask composition for EUV lithography.

Clause 16: The dry photoresist or hard mask composition according to clause 15, comprising the organometallic compound in an amount of 5 to 95% by weight, based on the total weight of the photoresist composition, in particular in an amount of 10 to 90% by weight, more particularly in an amount of 20 to 80% by weight.

Clause 17: The dry photoresist or hard mask composition according to clause 15 or 16, further comprising a solvent.

Clause 18: A dry photoresist or hard mask composition according to any one of clauses 15 to 17.

Clause 19: A method of forming a patterned materials feature on a substrate, comprising the steps of providing a material surface on a substrate; forming a layer of the dry photoresist or hard mask composition according to any one of clauses 15 to 17 over said material surface; patternwise irradiating the dry photoresist or hard mask layer with an energy ray, thereby creating a pattern of radiation-exposed regions in the dry photoresist or hard mask layer; selectively removing portions of the dry photoresist or hard mask layer to form exposed portions of said material surface; and etching or ion implanting said exposed portions of said material, thereby forming the patterned material feature.

Clause 20: The method according to clause 19, wherein the selectively removing portions of said dry photoresist or hard mask layer is carried out by thermal process steps, plasma ashing, or plasma etching process steps.

What is claimed is:

1. An organometallic compound for dry photoresists or hardmasks for EUV lithography comprising:
at least one bismuth element selected from the group consisting of Bi(III) and Bi(V);
at least one terminal or bridging ligand A bonded to the bismuth element, wherein the A ligand is selected from the group consisting of O, S, and N—R, and wherein the R group in N—R is selected from the group consisting of H and C1 to C6 alkyls; and
at least one C1 to C6 alkyl ligand bonded to the bismuth element.

2. The organometallic compound of claim 1, having a general formula selected from the group consisting of: 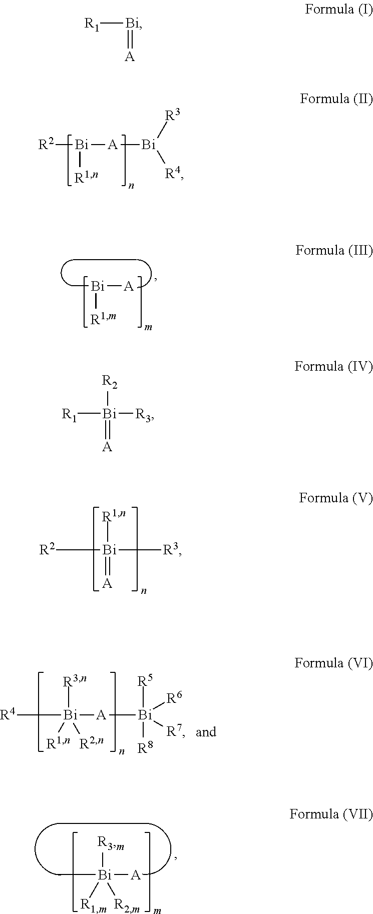
wherein, in the general formulas (I), (II), (III), (IV), (V), (VI), and (VII):
A represents a species selected from the group consisting of O, S, and N—R;
R1, R2, R3, R4, R5, R6, R7, and R8 represent alkyl ligands selected from the group consisting of an optionally substituted linear or branched C1 to C6 alkyl, an optionally substituted C3 to C6 cycloalkyl, and an optionally substituted C3 to C6 heterocycloalkyl;
n is an integer from 1 to 4;
m is an integer from 2 to 5; and
R in N—R represents a species selected from the group consisting of H, an optionally substituted linear C1 to C6 alkyl, an optionally substituted branched C1 to C6 alkyl, an optionally substituted C3 to C6 cycloalkyl, and an optionally substituted C3 to C6 heterocycloalkyl.

3. The organometallic compound of claim 2, wherein n is an integer from 1 to 3 and m is an integer from 2 to 4.

4. The organometallic compound of claim 2, wherein the organometallic compound has a formula selected from the group consisting of formulas (a) to (ad): 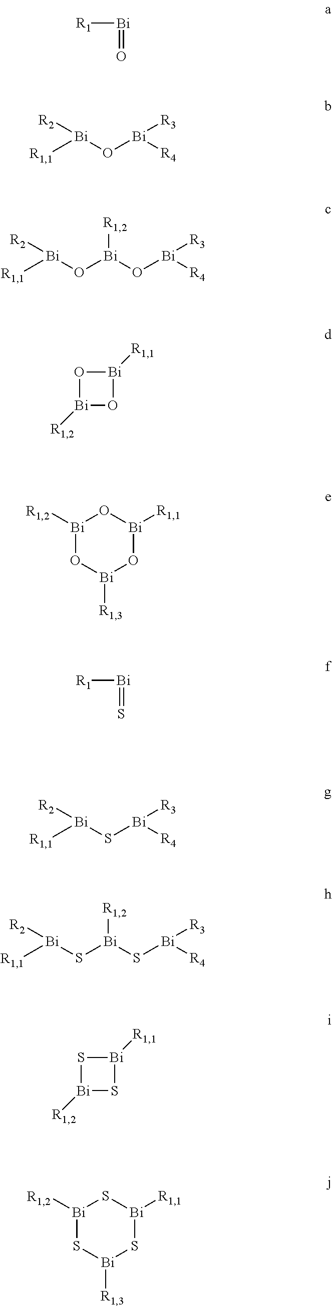 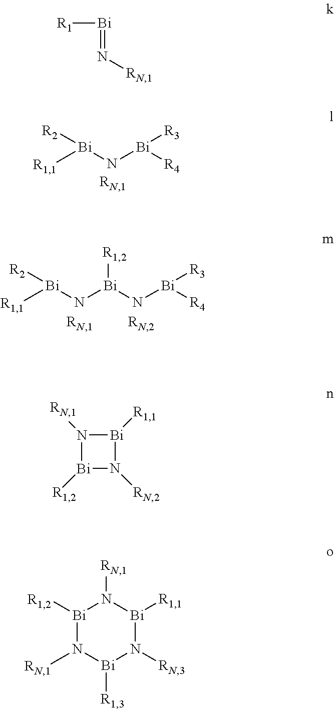 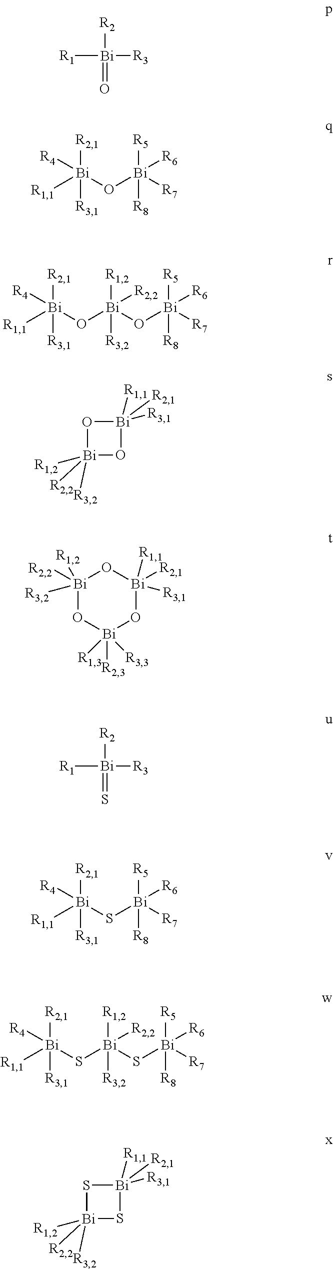 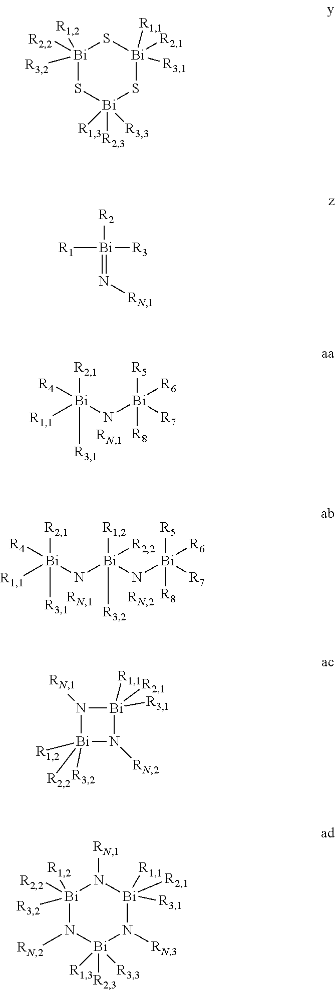
wherein:
in the general formulas (a) to (o), R1, R2, R3, R4, R1/1, R1/2, R1/3, RN/1, RN/2, and RN/3 are independently selected from the group consisting of an optionally substituted linear or branched C1 to C6 alkyl, an optionally substituted C3 to C6 cycloalkyl, and an optionally substituted C3 to C6 heterocycloalkyl; and
in the general formulas (p) to (ad), R1, R2, R3, R4, R5, R6, R7, R8, R1/1, R2/1, R3/1, R1/2, R2/2, R3/2, R1/3, R2/3, R3/3, RN/1, RN/2, and RN/3 are independently selected from the group consisting of an optionally substituted linear or branched C1 to C6 alkyl, an optionally substituted C3 to C6 cycloalkyl, and an optionally substituted C3 to C6 heterocycloalkyl.

5. The organometallic compound of claim 4, wherein R1, R2, R3, R4, R5, R6, R7, R8, R1/1, R2/1, R3/1, R1/2, R2/2, R3/2, R1/3, R2/3, R3/3, RN/1, RN/2, and RN/3 in the general formulas (a) to (ad) are selected from the group consisting of an optionally substituted linear C1 to C5 alkyl, an optionally substituted branched C1 to C5 alkyl, an optionally substituted C3 to C5 cycloalkyl, and an optionally substituted C3 to C5 heterocycloalkyl.

6. The organometallic compound of claim 4, wherein R1, R2, R3, R4, R5, R6, R7, R8, R1/1, R2/1, R3/1, R1/2, R2/2, R3/2, R1/3, R2/3, R3/3, RN/1, RN/2, and RN/3 in the general formulas (a) to (ad) are selected from the group consisting of an optionally substituted linear C1 to C4 alkyl, an optionally substituted branched C1 to C4 alkyl, an optionally substituted C3 or C4 cycloalkyl, and an optionally substituted C3 or C4 heterocycloalkyl.

7. The organometallic compound of claim 4, wherein R1, R2, R3, R4, R5, R6, R7, R8, R1/1, R2/1, R3/1, R1/2, R2/2, R3/2, R1/3, R2/3, R3/3, RN/1, RN/2, and RN/3 in the general formulas (a) to (ad) are selected from the group consisting of an optionally substituted linear C1 to C3 alkyl, an optionally substituted branched C1 to C3 alkyl, an optionally substituted C3 cycloalkyl, and an optionally substituted C3 heterocycloalkyl.

8. The organometallic compound of claim 4, wherein R1, R2, R3, R4, R5, R6, R7, R8, R1/1, R2/1, R3/1, R1/2, R2/2, R3/2, R1/3, R2/3, R3/3, RN/1, RN/2, and RN/3 in the general formulas (a) to (ad) are selected from the group consisting of an optionally substituted C1 alkyl and an optionally substituted C2 alkyl.

9. The organometallic compound of claim 4, wherein R1, R2, R3, R4, R5, R6, R7, R8, R1/1, R2/1, R3/1, R1/2, R2/2, R3/2, R1/3, R2/3, R3/3, RN/1, RN/2, and RN/3 in general formulas (a) to (ad) are identical to each other.

10. The organometallic compound of claim 1, wherein the organometallic compound has a melting point of at least 100° C.

11. The organometallic compound of claim 10, wherein the organometallic compound has a melting point in a range of 300° C. to 600° C.

12. The organometallic compound of claim 1, wherein the organometallic compound has a dissociation energy of at least 30 kcal/mol.

13. The organometallic compound of claim 1, wherein the organometallic compound is selected from the group consisting of methylbismuthanone,
ethylbismuthanone,
propylbismuthanone,
butylbismuthanone,
methylbismuthanethione,
ethylbismuthanethione,
propylbismuthanethione,
butylbismuthanethione,
Bi-methylbismuthanimine,
Bi-ethylbismuthanimine,
Bi-propylbismuthanimine,
Bi-butylbismuthanimine,
trimethyl-λ⁵-bismuthanone,
triethyl-λ⁵-bismuthanone,
tripropyl-λ⁵-bismuthanone,
tributyl-λ⁵-bismuthanone,
trimethyl-λ⁵-bismuthanethione,
triethyl-λ⁵-bismuthanethione,
tripropyl-λ⁵-bismuthanethione,
tributyl-λ⁵-bismuthanethione,
Bi,Bi,Bi-trimethyl-λ⁵-bismuthanimine,
Bi,Bi,Bi-triethyl-λ⁵-bismuthanimine,
Bi,Bi,Bi-tripropyl-λ⁵-bismuthanimine,
Bi,Bi,Bi-tributyl-λ⁵-bismuthanimine,
propan-2-ylbismuthanone,
tert-butylbismuthanone,
propan-2-ylbismuthanethione,
tert-butylbismuthanethione,
Bi-propan-2-ylbismuthanimine,
Bi-tert-butylbismuthanimine,
tri(propan-2-yl)-λ⁵-bismuthanone,
tri(tert-butyl)-λ⁵-bismuthanone,
tri(propan-2-yl)-λ⁵-bismuthanethione,
tri(tert-butyl)-λ⁵-bismuthanethione,
Bi,Bi,Bi-tri(propan-2-yl)-λ⁵-bismuthanimine,
Bi,Bi,Bi-tri(tert-butyl)-λ⁵-bismuthanimine,
cyclopropylbismuthanone,
cyclobutylbismuthanone,
cyclopropylbismuthanethione,
cyclobutylbismuthanethione,
Bi-cyclopropylbismuthanimine,
Bi-cyclobutylbismuthanimine,
tricyclopropyl-λ⁵-bismuthanone,
tricyclobutyl-λ⁵-bismuthanone,
tricyclopropyl-λ⁵-bismuthanethione,
tricyclobutyl-λ⁵-bismuthanethione,
Bi,Bi,Bi-tricyclopropyl-λ⁵-bismuthanimine,
Bi,Bi,Bi-tricyclobutyl-λ⁵-bismuthanimine,
dimethylbismuthanyloxy(dimethyl)bismuthane,
bis(dimethylbismuthanyloxy)(methyl)bismuthane,
dimethylbismuthanylsulfanyl(dimethyl)bismuthane,
bis(dimethylbismuthanylsulfanyl)(methyl)bismuthane,
bis(dimethylbismuthanyl)amine,
dimethylbismuthanylamino(methyl)bismuthanyl(dimethylbismuthanyl)amine,
diethylbismuthanyloxy(diethyl)bismuthane,
bis(diethylbismuthanyloxy)(ethyl)bismuthane,
diethylbismuthanylsulfanyl(diethyl)bismuthane,
bis(diethylbismuthanylsulfanyl)(ethyl)bismuthane,
bis(diethylbismuthanyl)amine,
diethylbismuthanylamino(ethyl)bismuthanyl(diethylbismuthanyl)amine,
dipropylbismuthanyloxy(dipropyl)bismuthane,
bis(dipropylbismuthanyloxy)(propyl)bismuthane,
dipropylbismuthanylsulfanyl(dipropyl)bismuthane,
bis(dipropylbismuthanylsulfanyl)(propyl)bismuthane,
bis(dipropylbismuthanyl)amine,
dipropylbismuthanylamino(propyl)bismuthanyl(dipropylbismuthanyl)amine,
dibutylbismuthanyloxy(dibutyl)bismuthane,
bis(dibutylbismuthanyloxy)(butyl)bismuthane,
dibutylbismuthanylsulfanyl(dibutyl)bismuthane,
bis(dibutylbismuthanylsulfanyl)(butyl)bismuthane,
bis(dibutylbismuthanyl)amine,
dibutylbismuthanylamino(butyl)bismuthanyl(dibutylbismuthanyl,
tetramethyl-λ⁵-bismuthanyloxy(tetramethyl)-λ⁵-bismuthane,
bis(tetramethyl-λ⁵-bismuthanyloxy)(trimethyl)-λ⁵-bismuthane,
tetramethyl-λ⁵-bismuthanylsulfanyl(tetramethyl)-λ⁵-bismuthane,
bis(tetramethyl-λ⁵-bismuthanylsulfanyl)(trimethyl)-λ⁵-bismuthane,
bis(tetramethyl-λ⁵-bismuthanyl)amine,
tetramethyl-λ⁵-bismuthanylamino(trimethyl)-λ⁵-bismuthanyl)(tetramethyl-λ⁵-bismuthanyl)amine,
tetraethyl-λ⁵-bismuthanyloxy(tetraethyl)-λ⁵-bismuthane,
bis(tetraethyl-λ⁵-bismuthanyloxy)(triethyl)-λ⁵-bismuthane,
tetraethyl-λ⁵-bismuthanylsulfanyl(tetraethyl)-λ⁵-bismuthane,
bis(tetraethyl-λ⁵-bismuthanylsulfanyl)(triethyl)-λ⁵-bismuthane,
bis(tetraethyl-λ⁵-bismuthanyl)amine,
tetraethyl-λ⁵-bismuthanylamino(triethyl)-λ⁵-bismuthanyl)(tetraethyl-λ⁵-bismuthanyl)amine,
tetrapropyl-λ⁵-bismuthanyloxy(tetrapropyl)-λ⁵-bismuthane,
bis(tetrapropyl-λ⁵-bismuthanyloxy)(tripropyl)-λ⁵-bismuthane,
tetrapropyl-λ⁵-bismuthanylsulfanyl(tetrapropyl)-λ⁵-bismuthane,
bis(tetrapropyl-λ⁵-bismuthanylsulfanyl)(tripropyl)-λ⁵-bismuthane,
bis(tetrapropyl-λ⁵-bismuthanyl)amine,
tetrapropyl-λ⁵-bismuthanylamino(tripropyl)-λ⁵-bismuthanyl)(tetrapropyl-λ⁵-bismuthanyl)amine,
tetrabutyl-λ⁵-bismuthanyloxy(tetrabutyl)-λ⁵-bismuthane,
bis(tetrabutyl-λ⁵-bismuthanyloxy)(tributyl)-λ⁵-bismuthane,
tetrabutyl-λ⁵-bismuthanylsulfanyl(tetrabutyl)-λ⁵-bismuthane,
bis(tetrabutyl-λ⁵-bismuthanylsulfanyl)(tributyl)-λ⁵-bismuthane,
bis(tetrabutyl-λ⁵-bismuthanyl)amine,
tetrabutyl-λ⁵-bismuthanylamino(tributyl)-λ⁵-bismuthanyl)(tetrabutyl-λ⁵-bismuthanyl)amine,
dicyclopropylbismuthanyloxy(dicyclopropyl)bismuthane,
bis(dicyclopropylbismuthanyloxy)(cyclopropyl)bismuthane,
dicyclopropylbismuthanylsulfanyl(dicyclopropyl)bismuthane,
bis(dicyclopropylbismuthanylsulfanyl)(cyclopropyl)bismuthane,
bis(dicyclopropylbismuthanyl)amine,
dicyclopropylbismuthanylamino(cyclopropyl)bismuthanyl(dicyclopropylbismuthanyl)amine,
dicyclobutylbismuthanyloxy(dicyclobutyl)bismuthane,
bis(dicyclobutylbismuthanyloxy)(cyclobutyl)bismuthane,
dicyclobutylbismuthanylsulfanyl(dicyclobutyl)bismuthane,
bis(dicyclobutylbismuthanylsulfanyl)(cyclobutyl)bismuthane,
bis(dicyclobutylbismuthanyl)amine,
dicyclobutylbismuthanylamino(cyclobutyl)bismuthanyl(dicyclobutylbismuthanyl)amine,
tetracyclopropyl-λ⁵-bismuthanyloxy(tetracyclopropyl)-λ⁵-bismuthane,
bis(tetracyclopropyl-λ⁵-bismuthanyloxy)(tricyclopropyl)-λ⁵-bismuthane,
tetracyclopropyl-λ⁵-bismuthanylsulfanyl(tetracyclopropyl)-λ⁵-bismuthane,
bis(tetracyclopropyl-λ⁵-bismuthanylsulfanyl)(tricyclopropyl)-λ⁵-bismuthane,
bis(tetracyclopropyl-λ⁵-bismuthanyl)amine,
tetracyclopropyl-λ⁵-bismuthanylamino(tricyclopropyl)-λ⁵-bismuthanyl)(tetracyclopropyl-λ⁵-bismuthanyl)amine,
tetracyclobutyl-λ⁵-bismuthanyloxy(tetracyclobutyl)-λ⁵-bismuthane,
bis(tetracyclobutyl-λ⁵-bismuthanyloxy)(tricyclobutyl)-λ⁵-bismuthane,
tetracyclobutyl-λ⁵-bismuthanylsulfanyl(tetracyclobutyl)-λ⁵-bismuthane,
bis(tetracyclobutyl-λ⁵-bismuthanylsulfanyl)(tricyclobutyl)-λ⁵-bismuthane,
bis(tetracyclobutyl-λ⁵-bismuthanyl)amine,
tetracyclobutyl-λ⁵-bismuthanylamino(tricyclobutyl)-λ⁵-bismuthanyl)(tetracyclobutyl-λ⁵-bismuthanyl)amine,
2,4-dimethyl-1,3,2,4-dioxadibismetane,
2,4-diethyl-1,3,2,4-dioxadibismetane,
2,4-dipropyl-1,3,2,4-dioxadibismetane,
2,4-dibutyl-1,3,2,4-dioxadibismetane,
2,4-dimethyl-1,3,2,4-dithiadibismetane,
2,4-diethyl-1,3,2,4-dithiadibismetane,
2,4-dipropyl-1,3,2,4-dithiadibismetane,
2,4-dibutyl-1,3,2,4-dithiadibismetane,
2,4-dimethyl-1,3,2,4-diazadibismetane,
2,4-diethyl-1,3,2,4-diazadibismetane,
2,4-dipropyl-1,3,2,4-diazadibismetane,
2,4-dibutyl-1,3,2,4-diazadibismetane,
2,2,2,4,4,4-hexamethyl-1,3,2,4-dioxadi-λ⁵-bismetane,
2,2,2,4,4,4-hexaethyl-1,3,2,4-dioxadi-λ⁵-bismetane,
2,2,2,4,4,4-hexapropyl-1,3,2,4-dioxadi-λ⁵-bismetane,
2,2,2,4,4,4-hexabutyl-1,3,2,4-dioxadi-λ⁵-bismetane,
2,2,2,4,4,4-hexamethyl-1,3,2,4-dithiadi-λ⁵-bismetane,
2,2,2,4,4,4-hexaethyl-1,3,2,4-dithiadi-λ⁵-bismetane,
2,2,2,4,4,4-hexapropyl-1,3,2,4-dithiadi-λ⁵-bismetane,
2,2,2,4,4,4-hexabutyl-1,3,2,4-dithiadi-λ⁵-bismetane,
2,2,2,4,4,4-hexamethyl-1,3,2,4-diazadi-λ⁵-bismetane,
2,2,2,4,4,4-hexaethyl-1,3,2,4-diazadi-λ⁵-bismetane,
2,2,2,4,4,4-hexapropyl-1,3,2,4-diazadi-λ⁵-bismetane,
2,2,2,4,4,4-hexabutyl-1,3,2,4-diazadi-λ⁵-bismetane,
2,4-dicyclopropyl-1,3,2,4-dioxadibismetane,
2,4-dicyclobutyl-1,3,2,4-dioxadibismetane,
2,4-dicyclopropyl-1,3,2,4-dithiadibismetane,
2,4-dicyclobutyl-1,3,2,4-dithiadibismetane,
2,4-dicyclopropyl-1,3,2,4-diazabismetane,
2,4-dicyclobutyl-1,3,2,4-diazadibismetane,
2,2,2,4,4,4-hexacyclopropyl-1,3,2,4-dioxadi-λ⁵-bismetane,
2,2,2,4,4,4-hexacyclobutyl-1,3,2,4-dioxadi-λ⁵-bismetane,
2,2,2,4,4,4-hexacyclopropyl-1,3,2,4-dithiadi-λ⁵-bismetane,
2,2,2,4,4,4-hexacyclobutyl-1,3,2,4-dithiadi-λ⁵-bismetane,
2,2,2,4,4,4-hexacyclopropyl-1,3,2,4-diazadi-λ⁵-bismetane,
2,2,2,4,4,4-hexacyclobutyl-1,3,2,4-diazadi-λ⁵-bismetane,
2,4,6-trimethyl-1,3,5,2,4,6-trioxatribismane,
2,4,6-triethyl-1,3,5,2,4,6-trioxatribismane,
2,4,6-tripropyl-1,3,5,2,4,6-trioxatribismane,
2,4,6-tributyl-1,3,5,2,4,6-trioxatribismane,
2,4,6-trimethyl-1,3,5,2,4,6-trithiatribismane,
2,4,6-triethyl-1,3,5,2,4,6-trithiatribismane,
2,4,6-tripropyl-1,3,5,2,4,6-trithiatribismane,
2,4,6-tributyl-1,3,5,2,4,6-trithiatribismane,
2,4,6-trimethyl-1,3,5,2,4,6-triazatribismane,
2,4,6-triethyl-1,3,5,2,4,6-triazatribismane,
2,4,6-tripropyl-1,3,5,2,4,6-triazatribismane,
2,4,6-tributyl-1,3,5,2,4,6-triazatribismane,
2,2,2,4,4,4,6,6,6-nonamethyl-1,3,5,2,4,6-trioxatri-λ⁵-bismane,
2,2,2,4,4,4,6,6,6-nonaethyl-1,3,5,2,4,6-trioxatri-λ⁵-bismane,
2,2,2,4,4,4,6,6,6-nonapropyl-1,3,5,2,4,6-trioxatri-λ⁵-bismane,
2,2,2,4,4,4,6,6,6-nonabutyl-1,3,5,2,4,6-trioxatri-λ⁵-bismane,
2,2,2,4,4,4,6,6,6-nonamethyl-1,3,5,2,4,6-trithiatri-λ⁵-bismane,
2,2,2,4,4,4,6,6,6-nonaethyl-1,3,5,2,4,6-trithiatri-λ⁵-bismane,
2,2,2,4,4,4,6,6,6-nonapropyl-1,3,5,2,4,6-trithiatri-λ⁵-bismane,
2,2,2,4,4,4,6,6,6-nonabutyl-1,3,5,2,4,6-trithiatri-λ⁵-bismane,
2,2,2,4,4,4,6,6,6-nonamethyl-1,3,5,2,4,6-triazatri-λ⁵-bismane,
2,2,2,4,4,4,6,6,6-nonaethyl-1,3,5,2,4,6-triazatri-λ⁵-bismane,
2,2,2,4,4,4,6,6,6-nonapropyl-1,3,5,2,4,6-triazatri-λ⁵-bismane,
2,2,2,4,4,4,6,6,6-nonabutyl-1,3,5,2,4,6-triazatri-λ⁵-bismane,
2,4,6-tricyclopropyl-1,3,5,2,4,6-trioxatribismane,
2,4,6-tricyclobutyl-1,3,5,2,4,6-trioxatribismane,
2,4,6-tricylcopropyl-1,3,5,2,4,6-trithiatribismane,
2,4,6-tricylcobutyl-1,3,5,2,4,6-trithiatribismane,
2,4,6-tricylcopropyl-1,3,5,2,4,6-triazatribismane,
2,4,6-tricylcobutyl-1,3,5,2,4,6-triazatribismane,
2,2,2,4,4,4,6,6,6-nonacyclopropyl-1,3,5,2,4,6-trioxatri-λ⁵-bismane,
2,2,2,4,4,4,6,6,6-nonacyclobutyl-1,3,5,2,4,6-trioxatri-λ⁵-bismane,
2,2,2,4,4,4,6,6,6-nonacylcopropyl-1,3,5,2,4,6-trithiatri-λ⁵-bismane,
2,2,2,4,4,4,6,6,6-nonacylcobutyl-1,3,5,2,4,6-trithiatri-λ⁵-bismane,
2,2,2,4,4,4,6,6,6-nonacylcopropyl-1,3,5,2,4,6-triazatri-λ⁵-bismane, and
2,2,2,4,4,4,6,6,6-nonacylcobutyl-1,3,5,2,4,6-triazatri-λ⁵-bismane.

14. The organometallic compound of claim 13, wherein the organometallic compound is selected from the group consisting of
methylbismuthanone,
ethylbismuthanone,
propylbismuthanone,
methylbismuthanethione,
ethylbismuthanethione,
propylbismuthanethione,
Bi-methylbismuthanimine,
Bi-ethylbismuthanimine,
Bi-propylbismuthanimine,
trimethyl-λ⁵-bismuthanone,
triethyl-λ⁵-bismuthanone,
tripropyl-λ⁵-bismuthanone,
trimethyl-λ⁵-bismuthanethione,
triethyl-λ⁵-bismuthanethione,
tripropyl-λ⁵-bismuthanethione,
Bi,Bi,Bi-trimethyl-λ⁵-bismuthanimine,
Bi,Bi,Bi-triethyl-λ⁵-bismuthanimine,
Bi,Bi,Bi-tripropyl-λ⁵-bismuthanimine,
cyclopropylbismuthanone,
cyclopropylbismuthanethione,
Bi-cyclopropylbismuthanimine,
tricyclopropyl-λ⁵-bismuthanone,
tricyclopropyl-λ⁵-bismuthanethione,
Bi,Bi,Bi-tricyclopropyl-λ⁵-bismuthanimine,
dimethylbismuthanyloxy(dimethyl)bismuthane,
bis(dimethylbismuthanyloxy)(methyl)bismuthane,
dimethylbismuthanylsulfanyl(dimethyl)bismuthane,
bis(dimethylbismuthanylsulfanyl)(methyl)bismuthane,
bis(dimethylbismuthanyl)amine,
dimethylbismuthanylamino(methyl)bismuthanyl(dimethylbismuthanyl)amine,
diethylbismuthanyloxy(diethyl)bismuthane,
bis(diethylbismuthanyloxy)(ethyl)bismuthane,
diethylbismuthanylsulfanyl(diethyl)bismuthane,
bis(diethylbismuthanylsulfanyl)(ethyl)bismuthane,
bis(diethylbismuthanyl)amine,
diethylbismuthanylamino(ethyl)bismuthanyl(diethylbismuthanyl)amine,
dipropylbismuthanyloxy(dipropyl)bismuthane,
bis(dipropylbismuthanyloxy)(propyl)bismuthane,
dipropylbismuthanylsulfanyl(dipropyl)bismuthane,
bis(dipropylbismuthanylsulfanyl)(propyl)bismuthane,
bis(dipropylbismuthanyl)amine,
dipropylbismuthanylamino(propyl)bismuthanyl(dipropylbismuthanyl)amine,
tetramethyl-λ⁵-bismuthanyloxy(tetramethyl)-as-bismuthane,
bis(tetramethyl-λ⁵-bismuthanyloxy)(trimethyl)-λ⁵-bismuthane,
tetramethyl-λ⁵-bismuthanylsulfanyl(tetramethyl)-λ⁵-bismuthane,
bis(tetramethyl-λ⁵-bismuthanylsulfanyl)(trimethyl)-λ⁵-bismuthane,
bis(tetramethyl-λ⁵-bismuthanyl)amine,
tetramethyl-λ⁵-bismuthanylamino(trimethyl)-λ⁵-bismuthanyl)(tetramethyl-λ⁵-bismuthanyl)amine,
tetraethyl-λ⁵-bismuthanyloxy(tetraethyl)-λ⁵-bismuthane,
bis(tetraethyl-λ⁵-bismuthanyloxy)(triethyl)-λ⁵-bismuthane,
tetraethyl-λ⁵-bismuthanylsulfanyl(tetraethyl)-λ⁵-bismuthane,
bis(tetraethyl-λ⁵-bismuthanylsulfanyl)(triethyl)-λ⁵-bismuthane,
bis(tetraethyl-λ⁵-bismuthanyl)amine,
tetraethyl-λ⁵-bismuthanylamino(triethyl)-λ⁵-bismuthanyl)(tetraethyl-λ⁵-bismuthanyl)amine,
tetrapropyl-λ⁵-bismuthanyloxy(tetrapropyl)-λ⁵-bismuthane,
bis(tetrapropyl-λ⁵-bismuthanyloxy)(tripropyl)-λ⁵-bismuthane,
tetrapropyl-λ⁵-bismuthanylsulfanyl(tetrapropyl)-λ⁵-bismuthane,
bis(tetrapropyl-λ⁵-bismuthanylsulfanyl)(tripropyl)-λ⁵-bismuthane,
bis(tetrapropyl-λ⁵-bismuthanyl)amine,
tetrapropyl-λ⁵-bismuthanylamino(tripropyl)-λ⁵-bismuthanyl)(tetrapropyl-λ⁵-bismuthanyl)amine,
dicyclopropylbismuthanyloxy(dicyclopropyl)bismuthane,
bis(dicyclopropylbismuthanyloxy)(cyclopropyl)bismuthane,
dicyclopropylbismuthanylsulfanyl(dicyclopropyl)bismuthane,
bis(dicyclopropylbismuthanylsulfanyl)(cyclopropyl)bismuthane,
bis(dicyclopropylbismuthanyl)amine,
dicyclopropylbismuthanylamino(cyclopropyl)bismuthanyl(dicyclopropylbismuthanyl)amine,
tetracyclopropyl-λ⁵-bismuthanyloxy(tetracyclopropyl)-λ⁵-bismuthane,
bis(tetracyclopropyl-λ⁵-bismuthanyloxy)(tricyclopropyl)-λ⁵-bismuthane,
tetracyclopropyl-λ⁵-bismuthanylsulfanyl(tetracyclopropyl)-λ⁵-bismuthane,
bis(tetracyclopropyl-λ⁵-bismuthanylsulfanyl)(tricyclopropyl)-λ⁵-bismuthane,
bis(tetracyclopropyl-λ⁵-bismuthanyl)amine,
tetracyclopropyl-λ⁵-bismuthanylamino(tricyclopropyl)-λ⁵-bismuthanyl)(tetracyclopropyl-λ⁵-bismuthanyl)amine,
2,4-dimethyl-1,3,2,4-dioxadibismetane,
2,4-diethyl-1,3,2,4-dioxadibismetane,
2,4-dipropyl-1,3,2,4-dioxadibismetane,
2,4-dimethyl-1,3,2,4-dithiadibismetane,
2,4-diethyl-1,3,2,4-dithiadibismetane,
2,4-dipropyl-1,3,2,4-dithiadibismetane,
2,4-dimethyl-1,3,2,4-diazadibismetane,
2,4-diethyl-1,3,2,4-diazadibismetane,
2,4-dipropyl-1,3,2,4-diazadibismetane,
2,2,2,4,4,4-hexamethyl-1,3,2,4-dioxadi-λ⁵-bismetane,
2,2,2,4,4,4-hexaethyl-1,3,2,4-dioxadi-λ⁵-bismetane,
2,2,2,4,4,4-hexapropyl-1,3,2,4-dioxadi-λ⁵-bismetane,
2,2,2,4,4,4-hexamethyl-1,3,2,4-dithiadi-λ⁵-bismetane,
2,2,2,4,4,4-hexaethyl-1,3,2,4-dithiadi-λ⁵-bismetane,
2,2,2,4,4,4-hexapropyl-1,3,2,4-dithiadi-λ⁵-bismetane,
2,2,2,4,4,4-hexamethyl-1,3,2,4-diazadi-λ⁵-bismetane,
2,2,2,4,4,4-hexaethyl-1,3,2,4-diazadi-λ⁵-bismetane,
2,2,2,4,4,4-hexapropyl-1,3,2,4-diazadi-λ⁵-bismetane,
2,4-dicyclopropyl-1,3,2,4-dioxadibismetane,
2,4-dicyclopropyl-1,3,2,4-dithiadibismetane,
2,4-dicyclopropyl-1,3,2,4-diazabismetane,
2,2,2,4,4,4-hexacyclopropyl-1,3,2,4-dioxadi-λ⁵-bismetane,
2,2,2,4,4,4-hexacyclopropyl-1,3,2,4-dithiadi-λ⁵-bismetane,
2,2,2,4,4,4-hexacyclopropyl-1,3,2,4-diazadi-λ⁵-bismetane,
2,4,6-trimethyl-1,3,5,2,4,6-trioxatribismane,
2,4,6-triethyl-1,3,5,2,4,6-trioxatribismane,
2,4,6-tripropyl-1,3,5,2,4,6-trioxatribismane,
2,4,6-trimethyl-1,3,5,2,4,6-trithiatribismane,
2,4,6-triethyl-1,3,5,2,4,6-trithiatribismane,
2,4,6-tripropyl-1,3,5,2,4,6-trithiatribismane,
2,4,6-trimethyl-1,3,5,2,4,6-triazatribismane,
2,4,6-triethyl-1,3,5,2,4,6-triazatribismane,
2,4,6-tripropyl-1,3,5,2,4,6-triazatribismane,
2,2,2,4,4,4,6,6,6-nonamethyl-1,3,5,2,4,6-trioxatri-λ⁵-bismane,
2,2,2,4,4,4,6,6,6-nonaethyl-1,3,5,2,4,6-trioxatri-λ⁵-bismane,
2,2,2,4,4,4,6,6,6-nonapropyl-1,3,5,2,4,6-trioxatri-λ⁵-bismane,
2,2,2,4,4,4,6,6,6-nonamethyl-1,3,5,2,4,6-trithiatri-λ⁵-bismane,
2,2,2,4,4,4,6,6,6-nonaethyl-1,3,5,2,4,6-trithiatri-λ⁵-bismane,
2,2,2,4,4,4,6,6,6-nonapropyl-1,3,5,2,4,6-trithiatri-λ⁵-bismane,
2,2,2,4,4,4,6,6,6-nonamethyl-1,3,5,2,4,6-triazatri-λ⁵-bismane,
2,2,2,4,4,4,6,6,6-nonaethyl-1,3,5,2,4,6-triazatri-λ⁵-bismane,
2,2,2,4,4,4,6,6,6-nonapropyl-1,3,5,2,4,6-triazatri-λ⁵-bismane,
2,4,6-tricyclopropyl-1,3,5,2,4,6-trioxatribismane,
2,4,6-tricylcopropyl-1,3,5,2,4,6-trithiatribismane,
2,4,6-tricylcopropyl-1,3,5,2,4,6-triazatribismane,
2,2,2,4,4,4,6,6,6-nonacyclopropyl-1,3,5,2,4,6-trioxatri-λ⁵-bismane,
2,2,2,4,4,4,6,6,6-nonacylcopropyl-1,3,5,2,4,6-trithiatri-λ⁵-bismane, and
2,2,2,4,4,4,6,6,6-nonacylcopropyl-1,3,5,2,4,6-triazatri-λ⁵-bismane.

15. The organometallic compound of claim 14, wherein the organometallic compound is selected from the group consisting of
methylbismuthanone,
ethylbismuthanone,
methylbismuthanethione,
ethylbismuthanethione,
Bi-methylbismuthanimine,
Bi-ethylbismuthanimine,
trimethyl-λ⁵-bismuthanone,
triethyl-λ⁵-bismuthanone,
trimethyl-λ⁵-bismuthanethione,
triethyl-λ⁵-bismuthanethione,
Bi,Bi,Bi-trimethyl-λ⁵-bismuthanimine,
Bi,Bi,Bi-triethyl-λ⁵-bismuthanimine,
dimethylbismuthanyloxy(dimethyl)bismuthane,
bis(dimethylbismuthanyloxy)(methyl)bismuthane,
dimethylbismuthanylsulfanyl(dimethyl)bismuthane,
bis(dimethylbismuthanylsulfanyl)(methyl)bismuthane,
bis(dimethylbismuthanyl)amine,
dimethylbismuthanylamino(methyl)bismuthanyl(dimethylbismuthanyl)amine,
diethylbismuthanyloxy(diethyl)bismuthane,
bis(diethylbismuthanyloxy)(ethyl)bismuthane,
diethylbismuthanylsulfanyl(diethyl)bismuthane,
bis(diethylbismuthanylsulfanyl)(ethyl)bismuthane,
bis(diethylbismuthanyl)amine,
diethylbismuthanylamino(ethyl)bismuthanyl(diethylbismuthanyl)amine,
tetramethyl-λ⁵-bismuthanyloxy(tetramethyl)-λ⁵-bismuthane,
bis(tetramethyl-λ⁵-bismuthanyloxy)(trimethyl)-λ⁵-bismuthane,
tetramethyl-λ⁵-bismuthanylsulfanyl(tetramethyl)-λ⁵-bismuthane,
bis(tetramethyl-λ⁵-bismuthanylsulfanyl)(trimethyl)-λ⁵-bismuthane,
bis(tetramethyl-λ⁵-bismuthanyl)amine,
tetramethyl-λ⁵-bismuthanylamino(trimethyl)-λ⁵-bismuthanyl)(tetramethyl-λ⁵-bismuthanyl)amine,
tetraethyl-λ⁵-bismuthanyloxy(tetraethyl)-λ⁵-bismuthane,
bis(tetraethyl-λ⁵-bismuthanyloxy)(triethyl)-λ⁵-bismuthane,
tetraethyl-λ⁵-bismuthanylsulfanyl(tetraethyl)-λ⁵-bismuthane,
bis(tetraethyl-λ⁵-bismuthanylsulfanyl)(triethyl)-λ⁵-bismuthane,
bis(tetraethyl-λ⁵-bismuthanyl)amine,
tetraethyl-λ⁵-bismuthanylamino(triethyl)-λ⁵-bismuthanyl)(tetraethyl-λ⁵-bismuthanyl)amine,
2,4-dimethyl-1,3,2,4-dioxadibismetane,
2,4-diethyl-1,3,2,4-dioxadibismetane,
2,4-dimethyl-1,3,2,4-dithiadibismetane,
2,4-diethyl-1,3,2,4-dithiadibismetane,
2,4-dimethyl-1,3,2,4-diazadibismetane,
2,4-diethyl-1,3,2,4-diazadibismetane,
2,2,2,4,4,4-hexamethyl-1,3,2,4-dioxadi-λ⁵-bismetane,
2,2,2,4,4,4-hexaethyl-1,3,2,4-dioxadi-λ⁵-bismetane,
2,2,2,4,4,4-hexamethyl-1,3,2,4-dithiadi-λ⁵-bismetane,
2,2,2,4,4,4-hexaethyl-1,3,2,4-dithiadi-λ⁵-bismetane,
2,2,2,4,4,4-hexamethyl-1,3,2,4-diazadi-λ⁵-bismetane,
2,2,2,4,4,4-hexaethyl-1,3,2,4-diazadi-λ⁵-bismetane,
2,4,6-trimethyl-1,3,5,2,4,6-trioxatribismane,
2,4,6-triethyl-1,3,5,2,4,6-trioxatribismane,
2,4,6-trimethyl-1,3,5,2,4,6-trithiatribismane,
2,4,6-triethyl-1,3,5,2,4,6-trithiatribismane,
2,4,6-trimethyl-1,3,5,2,4,6-triazatribismane,
2,4,6-triethyl-1,3,5,2,4,6-triazatribismane,
2,2,2,4,4,4,6,6,6-nonamethyl-1,3,5,2,4,6-trioxatri-λ⁵-bismane,
2,2,2,4,4,4,6,6,6-nonaethyl-1,3,5,2,4,6-trioxatri-λ⁵-bismane,
2,2,2,4,4,4,6,6,6-nonamethyl-1,3,5,2,4,6-trithiatri-λ⁵-bismane,
2,2,2,4,4,4,6,6,6-nonaethyl-1,3,5,2,4,6-trithiatri-λ⁵-bismane,
2,2,2,4,4,4,6,6,6-nonamethyl-1,3,5,2,4,6-triazatri-λ⁵-bismane, and
2,2,2,4,4,4,6,6,6-nonaethyl-1,3,5,2,4,6-triazatri-λ⁵-bismane.

16. A method of preparing a dry photoresist or hardmask composition for EUV lithography, comprising:
providing an organometallic compound, the organometallic compound comprising:
at least one bismuth element selected from the group consisting of Bi(III) and Bi(V);
at least one terminal or bridging ligand A bonded to the bismuth element, wherein the A ligand is selected from the group consisting of O, S, and N—R, and wherein the R group in N—R is selected from the group consisting of H and C1 to C6 alkyls; and
at least one C1 to C6 alkyl ligand bonded to the bismuth element.

17. A dry photoresist or hardmask composition for EUV lithography, comprising:
an organometallic compound, the organometallic compound comprising:
at least one bismuth element selected from the group consisting of Bi(III) and Bi(V);
at least one terminal or bridging ligand A bonded to the bismuth element, wherein the ligand A is selected from the group consisting of O, S, and N—R, and wherein the R group in N—R is selected from the group consisting of H and C1 to C6 alkyls; and
at least one C1 to C6 alkyl ligand bonded to the bismuth element.

18. The dry photoresist or hardmask composition of claim 17, wherein the organometallic compound is in an amount selected from the group consisting of 5 to 95% by weight, 10 to 90% by weight, and 20 to 80% by weight, based on the total weight of the photoresist composition.

19. The dry photoresist or hardmask composition of claim 17, further comprising a solvent.

20. The dry photoresist or hardmask composition of claim 17, wherein the organometallic compound has a general formula selected from the group consisting of: 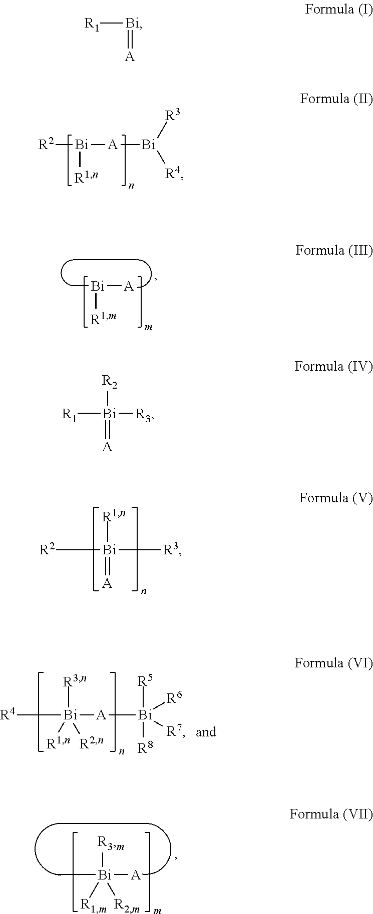
wherein, in the general formulas (I), (II), (III), (IV), (V), (VI), and (VII):
A represents a species selected from the group consisting of O, S, and N—R;
R1, R2, R3, R4, R5, R6, R7, and R8 represent alkyl ligands selected from the group consisting of an optionally substituted linear C1 to C6 alkyl, an optionally substituted branched C1 to C6 alkyl, an optionally substituted C3 to C6 cycloalkyl, and an optionally substituted C3 to C6 heterocycloalkyl;
n is an integer from 1 to 4;
m is an integer from 2 to 5; and
R in N—R represents a species selected from the group consisting of H, an optionally substituted linear C1 to C6 alkyl, an optionally substituted branched C1 to C6 alkyl, an optionally substituted C3 to C6 cycloalkyl, and an optionally substituted C3 to C6 heterocycloalkyl.

21. A dry photoresist or hardmask for EUV lithography, comprising:
a dry photoresist or hardmask composition comprising an organometallic compound, the organometallic compound comprising:
at least one bismuth element selected from the group consisting of Bi(III) and Bi(V);
at least one terminal or bridging ligand A bonded to the bismuth element, wherein the ligand A is selected from the group consisting of O, S, and N—R, and wherein the R group in N—R is selected from the group consisting of H and C1 to C6 alkyls; and
at least one C1 to C6 alkyl ligand bonded to the bismuth element.

22. The dry photoresist or hardmask of claim 21, wherein the organometallic compound has a general formula selected from the group consisting of: 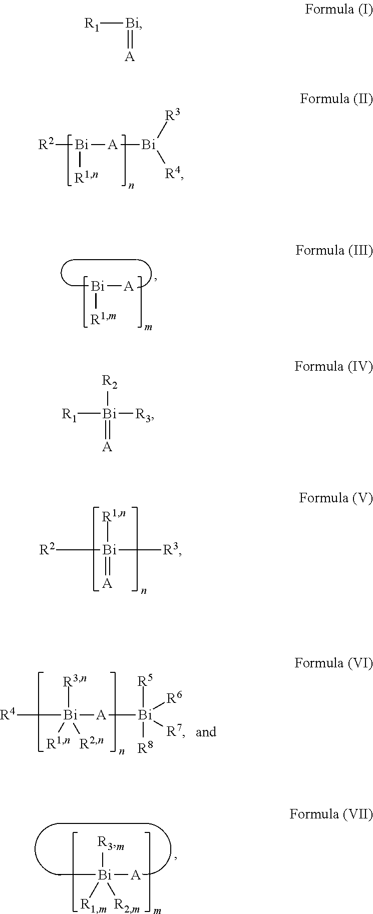
wherein, in the general formulas (I), (II), (III), (IV), (V), (VI), and (VII):
A represents a species selected from the group consisting of O, S, and N—R;
R1, R2, R3, R4, R5, R6, R7, and R8 represent alkyl ligands selected from the group consisting of an optionally substituted linear C1 to C6 alkyl, an optionally substituted branched C1 to C6 alkyl, an optionally substituted C3 to C6 cycloalkyl, and an optionally substituted C3 to C6 heterocycloalkyl;
n is an integer from 1 to 4;
m is an integer from 2 to 5; and
R in N—R represents a species selected from the group consisting of H, an optionally substituted linear C1 to C6 alkyl, an optionally substituted branched C1 to C6 alkyl, an optionally substituted C3 to C6 cycloalkyl, and an optionally substituted C3 to C6 heterocycloalkyl.

23. A method of forming a patterned material feature on a substrate, comprising:
providing a material surface on the substrate;
forming, over the material surface, a layer of a dry photoresist or hardmask composition comprising an organometallic compound, the organometallic compound comprising:
at least one bismuth element selected from the group consisting of Bi(III) and Bi(V);
at least one terminal or bridging ligand A bonded to the bismuth element, wherein the ligand A is selected from the group consisting of O, S, and N—R, and wherein the R group in N—R is selected from the group consisting of H and C1 to C6 alkyls; and
at least one C1 to C6 alkyl ligand bonded to the bismuth element;
patternwise irradiating the layer with an energy ray to form a pattern of radiation-exposed regions in the layer;
selectively removing portions of the layer to form exposed portions of the material surface; and
etching or ion implanting the exposed portions of the material surface to form the patterned material feature.

24. The method of claim 23, wherein the selectively removing portions of the layer is carried out using a technique selected from the group consisting of thermal process steps, plasma ashing, and plasma etching process steps.

25. The method of claim 23, wherein the energy ray comprises extreme ultraviolet (EUV) radiation.
